(19) United States
(12) Patent Application Publication
(10) Pub. No.: US 2023/0232702 A1
(43) Pub. Date: Jul. 20, 2023

(54) LIGHT EMITTING ELEMENT

(71) Applicant: Samsung Display Co., Ltd., Yongin-si (KR)

(72) Inventors: Ryuhei FURUE, Yokohama (JP); Yoshiro SUGITA, Yokohama (JP)

(73) Assignee: Samsung Display Co., Ltd., Yongin-si (KR)

(21) Appl. No.: 17/955,013

(22) Filed: Sep. 28, 2022

(30) Foreign Application Priority Data
Jan. 17, 2022 (KR) 10-2022-0006575

(51) Int. Cl. H01L 51/00; C07F 5/02; C09K 11/06

(52) U.S. Cl. CPC H01L 51/008; H01L 51/0072; H01L 51/0067; H01L 51/0087; C07F 5/027; C09K 11/06; H01L 51/5012

(57) ABSTRACT

A light emitting element includes a first electrode, a second electrode disposed on the first electrode, and an emission layer disposed between the first electrode and the second electrode. The emission layer may include a first compound represented by Formula 1, and at least one of a second compound, a third compound, and a fourth compound. The light emitting element including the first compound represented by Formula 1 exhibits high efficiency and a long lifespan.

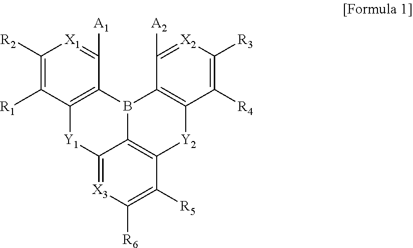

### CROSS-REFERENCE TO RELATED APPLICATION(S)

This application claims priority to and benefits of Korean Patent Application No. 10-2022-0006575 under 35 U.S.C. § 119, filed on Jan. 17, 2022 in the Korean Intellectual Property Office, the entire contents of which are incorporated herein by reference.

### BACKGROUND

### 1. Technical Field

The disclosure relates to a light emitting element including a polycyclic compound.

### 2. Description of the Related Art

Active development continues for organic electroluminescence display devices and the like as image display devices. Organic electroluminescence display devices and the like are display devices which include a so-called self-luminescent light emitting element in which holes and electrons respectively injected from a first electrode and a second electrode recombine in an emission layer, so that a luminescent material in the emission layer emits light to achieve display.

In the application of light emitting elements to display devices, there is a demand for light emitting elements which have high efficiency and long lifespan, and continuous development is required on materials that are capable of stably attaining such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element having increased color purity, efficiency, and lifespan.

An embodiment provides a light emitting element which may include a first electrode, a second electrode disposed on the first electrode, and an emission layer disposed between the first electrode and the second electrode. The emission layer may include: a first compound represented by Formula 1; and at least one of a second compound represented by Formula HT-1, a third compound represented by Formula ET-1, or a fourth compound represented by Formula M-b.

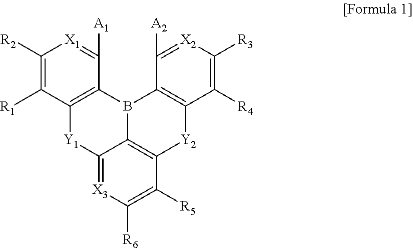

In Formula 1, X₁ to X₃ may each independently be C(R₇) or N; Y₁ and Y₂ may each independently be O, S, or N(Rₐ); Rₐ may be a substituted phenyl group including a substituent at an ortho position with respect to N; A₁ and A₂ may each independently be a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and R₁ to R₇ may each independently be a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

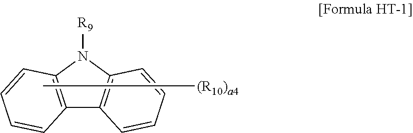

In Formula HT-1, a4 may be an integer from 0 to 8; and R₉ and R₁₀ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms.

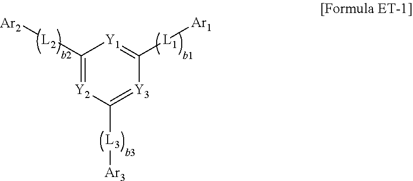

In Formula ET-1, at least one of Y₁ to Y₃ may be N; the remainder of Y₁ to Y₃ may each independently be C(R_{b}); R_{b} may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; b1 to b3 may each independently be an integer from 0 to 10; L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms; and Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

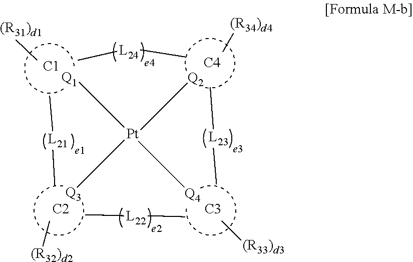

In Formula M-b, Q₁ to Q₄ may each independently be C or N; C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms; e1 to e4 may each independently be 0 or 1; L₂₁ to L₂₄ may each independently be a direct linkage,

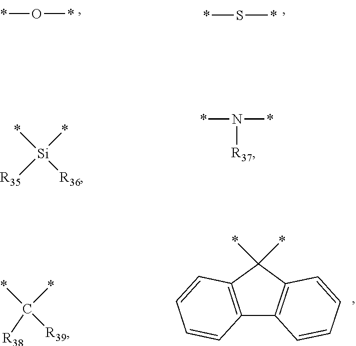

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; d1 to d4 may each independently be an integer from 0 to 4; and R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or may be bonded to an adjacent group to form a ring.

In an embodiment, in Formula 1, Rₐ may be a group represented by Formula 2.

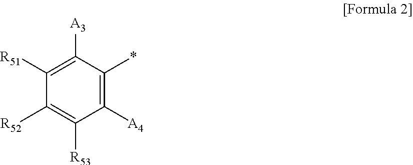

In Formula 2, at least one of A₃ or A₄ may each independently be a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; the remainder of A₃ and A₄ may be a hydrogen atom; and R₅₁ to R₅₃ may each independently be a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the group represented by Formula 2 may be a group represented by Formula 2-1.

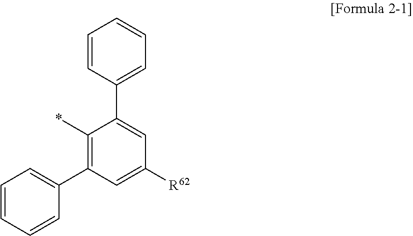

In Formula 2-1, R₆₂ may be a hydrogen atom, a deuterium atom, a substituted or unsubstituted alkyl group having 1 to 10 carbon atoms or a substituted or unsubstituted aryl group having 6 to 20 ring-forming carbon atoms.

In an embodiment, in Formula 2-1, R₆₂ may be an unsubstituted t-butyl group or an unsubstituted phenyl group.

In an embodiment, the first compound represented by Formula 1 may be a compound represented by Formula 1-1.

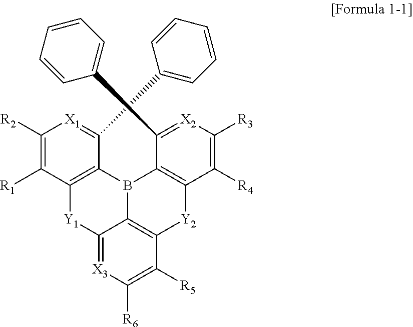

In Formula 1-1, X₁ to X₃, Y₁, Y₂, and R₁ to R₆ may each be the same as defined in Formula 1.

In an embodiment, the compound represented by Formula 1-1 may be a compound represented by Formula 1-1A.

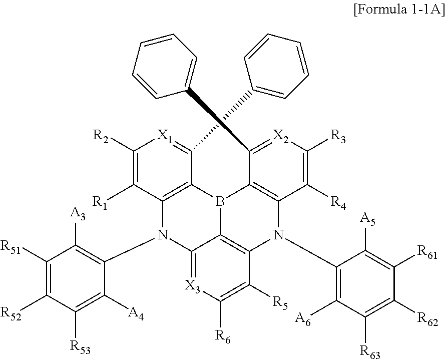

In Formula 1-1A, at least one of A₃ to A₆ may each independently be a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; the remainder of A₃ to A₆ may each independently be a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; R₅₁ to R₅₃ and R₆₁ to R₆₃ may each independently be a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and X₁ to X₃ and R₁ to R₆ may each be the same as defined in Formula 1.

In an embodiment, in Formula 1, R₂ and R₃ may each independently be a group represented by any one of R-1 to R-6.

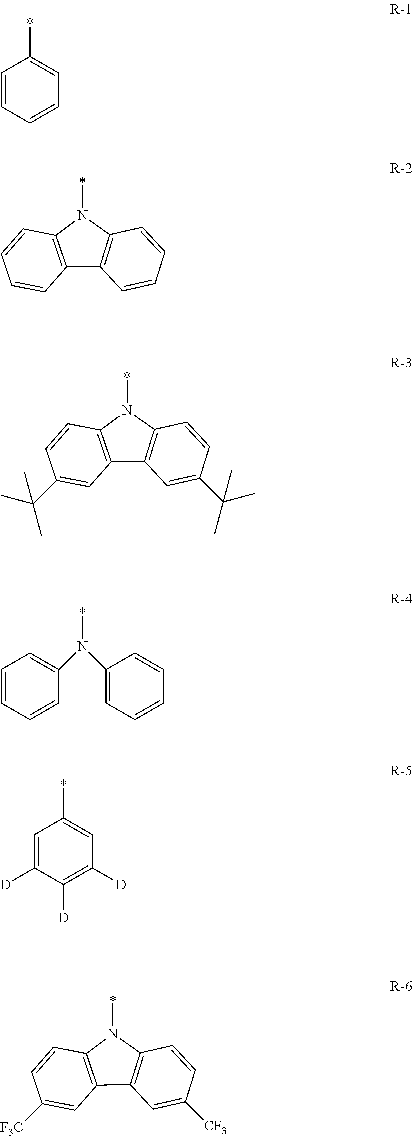 [SMILES: *c1ccccc1 ; *n1c2ccccc2c2ccccc21 ; *n1c2ccc(C(C)(C)C)cc2c2cc(C(C)(C)C)ccc21 ; *N(c1ccccc1)c1ccccc1 ; *c1cc([2H])c([2H])c([2H])c1 ; *n1c2ccc(C(F)(F)F)cc2c2cc(C(F)(F)F)ccc21]

In R-5, D is a deuterium atom.

In an embodiment, in Formula 1, R₆ may be a t-butyl group.

In an embodiment, in Formula 1, at least one of X₁ to X₃ may be N.

In an embodiment, the first compound represented by Formula 1 may be a compound represented by any one of Formulas 1-1X to 1-3X.

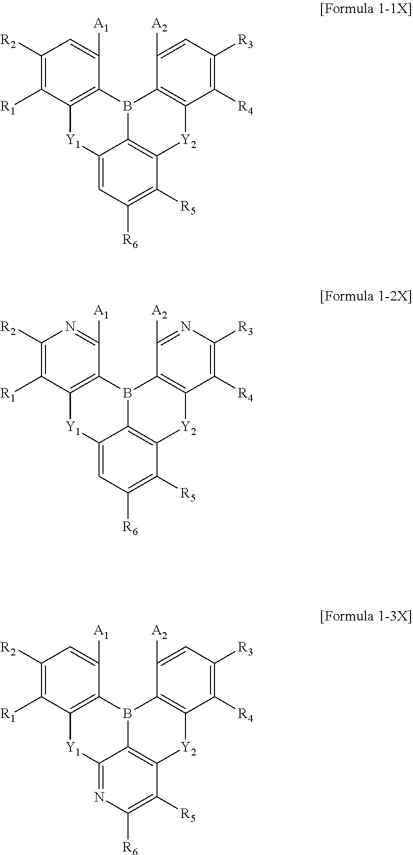

In Formulas 1-1X to 1-3X, A₁, A₂, Y₁, Y₂, and R₁ to R₆ may each be the same as defined in Formula 1.

In an embodiment, in Formula 1, at least one of Y₁, Y₂, and R₁ to R₆ may each independently include a deuterium atom or a substituent including a deuterium atom.

In an embodiment, the emission layer may include the first compound, the second compound, and the third compound.

In an embodiment, the emission layer may include the first compound, the second compound, the third compound, and the fourth compound.

In an embodiment, the first compound represented by Formula 1 may be selected from Compound Group 1, which is explained below.

An embodiment provides a light emitting element which may include a first electrode, a second electrode disposed on the first electrode, and at least one functional layer disposed between the first electrode and the second electrode, wherein the at least one functional layer may include a polycyclic compound represented by Formula 1.

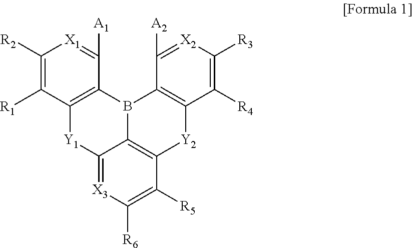

In Formula 1, X₁ to X₃ may each independently be C(R₇) or N; Y₁ and Y₂ may each independently be O, S, or N(Rₐ); Rₐ may be a substituted phenyl group including a substituent at an ortho position with respect to N; A₁ and A₂ may each independently be a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and R₁ to R₇ may each independently be a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the at least one functional layer may include an emission layer, a hole transport region disposed between the first electrode and the emission layer, and an electron transport region disposed between the emission layer and the second electrode; and the emission layer may include the polycyclic compound.

In an embodiment, the emission layer may be a delayed fluorescence emission layer including a host and a dopant, and the dopant may include the polycyclic compound.

In an embodiment, in Formula 1, A₁ and A₂ may each independently be a substituted or unsubstituted phenyl group.

In an embodiment, the polycyclic compound may be symmetrical with respect to a boron atom.

In an embodiment, the polycyclic compound may be selected from Compound Group 1, which is explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a plan view showing a display device according to an embodiment;

FIG. 2 is a schematic cross-sectional view showing a portion corresponding to line I-I′ of FIG. 1;

FIG. 3 is a schematic cross-sectional view showing a light emitting element according to an embodiment;

FIG. 4 is a schematic cross-sectional view showing a light emitting element according to an embodiment;

FIG. 5 is a schematic cross-sectional view showing a light emitting element according to an embodiment;

FIG. 6 is a schematic cross-sectional view showing a light emitting element according to an embodiment;

FIG. 7 is a schematic cross-sectional view showing a display device according to an embodiment;

FIG. 8 is a schematic cross-sectional view showing a display device according to an embodiment;

FIG. 9 is a schematic cross-sectional view showing a display device according to an embodiment; and

FIG. 10 is a schematic cross-sectional view showing a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments will be described with reference to the accompanying drawings.

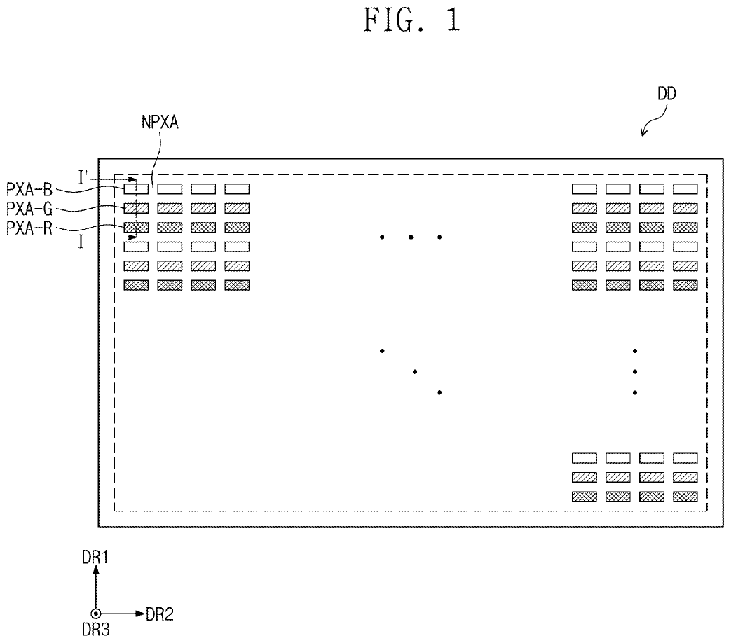

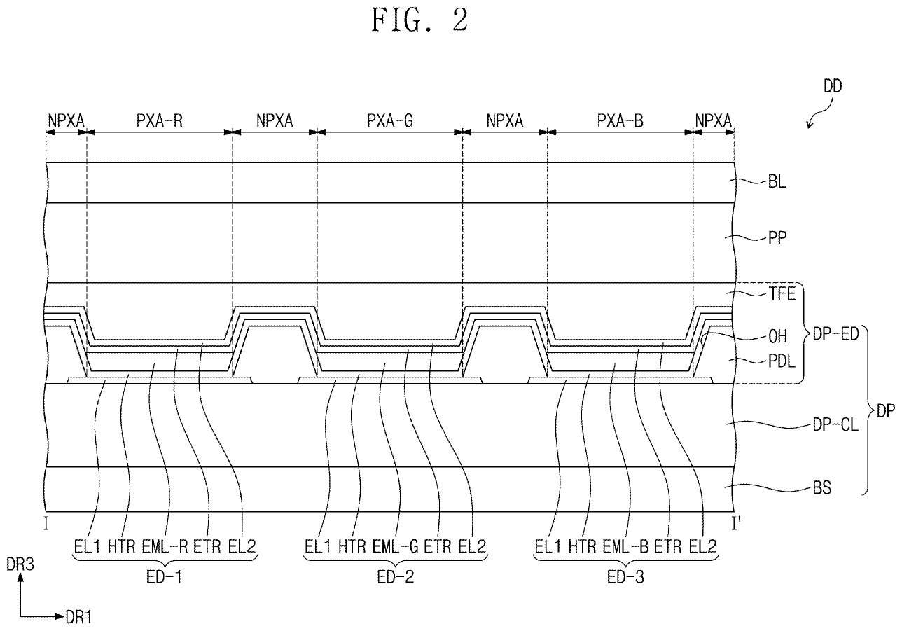

FIG. 1 is a plan view showing an embodiment of a display device DD. FIG. 2 is a schematic cross-sectional view of a display device DD according to an embodiment. FIG. 2 is a schematic cross-sectional view showing a portion corresponding to line I-I′ of FIG. 1.

The display device DD may include a display panel DP and an optical layer PP disposed on the display panel DP. The display panel DP may include light emitting elements ED-1, ED-2, and ED-3. The display device DD may include multiples of each of light emitting elements ED-1, ED-2, and ED-3. The optical layer PP may be disposed on the display panel DP and may control light reflected at the display panel DP from an external light. The optical layer PP may include, for example, a polarizing layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic resin, a silicone-based resin, or an epoxy-based resin.

The display panel DP may include a base layer BS, a circuit layer DP-CL provided on the base layer BS, and a display element layer DP-ED. The display element layer DP-ED may include pixel defining films PDL, light emitting elements ED-1, ED-2, and ED-3 disposed between the pixel defining films PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL may be disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

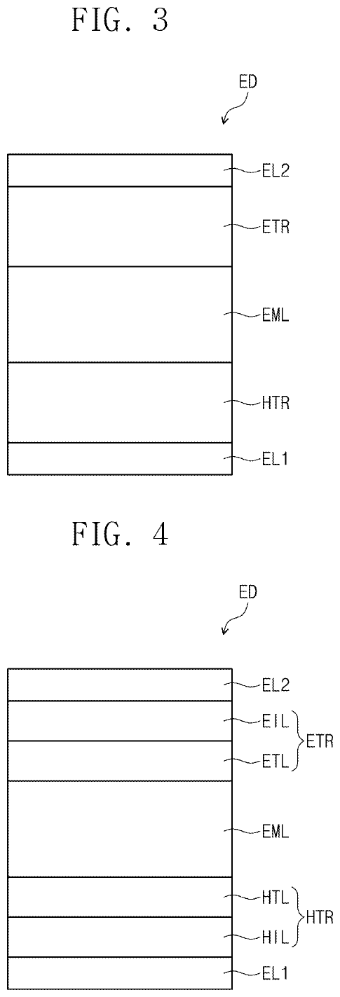

The light emitting elements ED-1, ED-2, and ED-3 may each have a structure of a light emitting element ED according to an embodiment of FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment in which the emission layers EML-R, EML-G, and EML-B of the light emitting elements ED-1, ED-2, and ED-3 are disposed in openings OH defined in the pixel defining films PDL, and the hole transport region HTR, the electron transport region ETR, and the second electrode EL2 are each provided as a common layer for all of the light emitting elements ED-1, ED-2, and ED-3. However, embodiments are not limited thereto. Although not shown in FIG. 2, in an embodiment, the hole transport region HTR and the electron transport region ETR may each be provided by being patterned inside the openings OH defined in the pixel defining films PDL. For example, in an embodiment, the hole transport region HTR, the emission layers EML-R, EML-G, and EML-B, and the electron transport region ETR, etc. of the light emitting elements ED-1, ED-2, and ED-3 may each be patterned and provided through an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed of a single layer or of multiple layers. The encapsulation layer may include at least one insulating layer. The encapsulation layer TFE according to an embodiment may include at least one inorganic film (hereinafter, an encapsulation inorganic film). The encapsulation layer TFE according to an embodiment may include at least one organic film (hereinafter, an encapsulation organic film) and at least one encapsulation inorganic film.

The encapsulation inorganic film may protect the display element layer DP-ED from moisture and/or oxygen, and the encapsulation organic film may protect the display element layer DP-ED from foreign substances such as dust particles. The encapsulation inorganic film may include silicon nitride, silicon oxy nitride, silicon oxide, titanium oxide, aluminum oxide, etc., but embodiments are not limited thereto. The encapsulation organic layer may include an acrylic compound, an epoxy-based compound, etc. The encapsulation organic layer may include a photopolymerizable organic material, but embodiments are not limited thereto.

The encapsulation layer TFE may be disposed on the second electrode EL2, and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region emitting light generated from each of the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining films PDL. The non-light emitting regions NPXA may be regions between neighboring light emitting regions PXA-R, PXA-G, and PXA-B, and may correspond to the pixel defining films PDL. For example, in an embodiment, the light emitting regions PXA-R, PXA-G, and PXA-B may each correspond to a pixel. The pixel defining films PDL may separate the light emitting elements ED-1, ED-2, and ED-3. The emission layers EML-R, EML-G, and EML-B of the light emitting elements ED-1, ED-2, and ED-3 may be disposed in the openings OH defined by the pixel defining films PDL and separated from each other.

The light emitting regions PXA-R, PXA-G, and PXA-B may be arranged into groups according to the color of light generated from the light emitting elements ED-1, ED-2, and ED-3. In the display device DD according to an embodiment shown in FIGS. 1 and 2, three light emitting regions PXA-R, PXA-G, and PXA-B which respectively emit red light, green light, and blue light, are illustrated as an example. For example, the display device DD according to an embodiment may include a red light emitting region PXA-R, a green light emitting region PXA-G, and a blue light emitting region PXA-B, which are distinct from one another.

In the display device DD according to an embodiment, the light emitting elements ED-1, ED-2, and ED-3 may emit light having different wavelength ranges from one another. For example, in an embodiment, the display device DD may include a first light emitting element ED-1 emitting red light, a second light emitting element ED-2 emitting green light, and a third light emitting element ED-3 emitting blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2 and ED-3 may emit light in a same wavelength range, or at least one light emitting element may emit light in a different wavelength range from the others. For example, the first to third light emitting elements ED-1, ED-2, and ED-3 may all emit blue light.

The light emitting regions PXA-R, PXA-G, and PXA-B in the display device DD according to an embodiment may be arranged in a stripe configuration. Referring to FIG. 1, red light emitting regions PXA-R, green light emitting regions PXA-G, and blue light emitting regions PXA-B may each be arranged along a second directional axis DR2. In another embodiment, the red light emitting region PXA-R, the green light emitting region PXA-G, and the blue light emitting region PXA-B may be arranged by turns along a first directional axis DR1.

FIGS. 1 and 2 illustrate that the light emitting regions PXA-R, PXA-G, and PXA-B have a similar size to each other, but embodiments are not limited thereto. The light emitting regions PXA-R, PXA-G and PXA-B may be different in size from each other according to a wavelength range of emitted light. The areas of the light emitting regions PXA-R, PXA-G, and PXA-B may be areas in a plan view that are defined by the first directional axis DR1 and the second directional axis DR2.

The arrangement of the light emitting regions PXA-R, PXA-G, and PXA-B is not limited to what is shown in FIG. 1, and the order in which the red light emitting region PXA-R, the green light emitting region PXA-G, and the blue light emitting region PXA-B are arranged may be provided in various combinations according to the display quality characteristics which are required for the display device DD. For example, the light emitting regions PXA-R, PXA-G, and PXA-B may be arranged in a PENTILE™ configuration or in a Diamond Pixel™ configuration.

In an embodiment, the areas of each of the light emitting regions PXA-R, PXA-G, and PXA-B may be different in size from one another. For example, in an embodiment, an area of the green light emitting region PXA-G may be smaller than an area of the blue light emitting region PXA-B, but embodiments are not limited thereto.

Hereinafter, FIGS. 3 to 6 are each a schematic cross-sectional view showing a light emitting element according to an embodiment. Each of the light emitting elements ED according to embodiments may include a first electrode EL1, a hole transport region HTR, an emission layer EML, an electron transport region ETR, and a second electrode EL2.

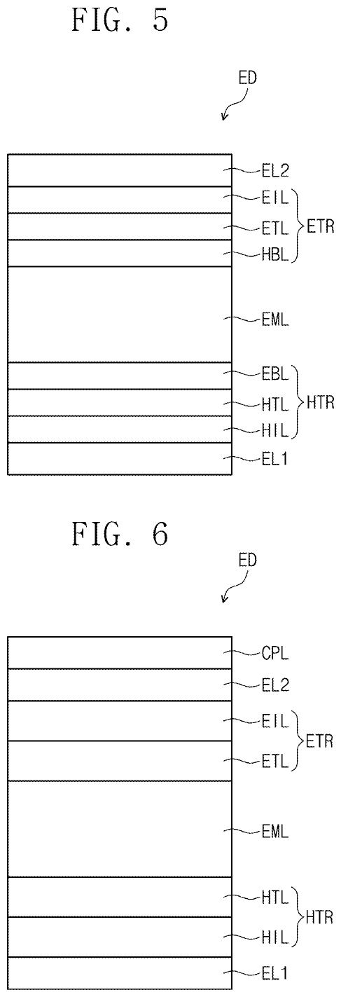

In comparison to FIG. 3, FIG. 4 shows a schematic cross-sectional view of a light emitting element ED of an embodiment in which the hole transport region HTR includes a hole injection layer HIL and a hole transport layer HTL, and the electron transport region ETR includes an electron injection layer EIL and an electron transport layer ETL. In comparison to FIG. 3, FIG. 5 shows a schematic cross-sectional view of a light emitting element ED of an embodiment in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. In comparison to FIG. 4, FIG. 6 shows a schematic cross-sectional view of a light emitting element ED of an embodiment, in which a capping layer CPL is disposed on the second electrode EL2.

In an embodiment, the emission layer may include a first compound, and at least one of a second compound, a third compound, or a fourth compound. The first compound may include a fused ring of five rings, and the fused ring of five rings may include a boron atom (B) as a ring-forming atom. The second compound may include a substituted or unsubstituted carbazole group, and the third compound may include a heterocyclic group including nitrogen (N) as a ring-forming atom. The fourth compound may be an organometallic compound including platinum (Pt) as a central metal. The first compound is the same as the polycyclic compound as described herein.

In the description, the term “substituted or unsubstituted” may mean a group that is substituted or unsubstituted with at least one substituent selected from the group consisting of a deuterium atom, a halogen atom, a cyano group, a nitro group, an amine group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the description, the term “bonded to an adjacent group to form a ring” may mean a group that is bonded to an adjacent group to form a substituted or unsubstituted hydrocarbon ring, or a substituted or unsubstituted heterocycle. The hydrocarbon ring may be an aliphatic hydrocarbon ring or an aromatic hydrocarbon ring. The heterocycle may be an aliphatic heterocycle or an aromatic heterocycle. The hydrocarbon ring and the heterocycle may each independently be monocyclic or polycyclic. A ring that is formed by adjacent groups being bonded to each other may itself be connected to another ring to form a spiro structure.

In the description, the term “adjacent group” may refer to a substituent substituted for an atom which is directly connected to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the description, examples of a halogen atom may include a fluorine atom, a chlorine atom, a bromine atom, or an iodine atom.

In the description, an alkyl group may be linear, branched, or cyclic. The number of carbon atoms in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, a s-butyl group, a t-butyl group, an i-butyl group, a 2-ethylbutyl group, a 3,3-a dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the description, a hydrocarbon ring group may be any functional group or substituent derived from an aliphatic hydrocarbon ring or an aromatic hydrocarbon ring. The number of ring-forming carbon atoms in the hydrocarbon ring group is not particularly limited, but may be 6 to 30. For example, the hydrocarbon ring group may be a saturated hydrocarbon ring group having 5 to 30 ring-forming carbon atoms.

In the description, an aryl group may be any functional group or substituent derived from an aromatic hydrocarbon ring. The aryl group may be monocyclic or polycyclic. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the description, a heterocyclic group may be any functional group or substituent derived from a ring including at least one of B, O, N, P, Si, or S as a heteroatom. The heterocyclic group may be an aliphatic heterocyclic group or an aromatic heterocyclic group. The aromatic heterocyclic group may be a heteroaryl group. The aliphatic heterocycle and the aromatic heterocycle may each independently be monocyclic or polycyclic.

In the description, the heterocyclic group may include at least one of B, O, N, P, Si or S as a hetero atom. When the heterocyclic group includes two or more heteroatoms, the two or more heteroatoms may be the same as or different from each other. The heterocyclic group may be monocyclic or polycyclic, and the heterocyclic group may be a heteroaryl group. The number of ring-forming carbon atoms in the heterocyclic group may be 2 to 60, 2 to 30, 2 to 20, or 2 to 10.

In the description, a heteroaryl group may include at least one of B, O, N, P, Si, or S as a heteroatom. When the heteroaryl group includes two or more heteroatoms, the two or more heteroatoms may be the same as or different from each other. The heteroaryl group may be monocyclic or polycyclic. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the description, the above description of the aryl group may be applied to an arylene group, except that the arylene group is a divalent group. The above description of the heteroaryl group may be applied to a heteroarylene group, except that the heteroarylene group is a divalent group.

In the description, the number of carbon atoms in an amine group is not particularly limited, but may be 1 to 30. The amine group may be an alkyl amine group or an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but embodiments are not limited thereto.

In the description, a direct linkage may be a single bond.

In the description, the symbols

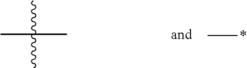

each represents a bonding site to a neighboring atom.

An emission layer EML may include a polycyclic compound according to an embodiment. The polycyclic compound may be represented by Formula 1.

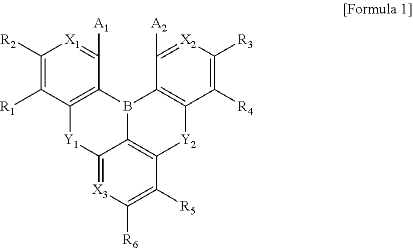

In Formula 1, X₁ to X₃ may each independently be C(R₇) or N. In an embodiment, at least one of X₁ to X₃ may be N. In another embodiment, each of X₁ to X₃ may be C(R₇).

In Formula 1, Y₁ and Y₂ may each independently be O, S, or N(Rₐ); and Rₐ may be a substituted phenyl group including a substituent at an ortho position with respect to N. In Rₐ, which is a substituted phenyl group, there are two ortho positions with respect to N, and a substituent may be bonded to at least one of the two ortho positions. The substituent bonded at the ortho position with respect to N may be a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₐ may include at least one of a deuterium atom, a t-butyl group, or a phenyl group as a substituent. In an embodiment, in Rₐ, a phenyl group may be bonded at an ortho position with respect to N.

In Formula 1, A₁ and A₂ may each independently be a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, when A₁ and A₂ are each a substituted or unsubstituted heteroaryl group, the number of ring-forming carbon atoms in the heteroaryl group may be 3 to 30. In an embodiment, A₁ and A₂ may each independently be a substituted or unsubstituted phenyl group.

In Formula 1, A₁ and A₂ are not hydrogen atoms. In Formula 1, A₁ is not bonded to X₁ and A₂ to form a ring, and A₂ is not bonded to X₂ and A₁ to form a ring.

In Formula 1, R₁ to R₇ may each independently be a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, R₆ may be a t-butyl group. In an embodiment, the polycyclic compound may include at least one t-butyl group or at least one substituent including a t-butyl group.

In the polycyclic compound according to an embodiment, any hydrogen atom may be substituted with a deuterium atom. In an embodiment, in Formula 1, at least one of Y₁, Y₂, or R₁ to R₆ may include a deuterium atom or a substituent including a deuterium atom. For example, Y₁ and Y₂ may each independently include a phenyl group substituted with a deuterium atom as a substituent. At least one of R₁ to R₆ may be a phenyl group substituted with a deuterium atom. However, this is only presented as an example, and embodiments are not limited thereto.

In an embodiment, R₂ and R₃ may each independently be a substituted or unsubstituted phenyl group, a substituted or unsubstituted carbazole group, or a substituted or unsubstituted diphenylamine group. For example, in an embodiment, R₂ and R₃ may each independently be a group represented by any one of R-1 to R-6. R-1 represents an unsubstituted phenyl group, and R-2 represents an unsubstituted carbazole group. R-3 represents a carbazole group substituted with two t-butyl groups. R-4 represents an unsubstituted diphenylamine group. R-5 represents a phenyl group substituted with a deuterium atom. In R-5, D is a deuterium atom. R-6 represents a carbazole group substituted with a trifluoromethyl group.

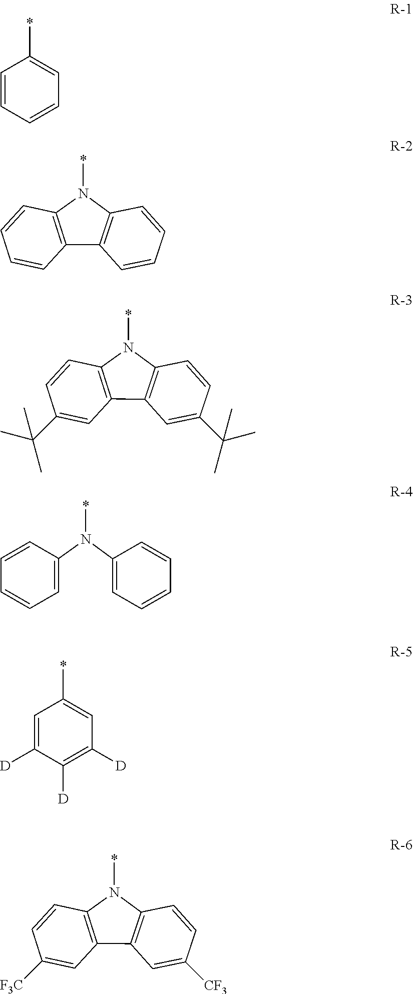

In an embodiment, a polycyclic compound represented by Formula 1 may be symmetrical with respect to a boron atom (B), which is a ring-forming atom of a fused ring. For example, in an embodiment, in Formula 1, A₁ and A₂ are the same, X₁ and X₂ are the same, Y₁ and Y₂ are the same, R₁ and R₄ are the same, R₂ and R₃ are the same, and X₃ is CR₇ such that R₅ and R₇ may be the same. In the polycyclic compound which is symmetrical with respect to a boron atom, a right-handed enantiomer and a left-handed enantiomer may be present in substantially similar amounts. The polycyclic compound which is symmetrical with respect to a boron atom may be a racemic mixture. Circularly polarized light emission may not take place in the emission layer EML that includes the polycyclic compound a racemic mixture.

In an embodiment, Rₐ may be a group represented by Formula 2. In Formula 2, A₃ and A₄ are substituents that are each at an ortho position with respect to N.

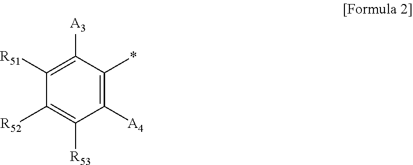

In Formula 2, at least one of A₃ or A₄ may be a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula 2, the remainder of A₃ and A₄ may be a hydrogen atom. For example, in Formula 2, at least one of A₃ or A₄ may not be a hydrogen atom.

In Formula 1, Y₁ and Y₂ may each independently be N(Rₐ). For example, when Y₁ and Y₂ are each N(Rₐ), Rₐ of Y₁ and Rₐ of Y₂ may be the same as or different from each other. For example, when only Y₁ from Y₁ and Y₂ is N(Rₐ) and Rₐ is represented by Formula 2, A₃ is not bonded to R₅₁ and R₁ to form a ring, and A₄ is not bonded to R₅₃ and X₃ to form a ring. When only Y₂ from Y₁ and Y₂ is N(Rₐ) and Rₐ is represented by Formula 2, A₃ is not bonded to R₅₁ and R₄ to form a ring, and A₄ is not bonded to R₅₃ and R₅ to form a ring.

For example, when Y₁ and Y₂ are each N(Rₐ), and Rₐ of Y₁ and Rₐ of Y₂ are each independently represented by Formula 2, A₃ and A₄ of Y₁ are not bonded to adjacent groups (R₅₁, R₁, R₅₃, and X₃) to form a ring or A₃ and A₄ of Y₂ are not bonded to adjacent groups (R₅₁, R₄, R₅₃, and R₅) to form a ring.

In Formula 2, R₅₁ to R₅₃ may each independently be a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, at least one of R₅₁ to R₅₃ may be a substituted or unsubstituted alkyl group having 1 to 20 carbon atoms, or a substituted or unsubstituted aryl group having 6 to 30 ring-forming carbon atoms.

In an embodiment, the group represented by Formula 2 may be a group represented by Formula 2-1. Formula 2-1 represents a case in which A₃ and A₄ are each an unsubstituted phenyl group, and R₅₁ and R₅₃ are each a hydrogen atom in Formula 2.

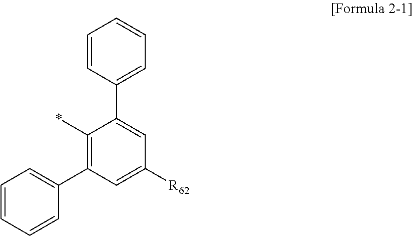

In Formula 2-1, R₆₂ may be a hydrogen atom, a deuterium atom, a substituted or unsubstituted alkyl group having 1 to 10 carbon atoms or a substituted or unsubstituted aryl group having 6 to 20 ring-forming carbon atoms. For example, in an embodiment, in Formula 2-1, R₆₂ may be an unsubstituted t-butyl group or an unsubstituted phenyl group.

In an embodiment, the polycyclic compound represented by Formula 1 may be a compound represented by Formula 1-1. Formula 1-1 represents a case in which A₁ and A₂ are each an unsubstituted phenyl group in Formula 1.

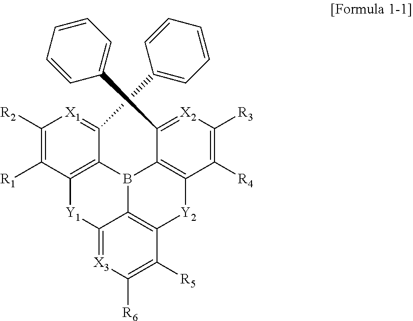

In Formula 1-1, X₁ to X₃, Y₁, Y₂, and R₁ to R₆ are each the same as defined in Formula 1.

In an embodiment, the compound represented by Formula 1-1 may be a compound represented by Formula 1-1A.

Formula 1-1A represents a case in which Y₁ and Y₂ are each independently N(Rₐ) in Formula 1-1. Furthermore, Formula 1-1A represents a case in which Y₁ and Y₂ are each independently N(Rₐ) in Formula 1-1, and Rₐ of Y₁ and Rₐ of Y₂ is each independently a group represented by Formula 2.

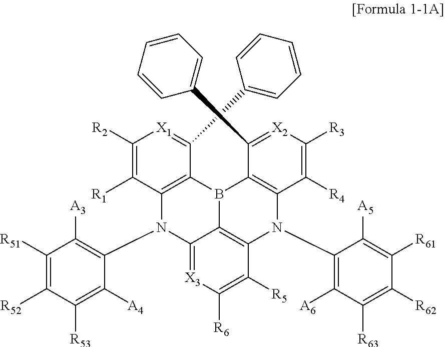

In Formula 1-1A, X₁ to X₃ and R₁ to R₆ are each the same as defined in Formula 1. In Formula 1-1A, A₃ is not bonded to R₁ and R₅₁ to form a ring, and A₄ is not bonded to X₃ and R₅₃ to form a ring. In Formula 1-1A, A₅ is not bonded to R₄ and R₆₁ to form a ring, and A₆ is not bonded to R₅ and R₆₃ to form a ring. For example, A₃ and A₄ are not bonded to adjacent groups (R₁, R₅₁, X₃, and R₅₃) to form a ring, or A₅ and A₆ are not bonded to adjacent groups (R₄, R₆₁, R₅, and R₆₃) to form a ring. For example, A₃ and A₄ are not bonded to adjacent groups (R₁, R₅₁, X₃, and R₅₃) to form a ring, and A₅ and A₆ are not bonded to adjacent groups (R₄, R₆₁, R₅, and R₆₃) to form a ring.

In Formula 1-1A, at least one of A₃ to A₆ may each independently be a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in Formula 1-1A, at least one of A₃ to A₆ may not be a hydrogen atom.

In Formula 1-1A, the remainder of A₃ to A₆ may each independently be a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, A₃, A₄, As, and A₆ may each independently be a substituted or unsubstituted phenyl group.

In Formula 1-1A, R₅₁ to R₅₃ and R₆₁ to R₆₃ may each independently be a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in Formula 1-1A, R₅₂ and R₆₂ may be the same. In Formula 1-1A, R₅₂ and R₆₂ may each independently be a hydrogen atom, an unsubstituted t-butyl group, or an unsubstituted phenyl group.

In an embodiment, the polycyclic compound represented by Formula 1 may be a compound represented by any one of Formulas 1-1X to 1-3X. Formulas 1-1X to 1-3X each represent specific configurations of X₁ to X₃ in Formula 1. Formula 1-1X represents a case in which X₁ to X₃ are each C(R₇), and each R₇ is a hydrogen atom in Formula 1. Formula 1-2X represents a case in which X₁ and X₂ are each N, X₃ is C(R₇), and R₇ is a hydrogen atom in Formula 1. Formula 1-3X shows a case in which X₃ is N, X₁ and X₂ are each C(R₇), and each R₇ is a hydrogen atom in Formula 1.

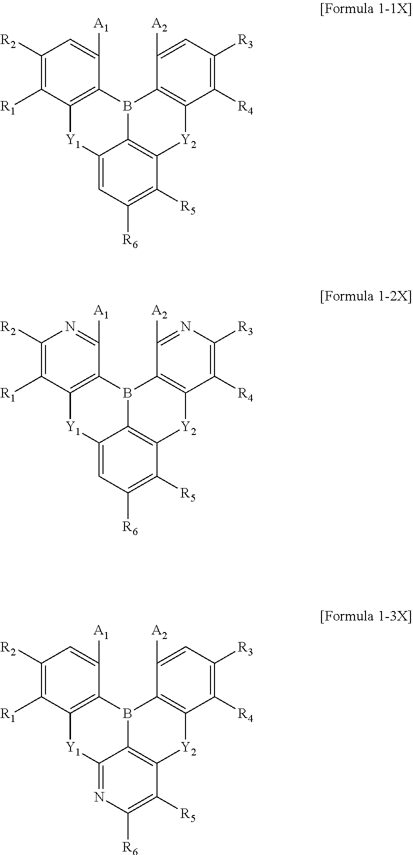

In Formulas 1-1X to 1-3X, A₁, A₂, Y₁, Y₂, and R₁ to R₆ are each the same as defined in Formula 1.

A polycyclic compound according to an embodiment may be any one selected from Compound Group 1. A light emitting element ED according to an embodiment may include at least one selected from Compound Group 1. In Compound Group 1, tBu is a t-butyl group, and D is a deuterium atom.

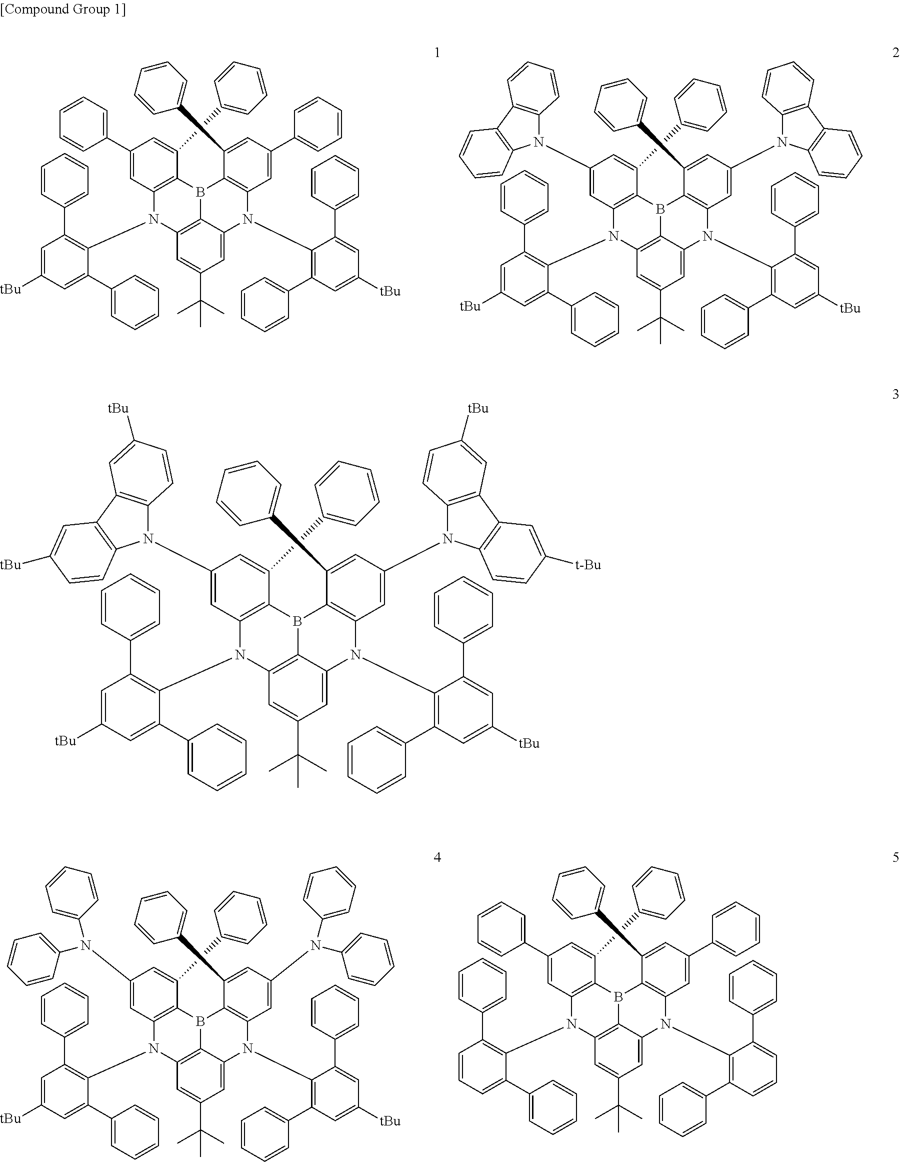

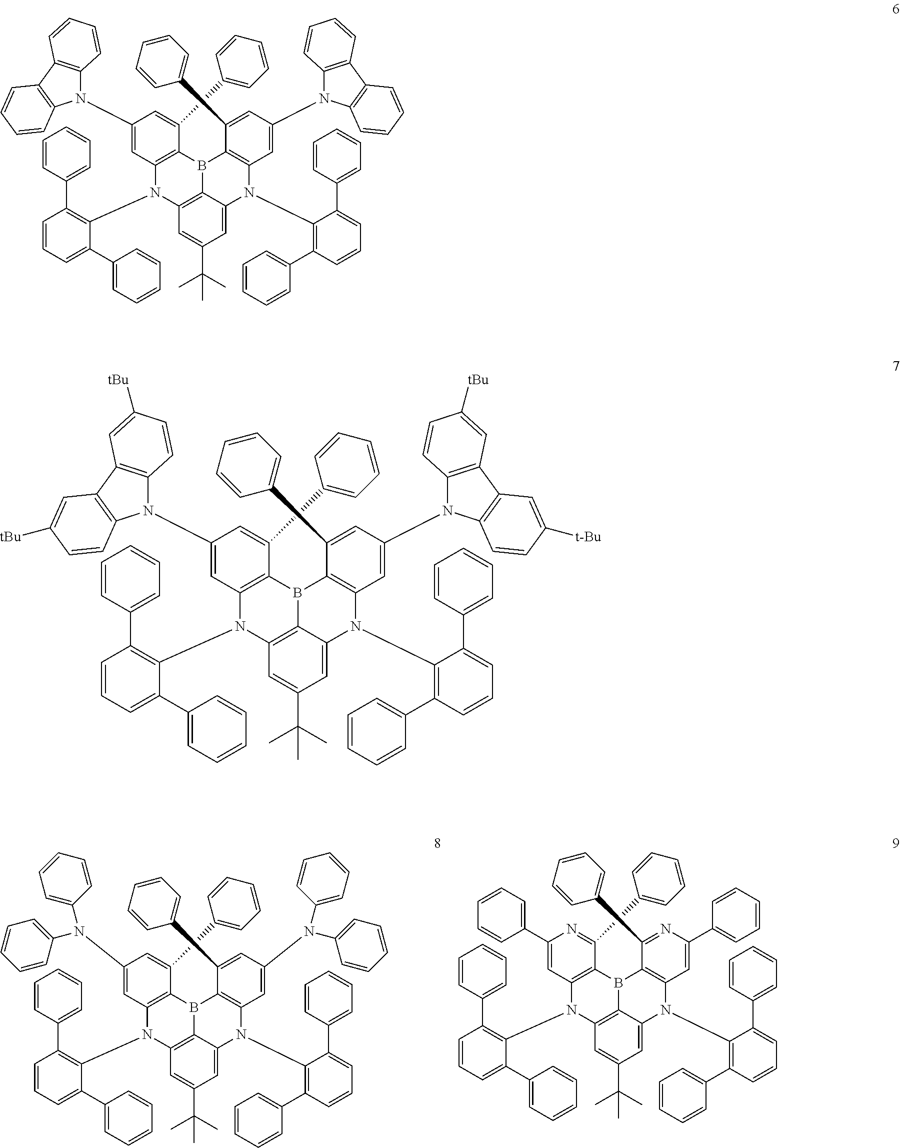

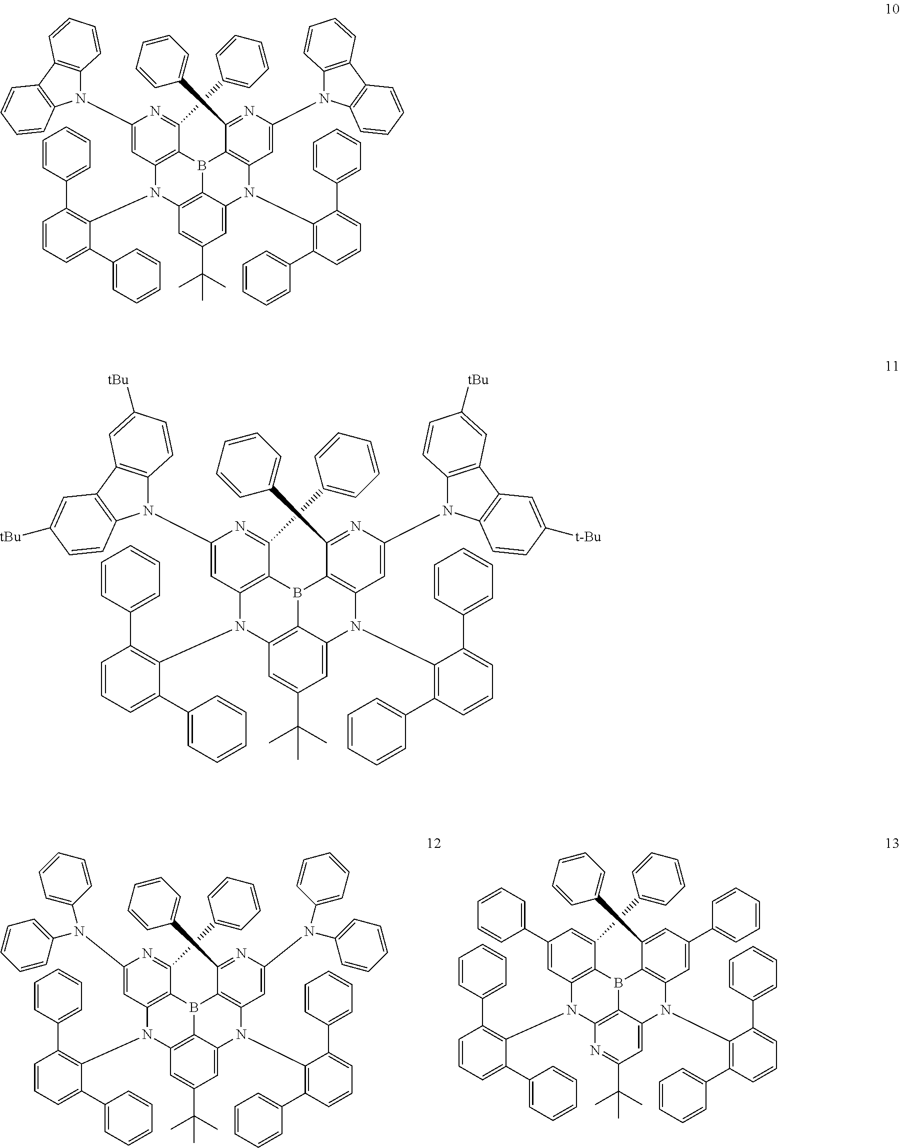

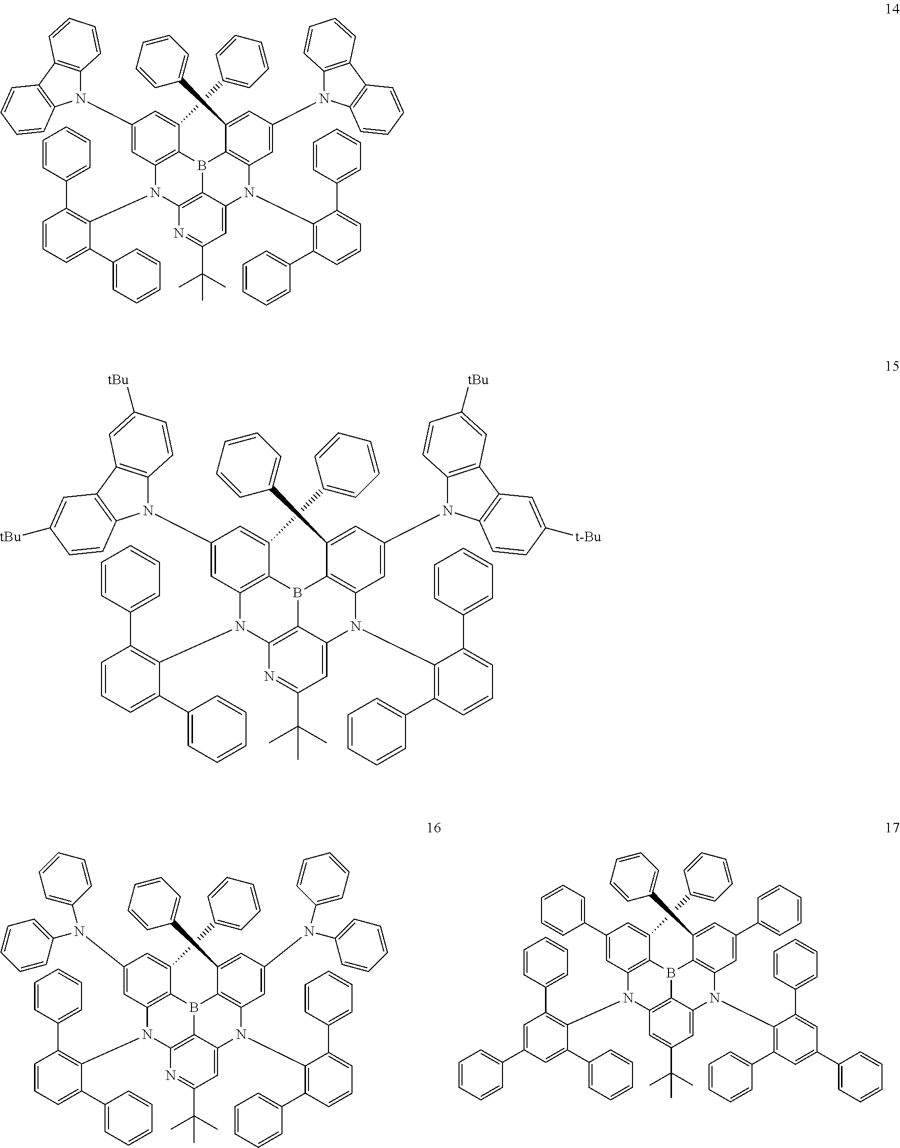

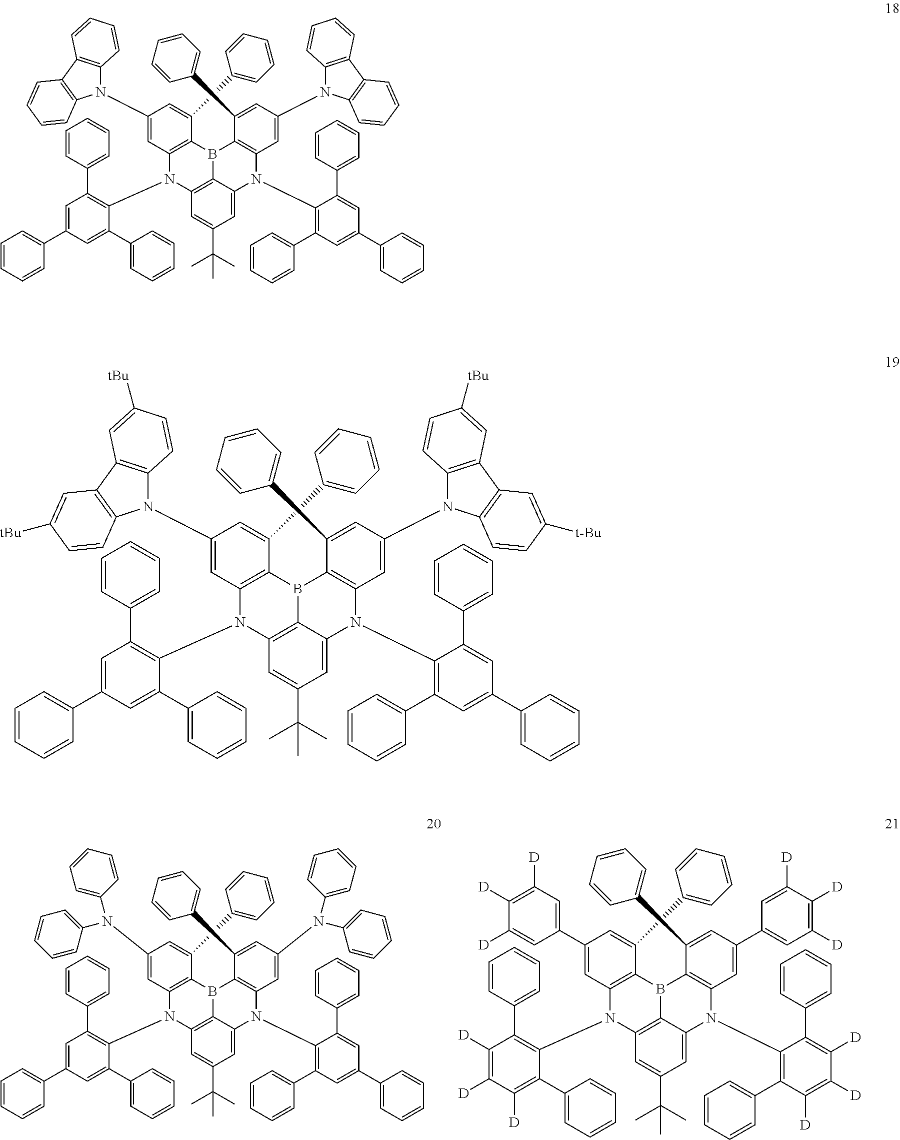

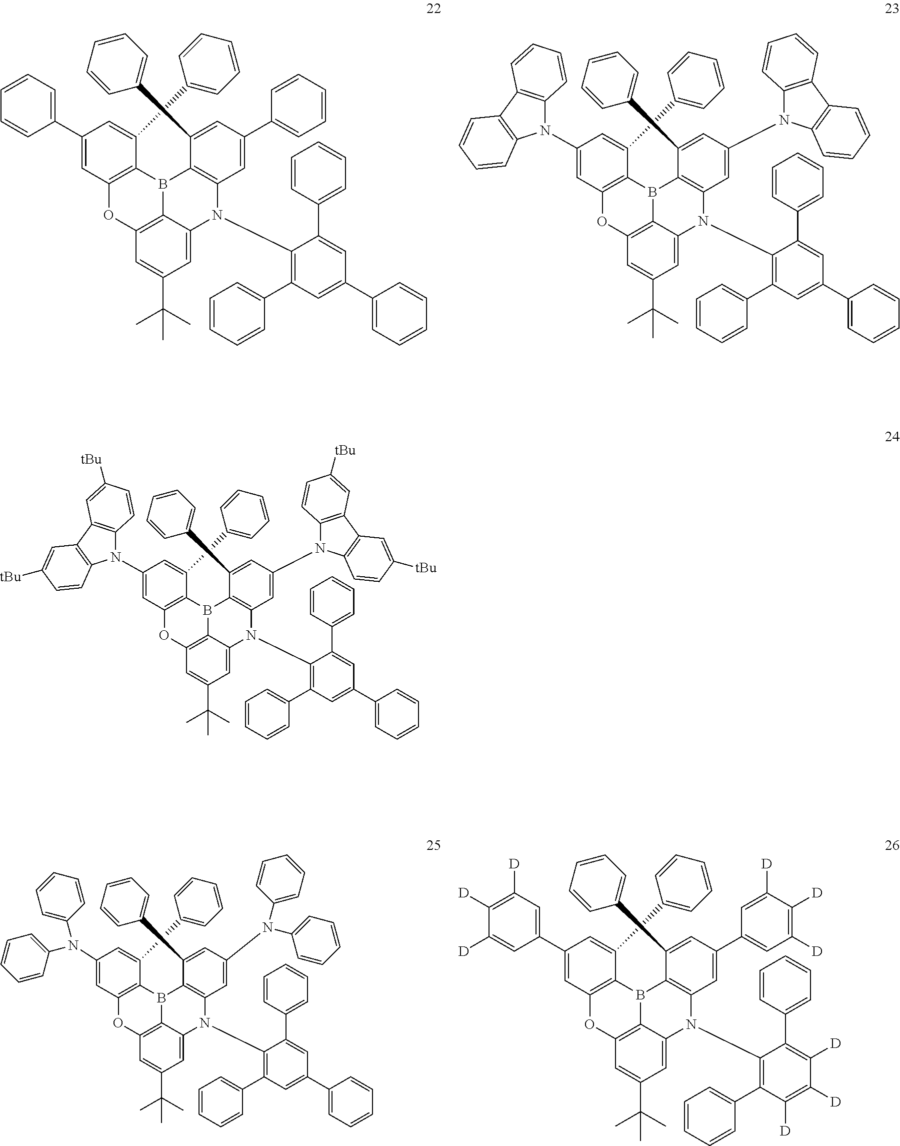

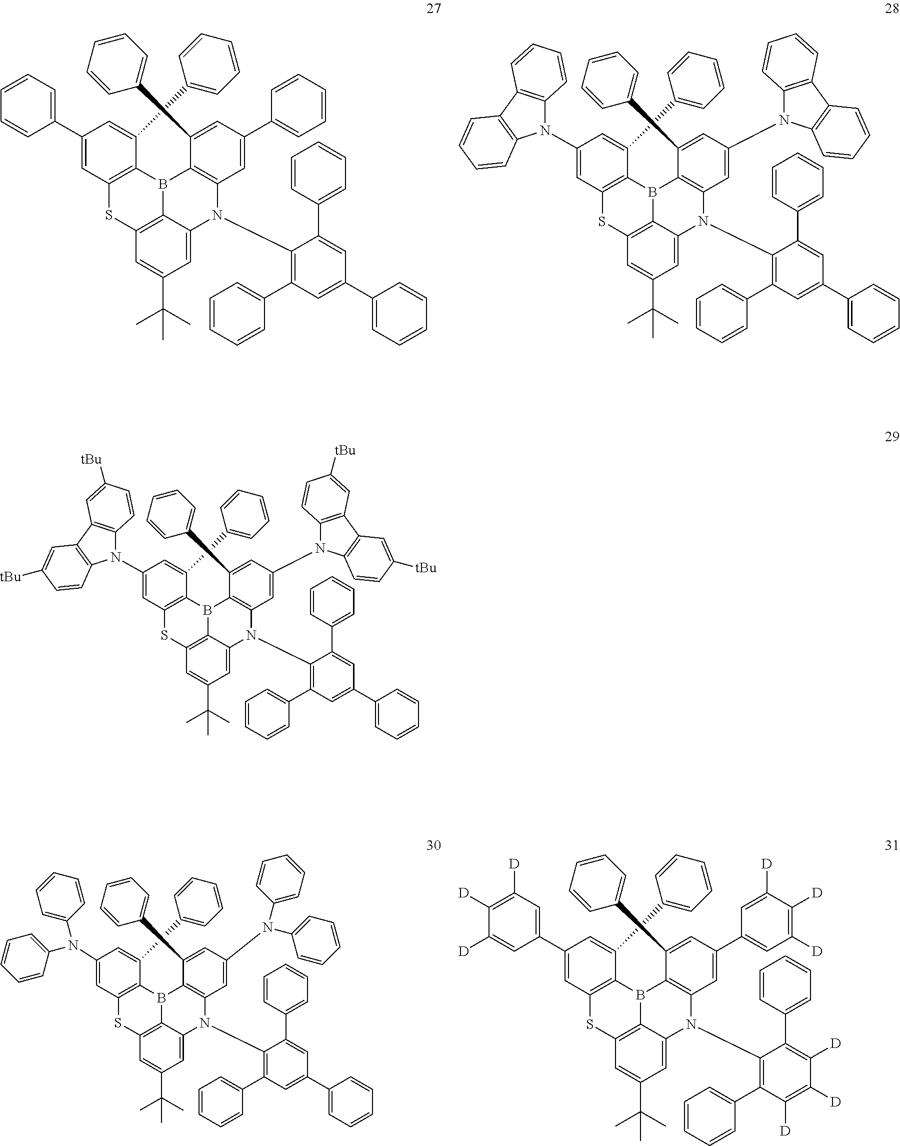

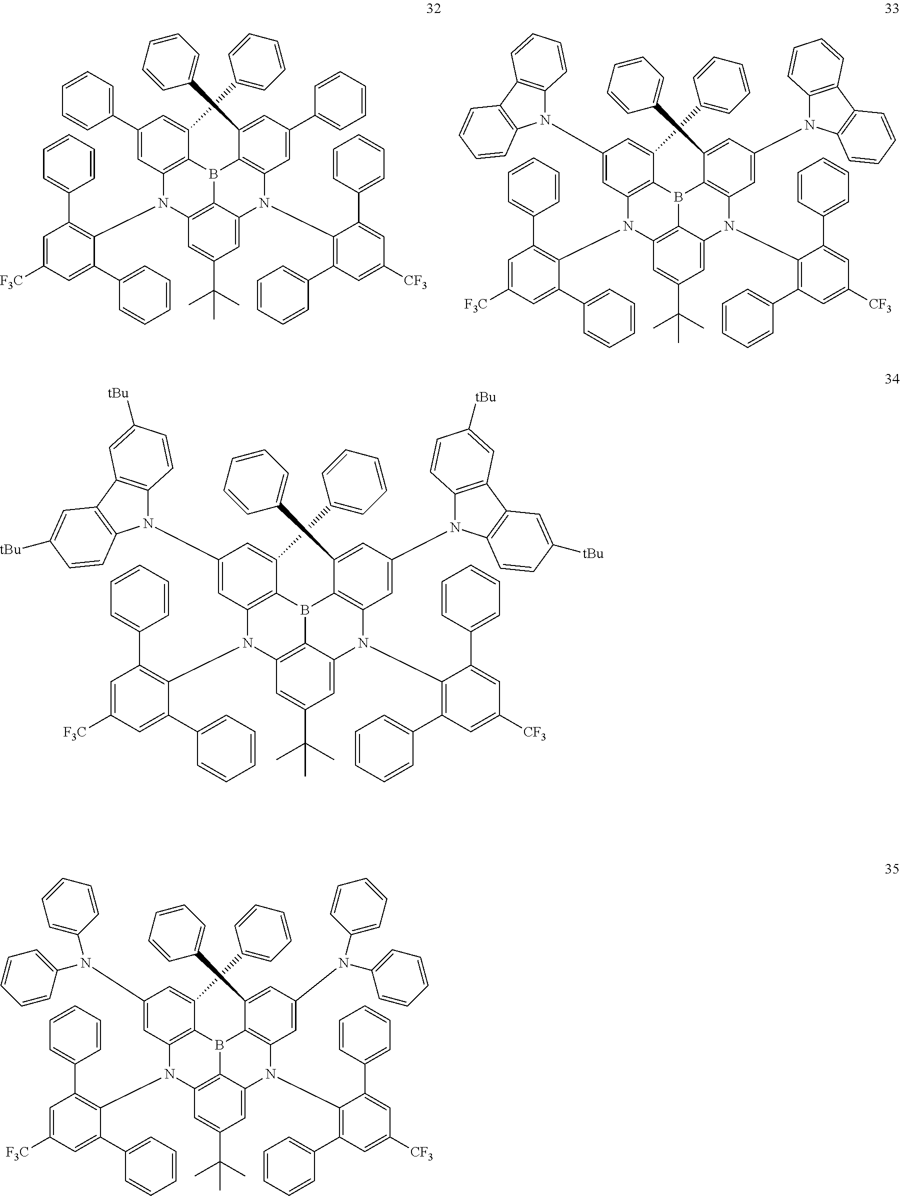

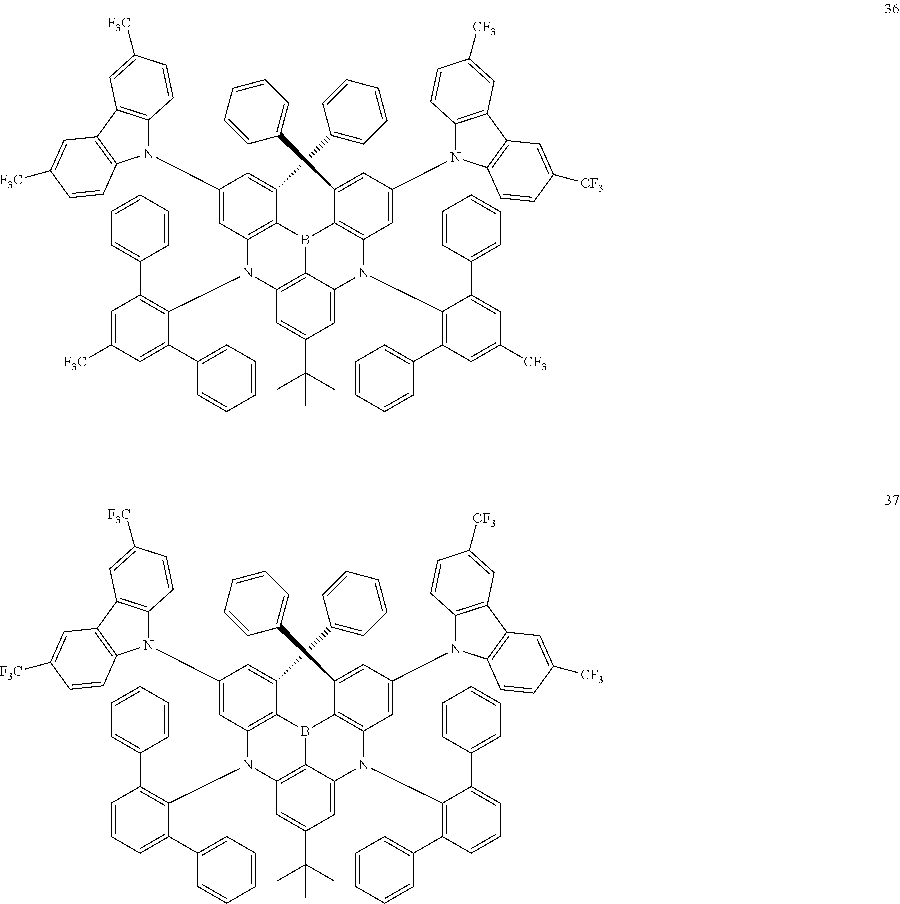

The polycyclic compound according to an embodiment may include a fused ring of five rings containing B as a ring-forming atom and two phenyl groups bonded to the fused ring of five rings and adjacent to each other. The fused ring of five rings may correspond to a DABNA structure. The polycyclic compound may include a structure represented by Formula Z1. In Formula Z1, P1 and P2 are marked to indicate two phenyl groups which are adjacent to each other. In Formula Z1, Y₁ may be O, S, or N(Rₐ), wherein Rₐ may be a substituted phenyl group including a substituent at an ortho position with respect to N. In Formula Z1, Y₁ may be the same as described for Y₁ as in Formula 1.

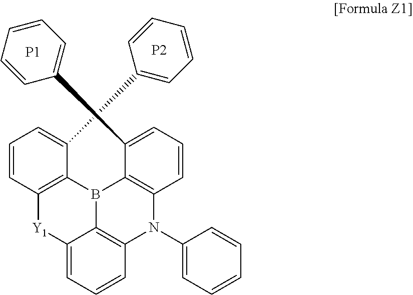

A phenyl group is bonded to a fused ring of five rings containing B as a ring-forming atom, and the skeleton of the fused ring may thus be protected through the phenyl group. Accordingly, in the polycyclic compound, intermolecular interaction is prevented, and thus Dexter energy transfer may not be caused. When the Dexter energy transfer is caused due to the intermolecular interaction in the compound included in an emission layer, compound deterioration and exciton decay take place, thereby reducing the efficiency and lifespan of light emitting elements.

In the polycyclic compound according to an embodiment, a phenyl group bonded to a fused ring of five rings containing B as a ring-forming atom protects the fused ring of five rings, thereby preventing intermolecular interaction. The polycyclic compound according to an embodiment may be included in the light emitting element ED, thereby contributing to improvement of a roll-off phenomenon at high luminance. Accordingly, the light emitting element ED including the polycyclic compound according to an embodiment may exhibit high efficiency and long lifespan.

The polycyclic compound according to an embodiment may be a multiple resonance (MR) type dopant. The emission layer EML including the polycyclic compound as a multiple resonance (MR) type dopant may emit light having a narrow full width at half maximum (FWHM). For example, the polycyclic compound according to an embodiment may emit light having a full width at half maximum equal to or less than about 22 nm. Accordingly, the light emitting element ED including the polycyclic compound may emit light with enhanced color purity.

In an embodiment, the emission layer EML may be a delayed fluorescence emission layer including a host and a dopant. For example, the emission layer EML may emit light through a thermally activated delayed fluorescence (TADF) mechanism. The dopant of the emission layer EML may include the polycyclic compound according to an embodiment. The polycyclic compound according to an embodiment may be a thermally activated delayed fluorescence material. The polycyclic compound may emit blue light having a central emission wavelength in a range of about 440 nm to about 480 nm. For example, the polycyclic compound may emit light having a central emission wavelength in a range of about 450 nm to about 470 nm.

In an embodiment, the emission layer EML may include a second compound represented by Formula HT-1. For example, the second compound may be used as a hole transporting host material of the emission layer EML.

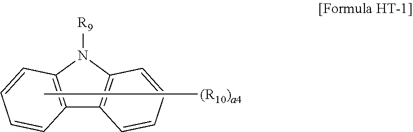

In Formula HT-1, a4 may be an integer from 0 to 8. When a4 is 2 or greater, multiple R₁₀ groups may all be the same, or at least one may be different from the others. In Formula HT-1, R₉ and R₁₀ may each independently be a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms. For example, R₉ may be a substituted phenyl group, an unsubstituted dibenzofuran group, or a substituted fluorenyl group. For example, R₁₀ may be a substituted or unsubstituted carbazole group.

The second compound may be selected from Compound Group 2. The light emitting element ED of an embodiment may include any one selected from Compound Group 2.

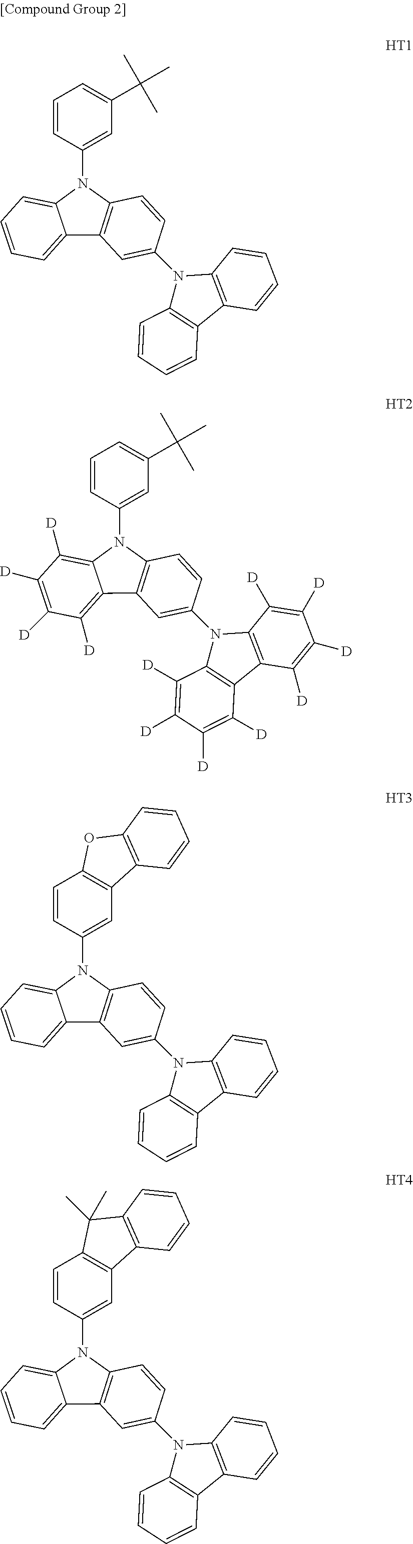

In an embodiment, the emission layer EML may include a third compound represented by Formula ET-1. For example, the third compound may be used as an electron transporting host material of the emission layer EML.

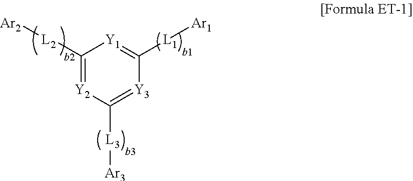

In Formula ET-1, at least one of Y₁ to Y₃ may be N, the remainder of Y₁ to Y₃ may each independently be C(R_{b}), and R_{b} may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms.

In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₁ to Ar₃ may each independently be a substituted or unsubstituted phenyl group or a substituted or unsubstituted carbazole group.

The third compound may be selected from Compound Group 3. The light emitting element ED of an embodiment may include any one selected from Compound Group 3.

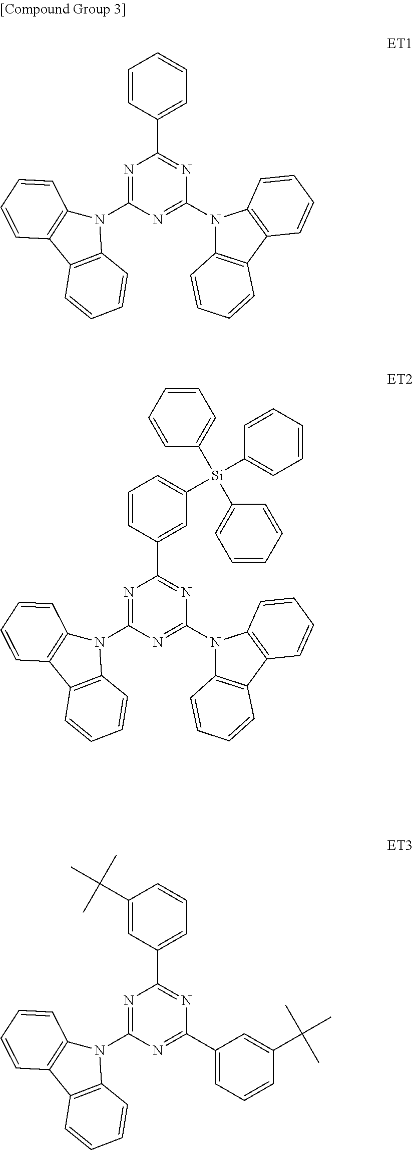 [SMILES: c1ccc(-c2nc(-n3c4ccccc4c4ccccc43)nc(-n3c4ccccc4c4ccccc43)n2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; CC(C)(C)c1cccc(-c2nc(-c3cccc(C(C)(C)C)c3)nc(-n3c4ccccc4c4ccccc43)n2)c1]

For example, the emission layer EML may include a second compound and a third compound, and the second compound and the third compound may form an exciplex. In the emission layer EML, a hole transporting host and an electron transporting host may form an exciplex. A triplet energy of the exciplex formed by the hole transporting host and the electron transporting host corresponds to a difference in energy level between a Lowest Unoccupied Molecular Orbital (LUMO) of the electron transporting host and a Highest Occupied Molecular Orbital (HOMO) of the hole transporting host.

For example, a triplet energy level (T1) of the exciplex formed by the hole transporting host and the electron transporting host may have an absolute value in a range of about 2.4 eV to about 3.0 eV. The triplet energy level of the exciplex may have a value smaller than the energy gap of each host material. The exciplex may have a triplet energy level equal to or less than about 3.0 eV, which is an energy gap between the hole transporting host and the electron transporting host. However, this is presented only as an example, and embodiments are not limited thereto.

The emission layer EML may include a fourth compound represented by Formula M-b. The fourth compound may be referred to as a phosphorescence sensitizer. For example, the fourth compound may be used as an auxiliary dopant or as a dopant of the emission layer EML. When the fourth compound is used as an auxiliary dopant of the emission layer EML, energy may be transferred from the fourth compound to the first compound to emit light. When the fourth compound is used as a dopant of the emission layer EML, phosphorescence light emission may take place. For example, the fourth compound may emit phosphorescence, or the fourth compound may transfer energy to the first compound as an auxiliary dopant. However, this is presented only as an example, and embodiments are not limited thereto.

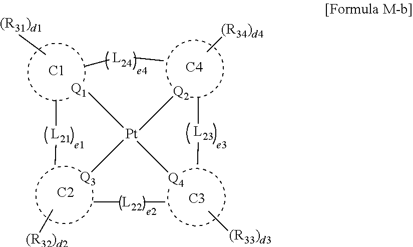

In Formula M-b, Q₁ to Q₄ may each independently be C or N. In Formula M-b, C1 to C4 may each independently be a substituted or unsubstituted hydrocarbon ring group having 5 to 30 ring-forming carbon atoms, or a substituted or unsubstituted heterocyclic group having 2 to 30 ring-forming carbon atoms.

In Formula M-b, e1 to e4 may each independently be 0 or 1, and L₂₁ to L₂₄ may each independently be a direct linkage,

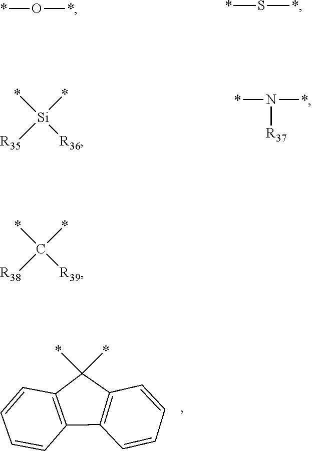

a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms.

In Formula M-b, d1 to d4 may each independently be an integer from 0 to 4. When d1 is 2 or greater, multiple R₃₁ groups may all be the same, or at least one may be different from the others. When d2 is 2 or greater, multiple R₃₂ groups may all be the same, or at least one may be different from the others. When d3 is 2 or greater, multiple R₃₃ groups may all be the same, or at least one may be different from the others. When d4 is 2 or greater, multiple R₃₄ groups may all be the same, or at least one may be different from the others.

In Formula M-b, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring.

The fourth compound may be selected from Compound Group 4. The light emitting element ED of an embodiment may include any one selected from Compound Group 4.

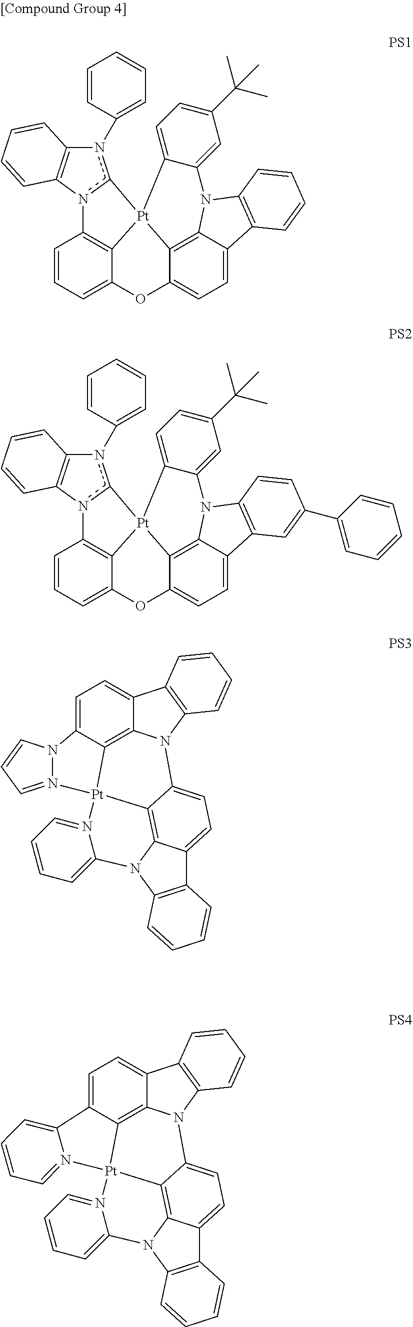

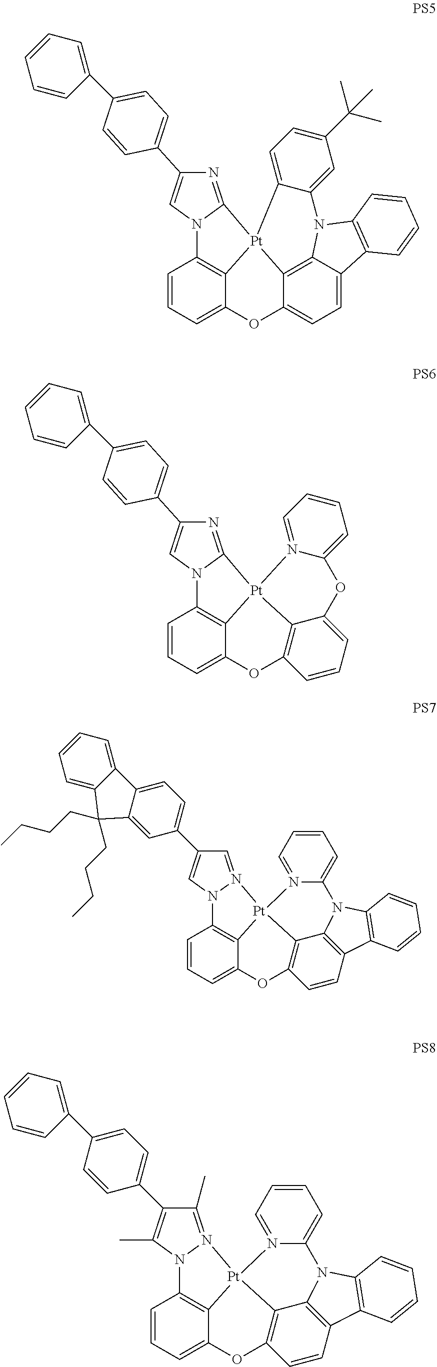

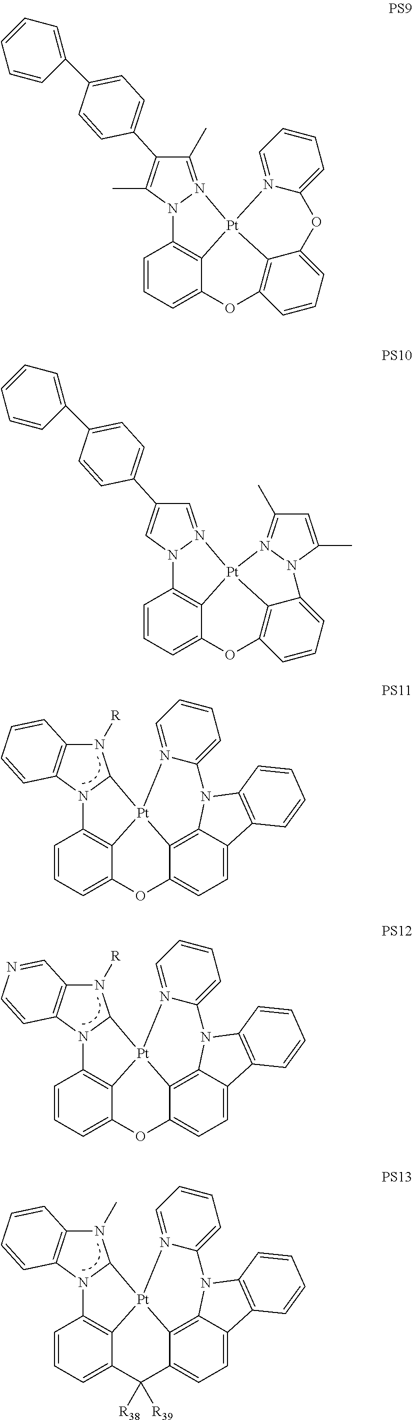

In Compound Group 4, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

The emission layer EML may have a thickness in a range of about 100 Å to about 1.000 Å. For example, the emission layer EML may have a thickness in a range of about 100 Å to about 300 Å. The emission layer EML may be a layer formed of a single material, a layer formed of different materials, or a structure including multiple layers formed of different materials.

The emission layer EML may further include compounds that will be described later, in addition to the first to fourth compounds.

The emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazolyl-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi). However, embodiments are not limited thereto, and for example, tris(8-hydroxyquinolino)aluminum (Alq₃), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be used as a host material.

In the light emitting element ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED, the emission layer EML may include a host and a dopant. The emission layer EML may include a compound represented by Formula E-1. The compound represented by Formula E-1 may be used as a fluorescent host material.

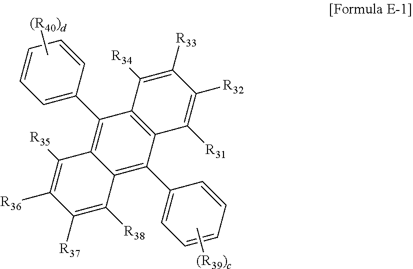

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

The compound represented by Formula E-1 may be any one selected from Compounds E1 to E19.

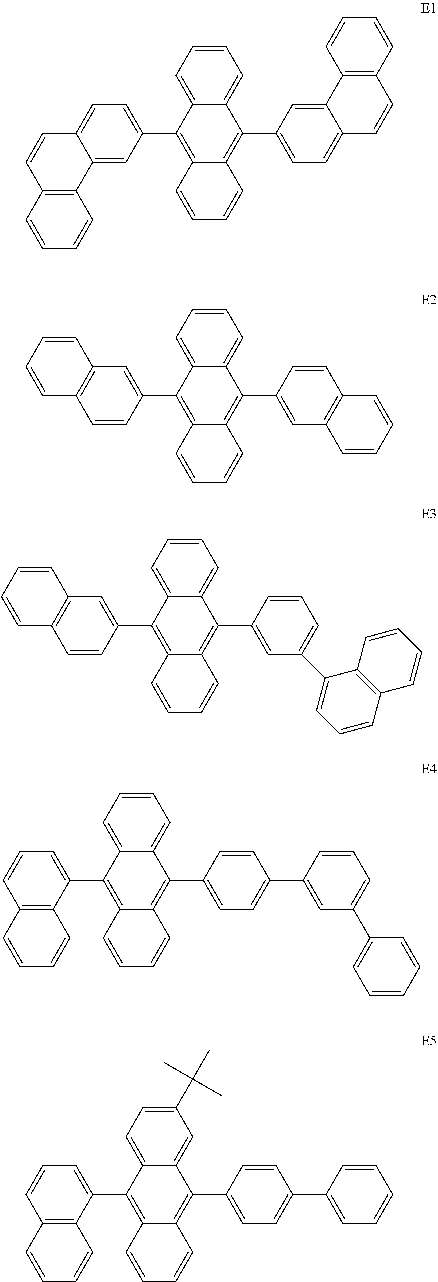

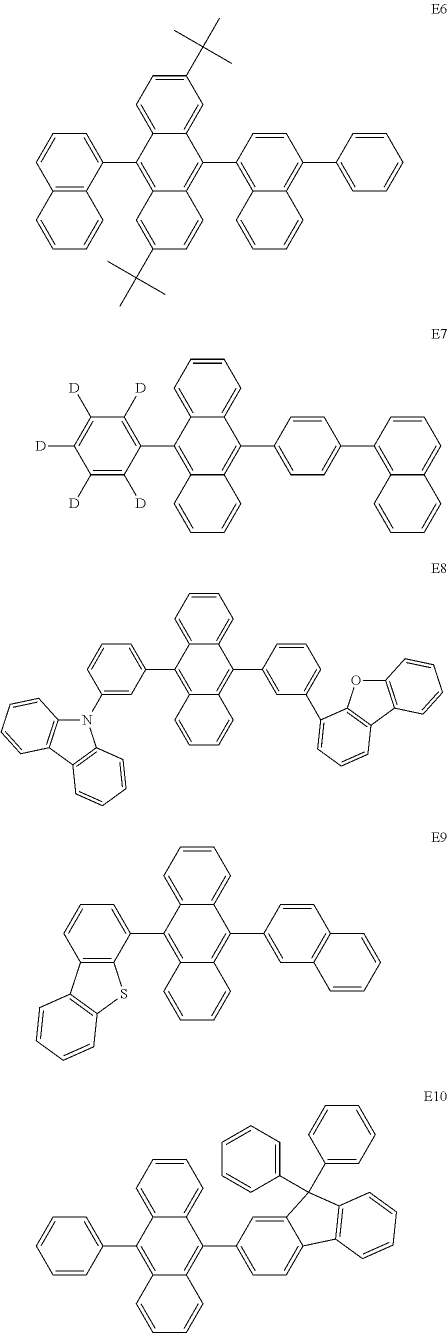

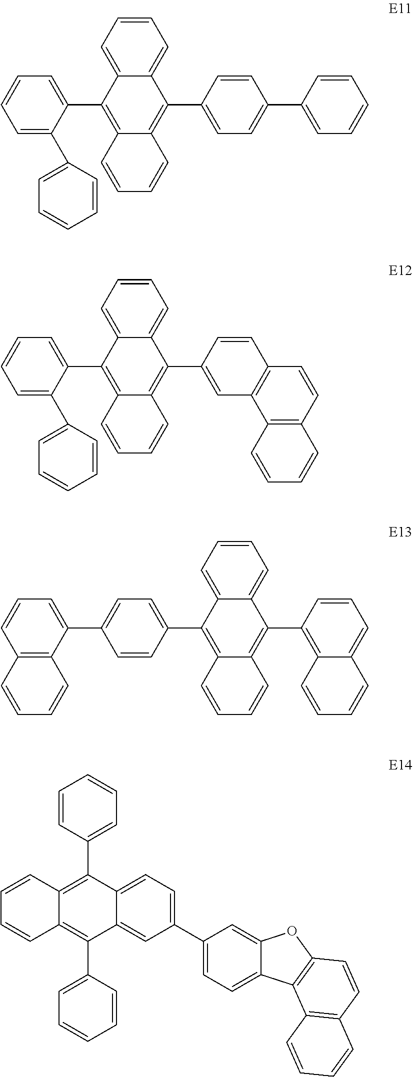

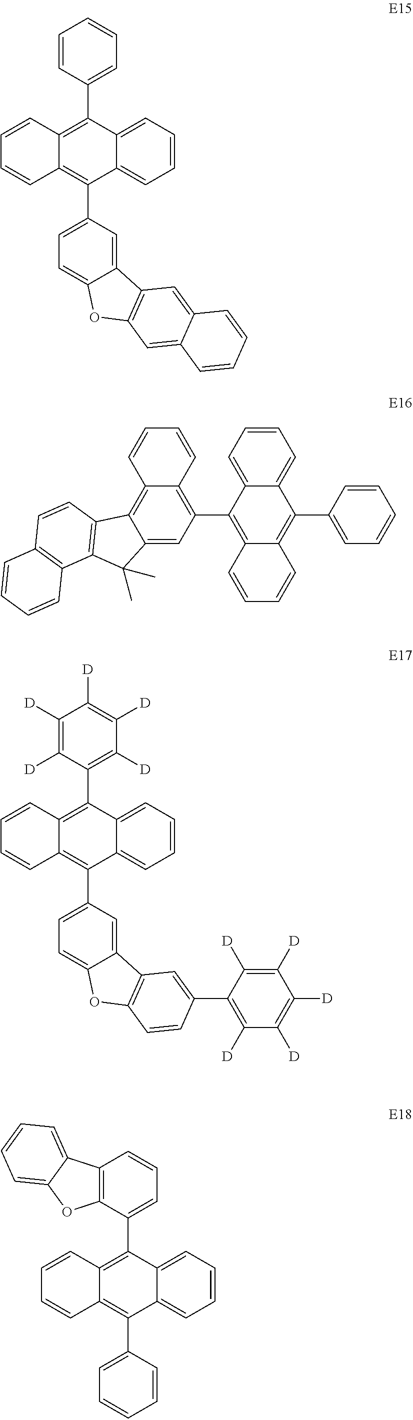

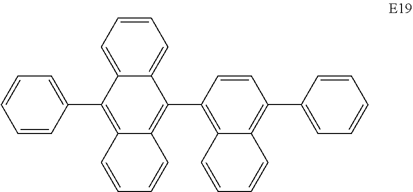 [SMILES: c1ccc(-c2ccc(-c3c4ccccc4c(-c4ccccc4)c4ccccc34)c3ccccc23)cc1]

The emission layer EML may include a compound represented by Formula E-2a or Formula E-2b. The compound represented by Formula E-2a or Formula E-2b may be used as a phosphorescent host material.

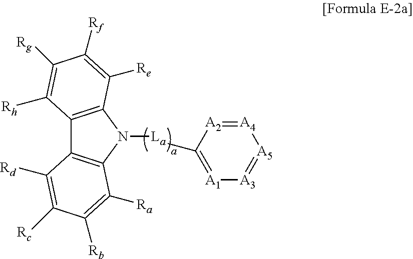

In Formula E-2a, a may be an integer from 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple Lₐ groups may each independently be a substituted or unsubstituted arylene group having 6 to 30 ring-forming carbon atoms, or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. For example, Rₐ to Rᵢ may be bonded to an adjacent group to form a hydrocarbon ring or a heterocycle including N, O, S, etc. as a ring-forming atom. In Formula E-2a, two or three of A₁ to A₅ may be N, and the remainder of A₁ to A₅ may each independently be C(R₁).

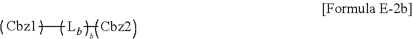

In Formula E-2b, Cbz1 and Cbz2 may each independently be an unsubstituted carbazole group or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10, and when b is 2 or greater, multiple L_{b} groups may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be any one selected from Compound Group E-2. However, the compounds listed in Compound Group E-2 are only examples, and the compound represented by Formula E-2a or Formula E-2b is not limited to Compound Group E-2.

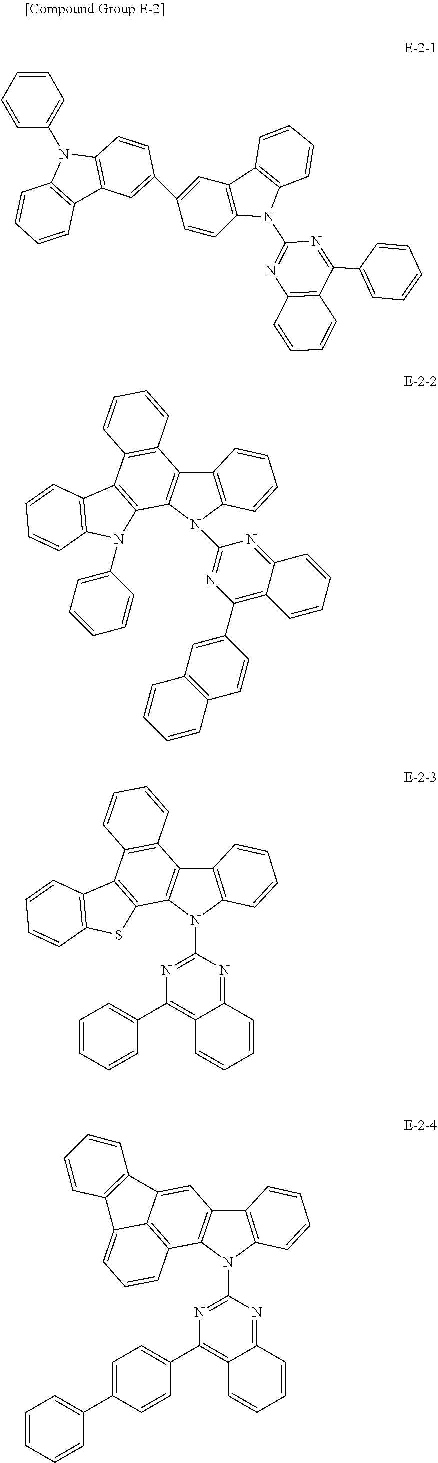 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1 ; c1ccc(-c2ccc(-c3nc(-n4c5ccccc5c5cc6c7c(cccc7c54)-c4ccccc4-6)nc4ccccc34)cc2)cc1]

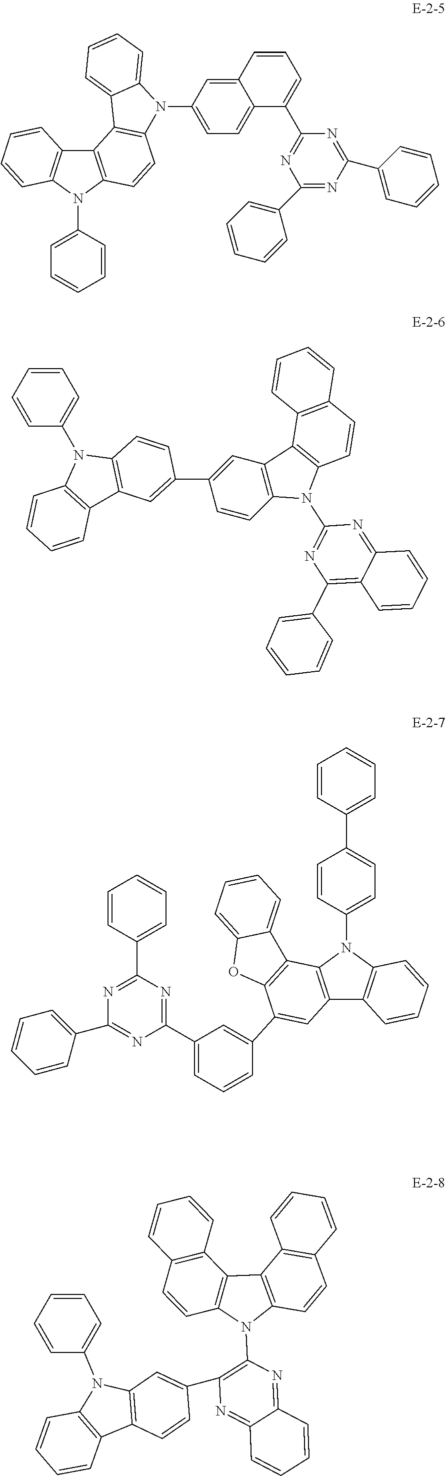 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

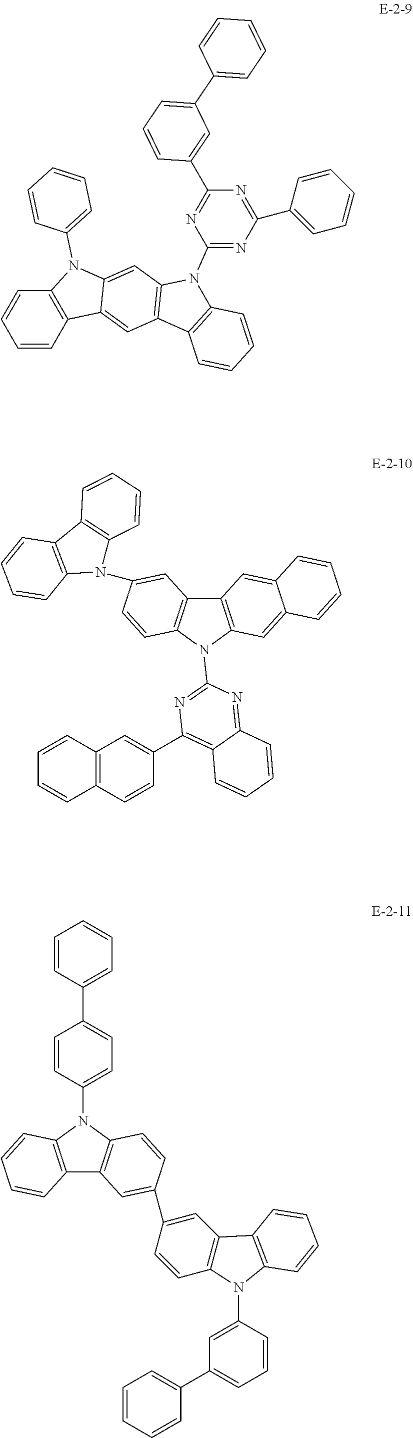 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

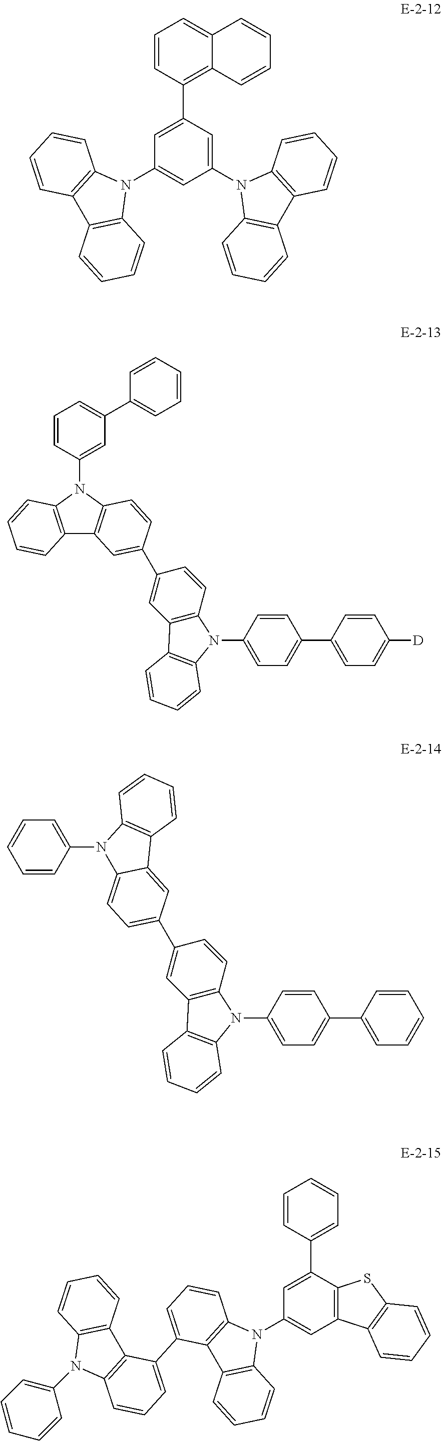 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

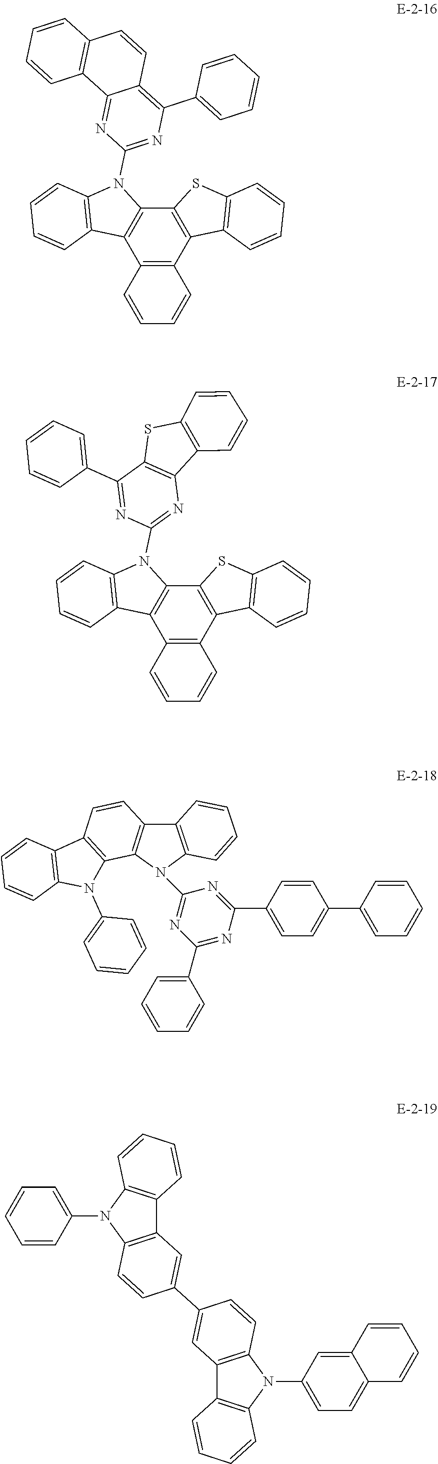 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

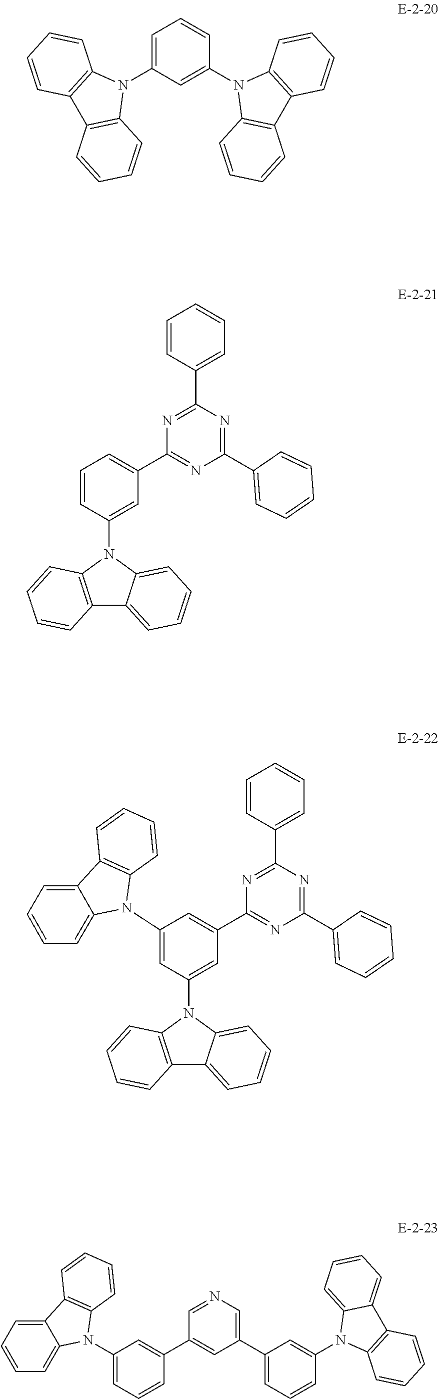 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

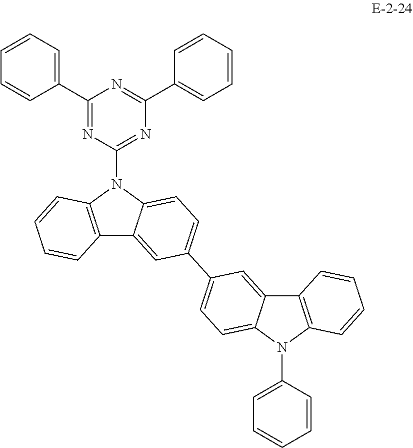 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The emission layer EML may include a compound represented by Formula M-a. The compound represented by Formula M-a may be used as a phosphorescent dopant.

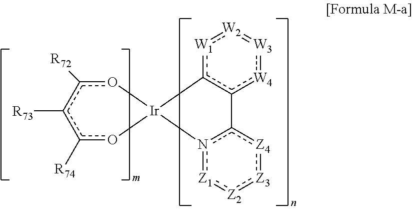

In Formula M-a, W₁ to W₄ and Z₁ to Z₄ may each independently be C(R₇₁) or N, and R₇₁ to R₇₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. In Formula M-a, m may be 0 or 1, and n may be 2 or 3. In Formula M-a, when m is 0, n may be 3, and when m is 1, n may be 2.

The compound represented by Formula M-a may be any one selected from Compounds M-a1 to M-a25. However, Compounds M-a1 to M-a25 are only presented as examples, and the compound represented by Formula M-a is not limited to Compounds M-a1 to M-a25.

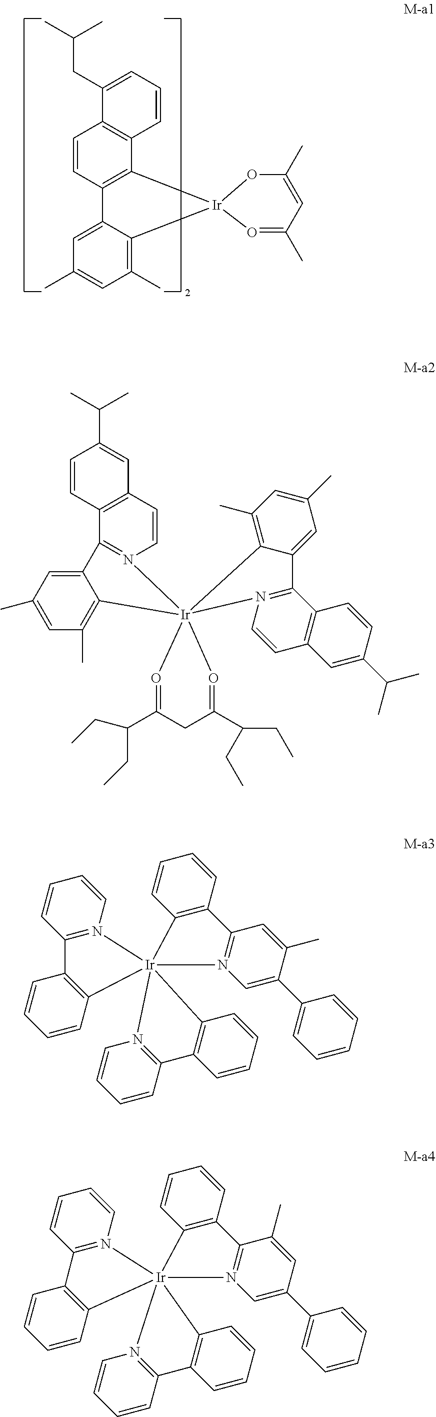

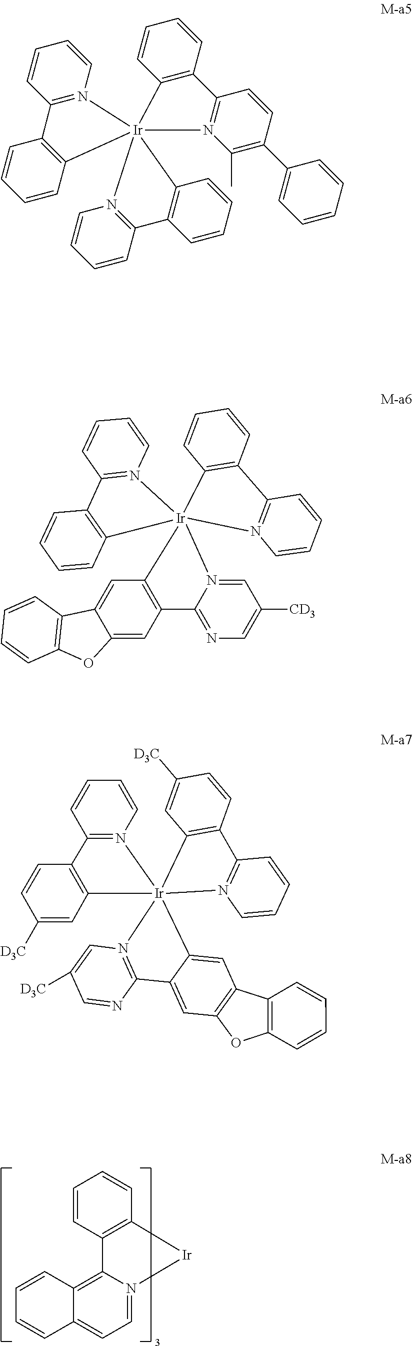

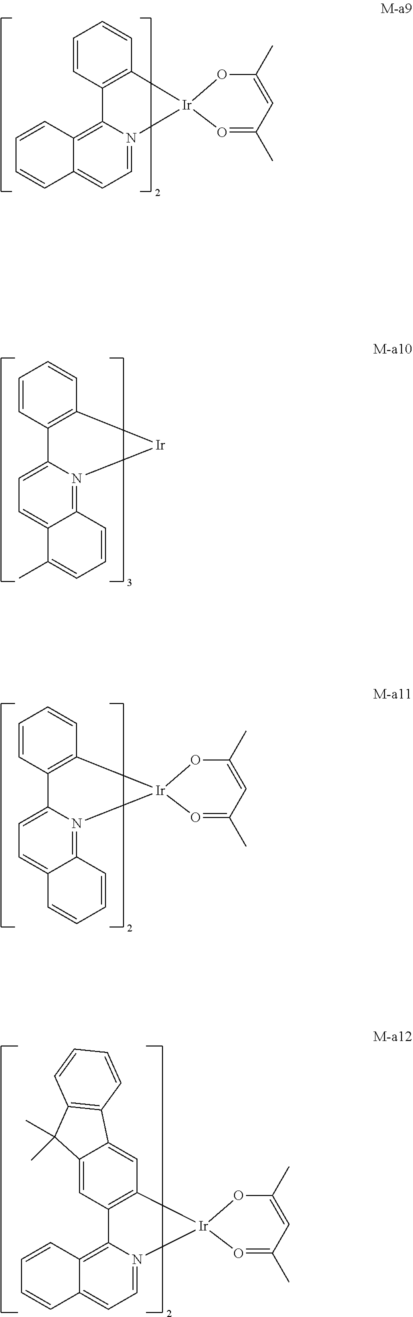

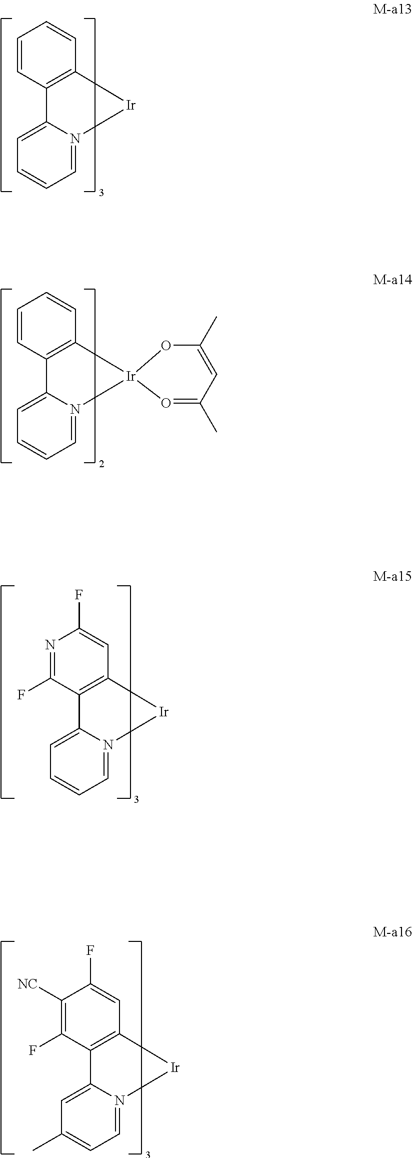

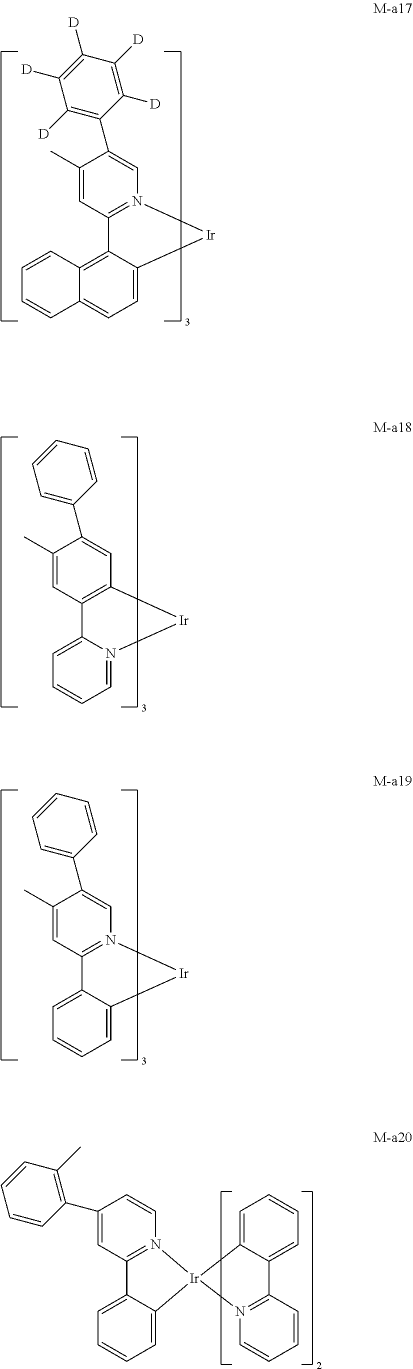

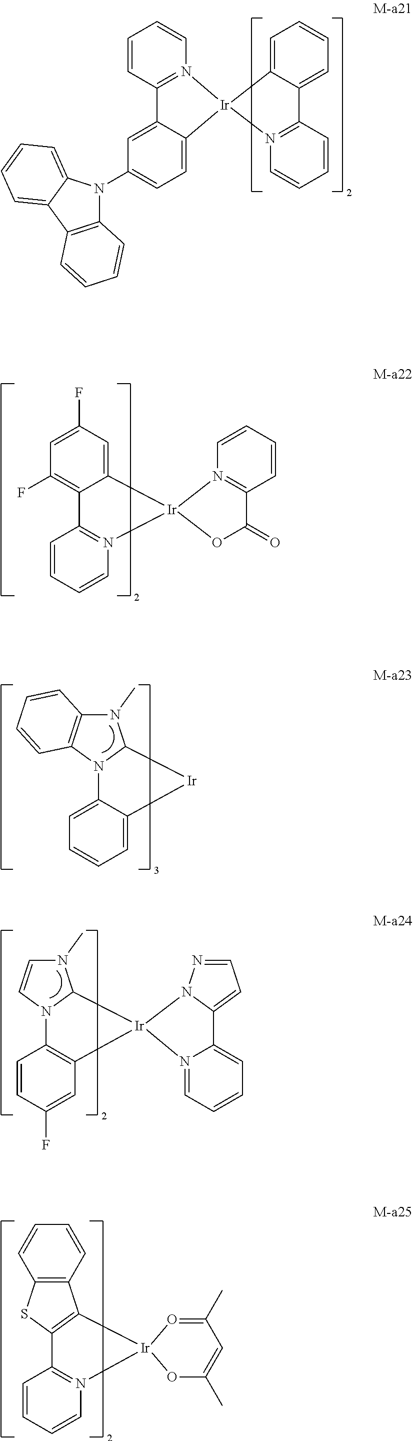

Compound M-a1 and Compound M-a2 may each be used as a red dopant material, and Compounds M-a3 to M-a7 may each be used as a green dopant material.

The emission layer EML may include a compound represented by Formula F-a or Formula F-b. The compounds represented by Formula F-a or Formula F-b may be used as a fluorescent dopant material.

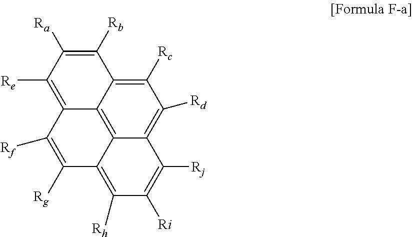

In Formula F-a, two of Rₐ to Rⱼ may each independently be substituted with a group represented by *—NAr₁Ar₂. The remainder of Rₐ to Rⱼ which are not substituted with the group represented by *—NAr₁Ar₂ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In the group represented by *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Aᵣ or Ar₂ may be a heteroaryl group including O or S as a ring-forming atom.

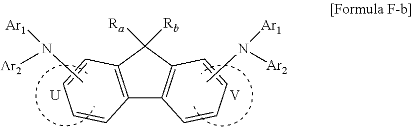

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, or may be bonded to an adjacent group to form a ring. In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, in Formula F-b, when the number of U or V is 1, a fused ring may be present at a portion indicated by U or V, and when the number of U or V is 0, a fused ring may not be present at the portion indicated by U or V. When the number of U is 0 and the number of V is 1, or when the number of U is 1 and the number of V is 0, a fused ring having a fluorene core of Formula F-b may be a cyclic compound having four rings. When U and V are each 0, a fused ring having a fluorene core of Formula F-b may be a cyclic compound having three rings. When U and V are each 1, a fused ring having a fluorene core of Formula F-b may be a cyclic compound having five rings.

The emission layer EML may include, as a dopant material of the related art, styryl derivatives (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), etc.

The emission layer EML may include a phosphorescent dopant material of the related art. For example, as a phosphorescent dopant, a metal complex including iridium (Ir), platinum (Pt), osmium (Os), gold (Au), titanium (Ti), zirconium (Zr), hafnium (Hf), europium (Eu), and terbium (Tb), or thulium (Tm) may be used. For example, iridium(III) bis(4,6-difluorophenylpyridinato-N,C2′)picolinate (FIrpic), bis(2,4-difluorophenylpyridinato)-tetrakis(1-pyrazolyl)borate iridium(III) (Fir6), platinum octaethyl porphyrin (PtOEP), etc. may be used as a phosphorescent dopant. However, embodiments are not limited thereto.

Referring back to FIGS. 3 to 6, the first electrode EL1 has conductivity. The first electrode EL1 may include a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. The first electrode may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

When the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the first electrode EL1 may have a three-layer structure of ITO/Ag/ITO, but is not limited thereto. However, embodiments are not limited thereto, and the first electrode EL1 may include the above-described metal materials, a combination of two or more metal materials selected from the above-described metal materials, or oxides of the above-described metal materials. The first electrode EL1 may have a thickness in a range of about 700 Å to about 10,000 Å. For example, the first electrode EL1 may have a thickness in a range of about 1,000 Å to about 3,000 Å.

The hole transport region HTR may be provided on the first electrode EL1. The hole transport region HTR may include at least one of a hole injection layer HIL, a hole transport layer HTL, a buffer layer (not shown), a light emitting auxiliary layer (not shown), and an electron blocking layer EBL. The hole transport region HTR may have, for example, a thickness in a range of about 50 Å to about 15,000 Å.

The hole transport region HTR may be a layer formed of a single material, a layer formed of different materials, or a structure having multiple layers formed of different materials.

For example, the hole transport region HTR may have a single-layer structure formed of the hole injection layer HIL or the hole transport layer HTL, or a single-layer structure formed of a hole injection material or a hole transport material. For example, the hole transport region HTR may have a single-layer structure formed of different materials, or may have a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in it respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1.

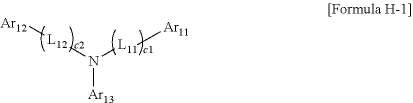

In Formula H-1, c1 and c2 may each independently be an integer from 0 to 10. In Formula H-1, L₁₁ and Lu may each independently be a direct linkage, a substituted or unsubstituted arylene group having 6 to 30 ring-forming carbon atoms, or a substituted or unsubstituted heteroarylene group having 2 to 30 ring-forming carbon atoms.

In Formula H-1, Ar₁₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In Formula H-1, Ar₁₃ may be a substituted or unsubstituted aryl group having 6 to 30 ring-forming carbon atoms.

In an embodiment, a compound represented by Formula H-1 may be a monoamine compound. In another embodiment, the compound represented by Formula H-1 may be a diamine compound in which at least one of Ar₁ to Ar₃ includes an amine group as a substituent. In still another embodiment, the compound represented by Formula H-1 may be a carbazole-based compound including a substituted or unsubstituted carbazole group in at least one of Ar₁ or Ar₂, or may be a fluorene-based compound including a substituted or unsubstituted fluorene group in at least one of Ar₁ or Ar₂.

The compound represented by Formula H-1 may be any one selected from Compound Group H. However, the compounds listed in Compound Group H are presented only as examples, and the compound represented by Formula H-1 is not limited to Compound Group H.

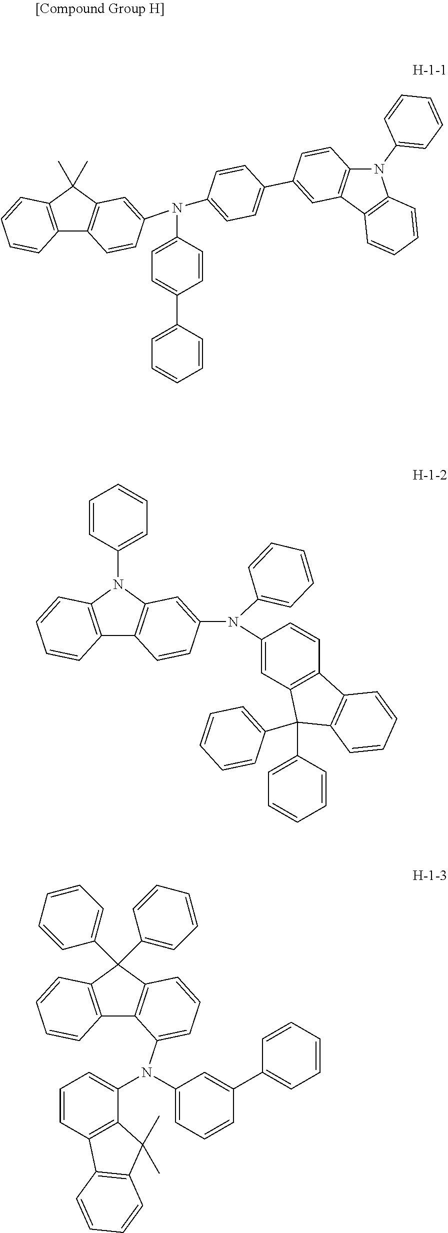 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21]

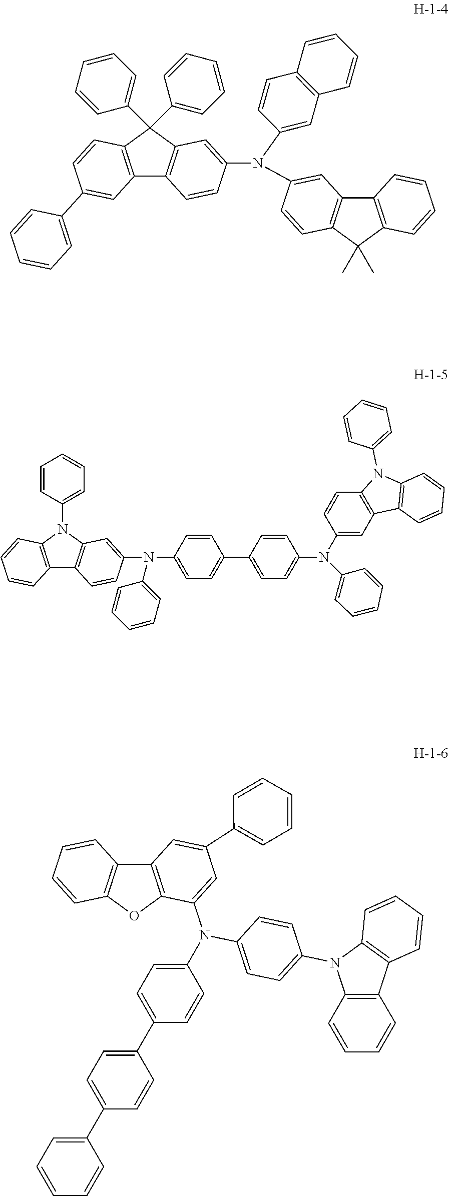 [SMILES: CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1]

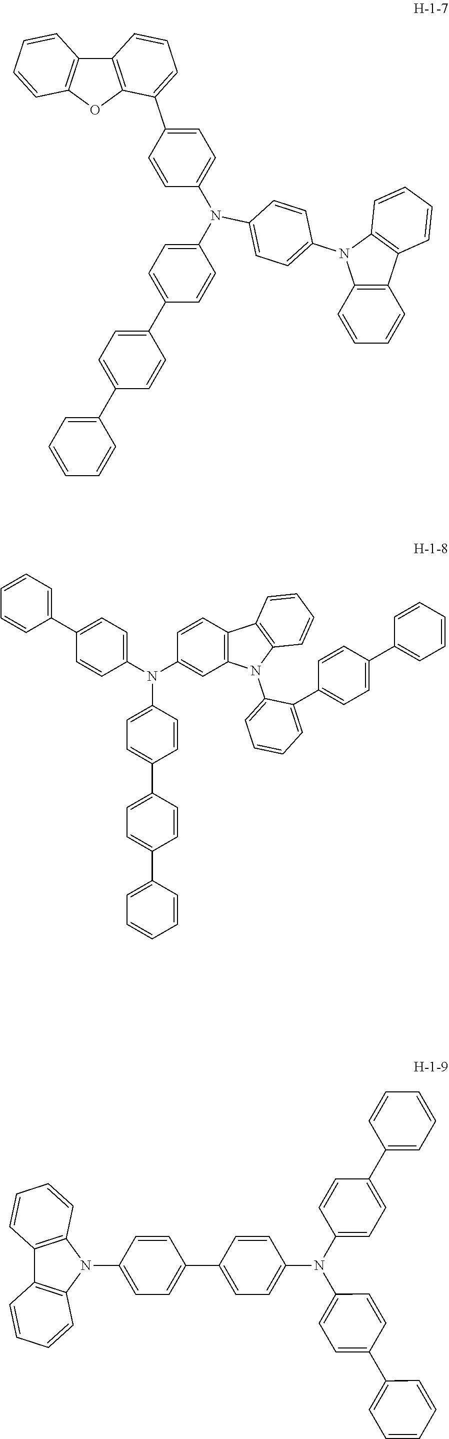 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1]

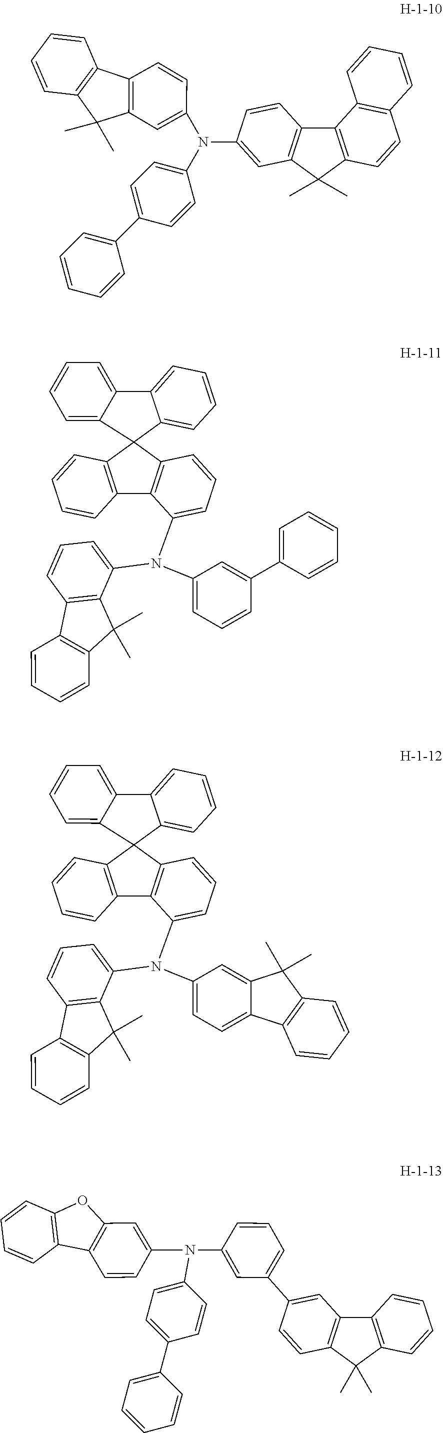 [SMILES: CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21]

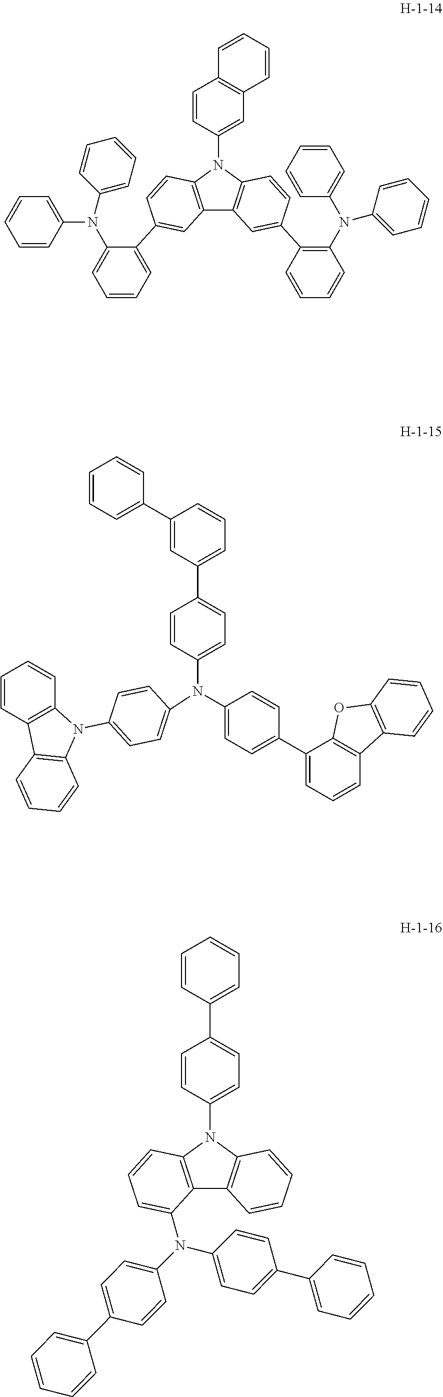 [SMILES: c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1]

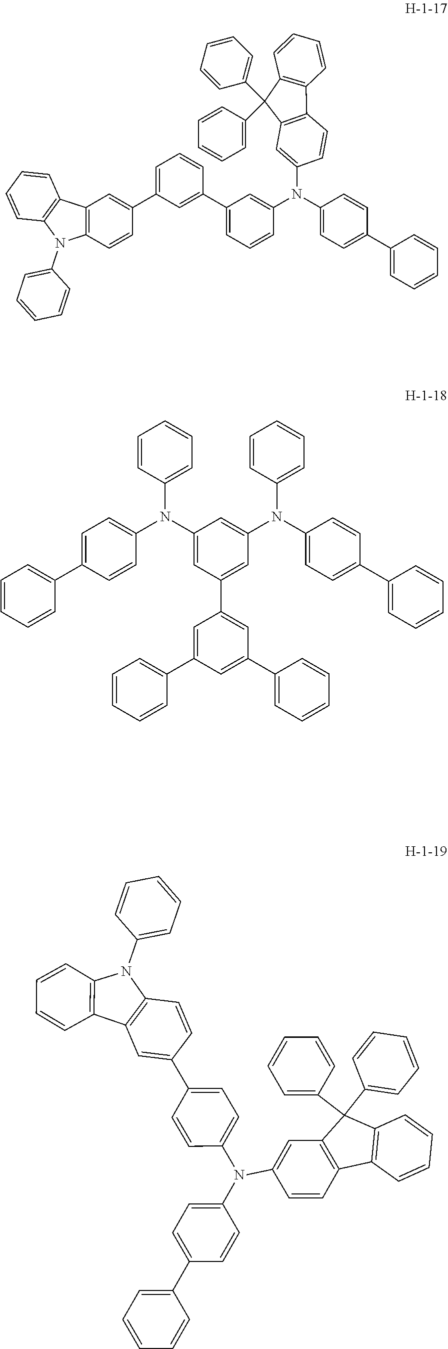 [SMILES: c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/Dodecylbenzenesulfonic acid (PANI/DBSA), polyaniline/camphor sulfonicacid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium tetrakis(pentafluorophenyl)borate, dipyrazino[2,3-f: 2′,3′-h] quinoxaline-2,3,6,7,10,11-hexacarbonitrile (HAT-CN), etc.

The hole transport region HTR may include carbazole-based derivatives such as N-phenyl carbazole and polyvinyl carbazole, fluorene-based derivatives, N,N′-bis(3-methylphenyl)-N,N′-diphenyl-[1,1-biphenyl]-4,4′-diamine (TPD), triphenylamine-based derivatives such as 4,4′,4″-tris(N-carbazolyl)triphenylamine (TCTA), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 9-(4-tert-Butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzene (mDCP) etc.

The hole transport region HTR may include the compounds of the hole transport region described above in at least one of a hole injection layer HIL, a hole transport layer HTL, or an electron blocking layer EBL.

The hole transport region HTR may have a thickness in a range of about 100 Å to about 10,000 Å. For example, the hole transport region HTR may have a thickness in a range of about 100 Å to about 5,000 Å. When the hole transport region HTR includes a hole injection layer HIL, the hole injection layer HIL may have a thickness, for example, in a range of about 30 Å to about 1,000 Å. When the hole transport region HTR includes a hole transport layer HTL, the hole transport layer HTL may have a thickness in a range of about 30 Å to about 1,000 Å. When the hole transport region HTR includes an electron blocking layer EBL, the electron blocking layer EBL may have a thickness, for example, in a range of about 10 Å to about 1,000 Å. When the thicknesses of the hole transport region HTR, the hole injection layer HIL, the hole transport layer HTL, and the electron blocking layer EBL satisfy the above-described ranges, satisfactory hole transport properties may be obtained without a substantial increase in driving voltage.

The hole transport region HTR may further include, in addition to the above-described materials, a charge generation material to increase conductivity. The charge generation material may be uniformly or non-uniformly dispersed in the hole transport region HTR. The charge generation material may be, for example, a p-dopant. The p-dopant may include at least one of halogenated metal compounds, quinone derivatives, metal oxides, or cyano group-containing compounds, but embodiments are not limited thereto. For example, the p-dopant may include halogenated metal compounds such as CuI and RbI, quinone derivatives such as tetracyanoquinodimethane (TCNQ) and 2,3,5,6-tetrafluoro-7,7,8,8-tetracyanoquinodimethane (F4-TCNQ), metal oxides such as tungsten oxides and molybdenum oxides, cyano group-containing compounds such as dipyrazino[2,3-f. 2′,3′-h]quinoxaline-2,3,6,7,10,11-hexacarbonitrile (HAT-CN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include at least one of a buffer layer (not shown), a light emitting auxiliary layer (not shown), or an electron blocking layer EBL, in addition to the hole injection layer HIL and the hole transport layer HTL. The buffer layer (not shown) may compensate for a resonance distance according to a wavelength of light emitted from an emission layer EML, and may thus increase luminous efficiency. Materials which may be included in the hole transport region HTR may be used as materials included in the buffer layer (not shown). The electron blocking layer EBL may prevent electrons from being injected from the electron transport region ETR to the hole transport region HTR. The light emitting auxiliary layer (not shown) may improve charge balance between holes and electrons. When the hole transport region HTR includes the electron blocking layer EBL, the electron blocking layer EBL may function as a light emitting auxiliary layer.

The electron transport region ETR is provided on the emission layer EML. The electron transport region ETR may include at least one of a hole blocking layer HBL, an electron transport layer ETL, or an electron injection layer EIL, but embodiments are not limited thereto.

The electron transport region ETR may be a layer formed of a single material, a layer formed of different materials, or a structure having multiple layers formed of different materials.

For example, the electron transport region ETR may have a single layer structure of an electron injection layer EIL or an electron transport layer ETL, or may have a single layer structure formed of an electron injection material and an electron transport material. In other embodiments, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, a laser induced thermal imaging (LITI) method, etc.

The electron transport region ETR may include the third compound described above. The third compound may be represented by Formula ET-1.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (Balq), berylliumbis(benzoquinolin-10-olate (Bebg₂), 9,10-di(naphthalene-2-yl)anthracene (ADN), 1,3-bis[3,5-di(pyridin-3-yl)phenyl]benzene (BmPyPhB), or a mixture thereof.

The electron transport region ETR may include halogenated metals such as LiF, NaCl, CsF, RbCl, RbI, CuI, and KI, lanthanide metals such as Yb, or co-deposition materials of a halogenated metal and a lanthanide metal. For example, the electron transport region ETR may include KJ:Yb, RbJ:Yb, LiF:Yb, etc. as a co-deposition material. For the electron transport region ETR, a metal oxide such as Li₂O and BaO, or 8-hydroxyl-lithium quinolate (Liq), etc. may be used, but embodiments are not limited thereto. The electron transport region ETR may also include a mixture material of an electron transport material and an insulating organometallic salt. The organometallic salt may be a material having an energy band gap equal to or greater than about 4 eV. For example, the organometallic salt may include metal acetates, metal benzoates, metal acetoacetates, metal acetylacetonates, or metal stearates.

The electron transport region ETR may further include, for example, at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the materials described above, but embodiments are not limited thereto.

The electron transport region ETR may include the compounds of the electron transport region described above in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. When the thickness of the electron transport layer ETL satisfies the above-described range, satisfactory electron transport properties may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. When the thickness of the electron injection layer EIL satisfies the above-described ranges, satisfactory electron injection properties may be obtained without a substantial increase in driving voltage.

The second electrode EL2 is provided on the electron transport region ETR. The second electrode EL2 may be a common electrode. The second electrode EL2 may be a cathode or an anode but embodiments are not limited thereto. For example, when the first electrode EL1 is an anode, the second electrode EL2 may be a cathode, and when the first electrode EL1 is a cathode, the second electrode EL2 may be an anode. The second electrode EL2 may include Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In another embodiment, the second electrode EL2 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the second electrode EL2 may include the above-described metal materials, a combination of two or more metal materials selected from the above-described metal materials, or oxides of the above-described metal materials.

Although not shown in the drawings, the second electrode EL2 may be electrically connected to an auxiliary electrode. When the second electrode EL2 is electrically connected to the auxiliary electrode, the resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkali metal compound such as LiF, an alkaline earth metal compound such as MgF₂, SiON, SiNx, SiOy, etc.

For example, when the capping layer CPL includes an organic material, the organic material may include α-NPD, NPB, TPD, m-MTDATA, Alq₃ CuPc, N4,N4,N4′,N4′-tetra(biphenyl-4-yl) biphenyl-4,4′-diamine (TPD15), 4,4′,4″-tris(carbazol-9-yl)triphenylamine (TCTA), etc., or may include epoxy resins or acrylates such as methacrylates. However, embodiments are not limited thereto, and the capping layer CPL may include at least one of Compounds P1 to P5.

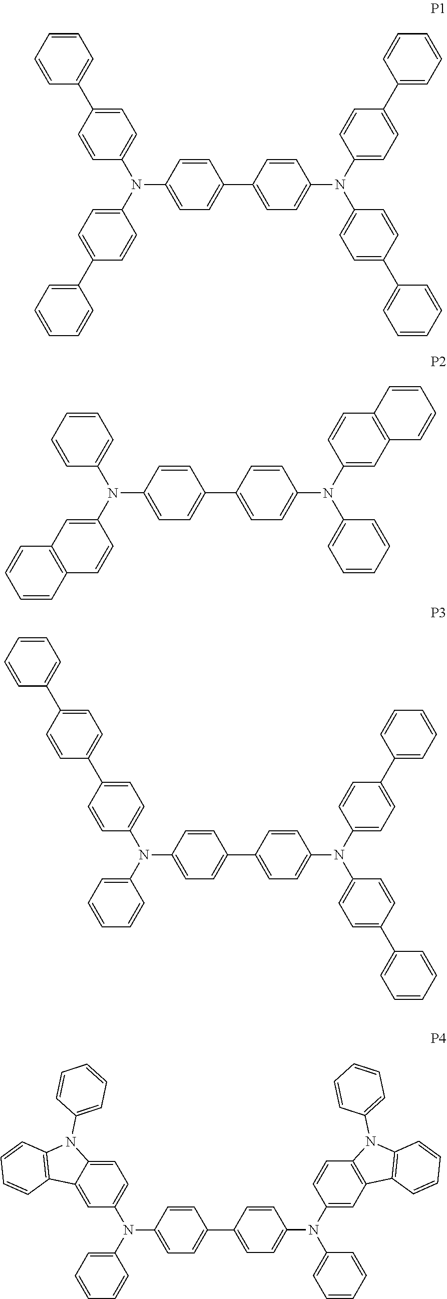

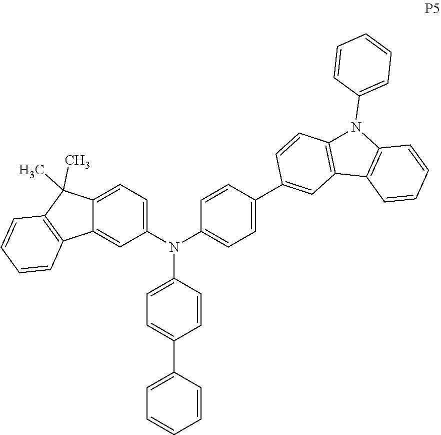 [SMILES: CC1(C)c2ccccc2-c2cc(N(c3ccc(-c4ccccc4)cc3)c3ccc(-c4ccc5c(c4)c4ccccc4n5-c4ccccc4)cc3)ccc21]

The capping layer CPL may have a refractive index equal to or greater than about 1.6. For example, the capping layer CPL may have a refractive index equal to or greater than about 1.6 with respect to light in a wavelength range of about 550 nm to about 660 nm.

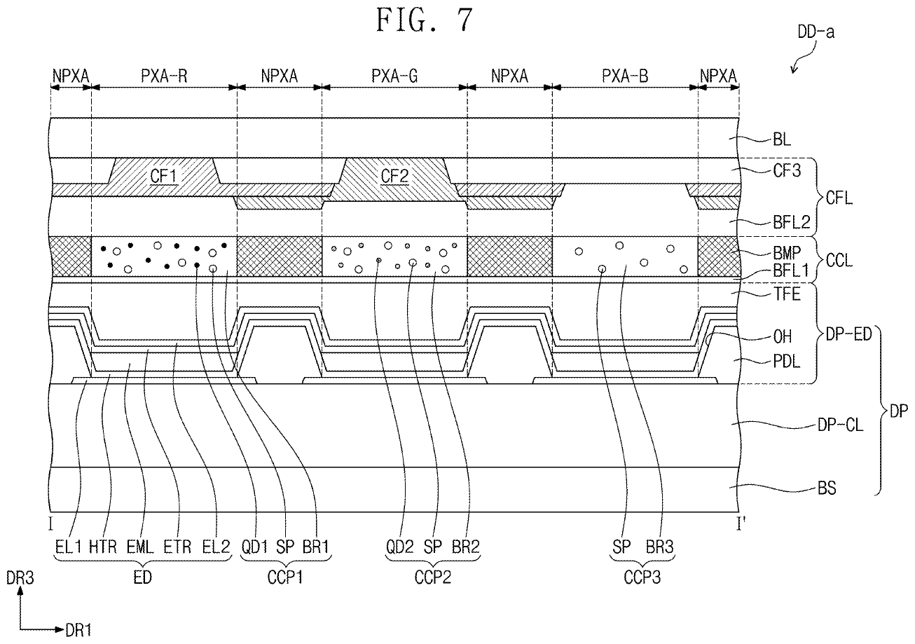

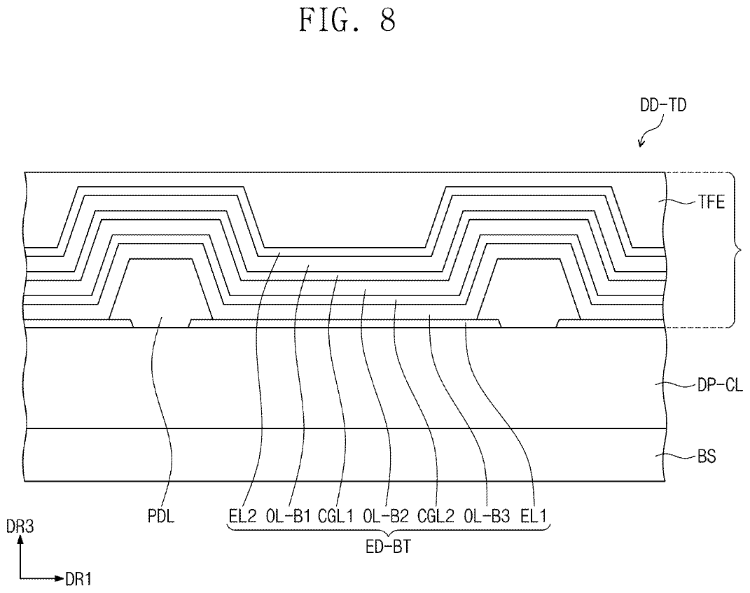

FIGS. 7 and 8 are each a schematic cross-sectional view of a display device according to an embodiment. In the description of the display device according to embodiments with reference to FIGS. 7 and 8, the features which have been described with respect to FIGS. 1 to 6 will not be explained again, and the disclosure will describe the differing features.

Referring to FIG. 7, a display device DD-a according to an embodiment may include a display panel DP having a display element layer DP-ED, a light control layer CCL disposed on the display panel DP, and a color filter layer CFL.

In an embodiment illustrated in FIG. 7, the display panel DP may include a base layer BS, a circuit layer DP-CL provided on the base layer BS, and a display element layer DP-ED, and the display element layer DP-ED may include a light emitting element ED.

The light emitting element ED may include a first electrode EL1, a hole transport region HTR disposed on the first electrode EL1, an emission layer EIL disposed on the hole transport region HTR, an electron transport region ETR disposed on the emission layer EIL, and a second electrode EL2 disposed on the electron transport region ETR. A structure of the light emitting element ED shown in FIG. 7 may be the same as a structure of a light emitting element according to one of FIGS. 3 to 6 as described above.

Referring to FIG. 7, in a display device DD-a, the emission layer EIL may be disposed in the openings OH defined in the pixel defining films PDL. For example, the emission layer EML, which is separated by the pixel defining films PDL and provided corresponding to each of the light emitting regions PXA-R, PXA-G, and PXA-B, may emit light in a same wavelength range. In the display device DD-a according to an embodiment, the emission layer EMIL may emit blue light. Although not shown in the drawings, in an embodiment, the emission layer EIL may be provided as a common layer for all of the light emitting regions PXA-R, PXA-G, and PXA-B.

The light control layer CCL may be disposed on the display panel DP. The light control layer CCL may include a photoconverter. The photoconverter may be a quantum dot or a phosphor. The photoconverter may convert the wavelength of a provided light, and may emit the resulting light. For example, the light control layer CCL may be a layer including quantum dots or phosphors.

The light control layer CCL may include light control units CCP1, CCP2, and CCP3. The light control units CCP1, CCP2, and CCP3 may be spaced apart from each other.

Referring to FIG. 7, a division pattern BMP may be disposed between the light control units CCP1, CCP2, and CCP3, which are spaced apart from each other, but embodiments are not limited thereto. FIG. 7 illustrates that the division pattern BMP does not overlap the light control units CCP1, CCP2, and CCP3, but edges of the light control units CCP1, CCP2, and CCP3 may overlap at least a portion of the division pattern BMP.

The light control layer CCL may include a first light control unit CCP1 including a first quantum dot QD1 that converts first color light provided from the light emitting element ED into second color light, a second light control unit CCP2 including a second quantum dot QD2 that converts the first color light into third color light, and a third light control unit CCP3 that transmits the first color light.

In an embodiment, the first light control unit CCP1 may provide red light, which is the second color light, and the second light control unit CCP2 may provide green light, which is the third color light. The third light control unit CCP3 may transmit and provide blue light, which is the first color light provided from the light emitting element ED. For example, the first quantum dot QD1 may be a red quantum dot, and the second quantum dot QD2 may be a green quantum dot.

The quantum dots QD1 and QD2 may each independently be selected from a Group II-VI compound, a Group III-VI compound, a Group I-III-VI compound, a Group III-V compound, a Group III-II-V compound, a Group IV-VI compound, a Group IV element, a Group IV compound, or a combination thereof.

The Group II-VI compound may be selected from: a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof, or any combination thereof.

The Group III-VI compound may be selected from: a binary compound such as In₂S₃ and In₂Se₃; a ternary compound such as InGaS₃ and InGaSe₃; or any combination thereof.

The Group I-III-VI compound may include a ternary compound selected from the group consisting of AgInS, AgInS₂, CuInS, CuInS₂, AgGaS₂, CuGaS₂ CuGaO₂, AgGaO₂, AgAlO₂, or any mixture thereof, or a quaternary compound such as AgInGaS₂ and CuInGaS₂.

The Group III-V compound may be selected from: a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof, a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof, or any combination thereof. The Group III-V compound may further include a Group II metal. For example, InZnP, etc. may be selected as a Group III-II-V compound.

The Group IV-VI compound may be selected from: a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, a quaternary compound selected from the group consisting of SnPbSSe, SnPbSeTe, SnPbSTe, and a mixture thereof, or any combination thereof. The Group IV element may be selected from the group consisting of Si, Ge, and a mixture thereof. The Group IV compound may be a binary compound selected from the group consisting of SiC, SiGe, and a mixture thereof.

A binary compound, a ternary compound, or a quaternary compound may be present in a particle at a uniform concentration distribution, or may be present in a particle at a partially different concentration distribution. In an embodiment, the quantum dots QD1 and QD2 may each independently have a core/shell structure in which a quantum dot surrounds another quantum dot. A quantum dot having a core/shell structure may have a concentration gradient in which the concentration of an element that is present in the shell decreases towards the core.

In embodiments, the quantum dots QD1 and QD2 may have a core/shell structure including a core containing nanocrystals and a shell surrounding the core, which are described above. The shell of the quantum dots may serve as a protection layer to prevent the chemical deformation of the core so as to keep semiconductor properties, and/or may serve as a charging layer to impart electrophoretic properties to the quantum dot. The shell may be a single layer or multiple layers. Examples of the shell of the quantum dot may include a metal oxide, a non-metal oxide, a semiconductor compound, or a combination thereof.

Examples of the metal oxide or the non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO; or a ternary compound such as MgAl₂O₄, CoFe₂O₄, NiFe₂O₄, and CoMn₂O₄, but embodiments are not limited thereto.

Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dots QD1 and QD2 may each have a full width at half maximum (FWHM) of a light emission wavelength spectrum equal to or less than about 45 nm. For example, the quantum dots QD1 and QD2 may each have a FWHM of a light emission wavelength spectrum equal to or less than about 40 nm. For example, the quantum dots QD1 and QD2 may each have a FWHM of a light emission wavelength spectrum equal to or less than about 30 nm. Color purity or color reproducibility may be enhanced in the above ranges. Light emitted through a quantum dot may be emitted in all directions, so that a wide viewing angle may be improved.

The form of the quantum dots QD1 and QD2 is not limited and may be any form that is used in the related art. For example, the quantum dot may have a spherical shape, a pyramidal shape, a multi-arm shape, or a cubic shape, or the quantum dot may be in the form of nanoparticles, nanotubes, nanowires, nanofibers, nanoplatelets, etc.

The quantum dot may control the color of emitted light according to a particle size thereof, and thus the quantum dot may have various colors of emitted light such as blue, red, green, etc.

The light control layer CCL may further include scatterers SP. The first light control unit CCP1 may include the first quantum dot QD1 and the scatterers SP, the second light control unit CCP2 may include the second quantum dot QD2 and the scatterers SP, and the third light control unit CCP3 may not include a quantum dot but may include the scatterers SP.

The scatterers SP may be inorganic particles. For example, the scatterers SP may include at least one of TiO₂, ZnO, Al₂O₃, SiO₂, or hollow silica. The scatterers SP may include any one of TiO₂, ZnO, Al₂O₃, SiO₂, or hollow silica, or the scatterers SP may be a mixture of two or more materials selected from TiO₂, ZnO, Al₂O₃, SiO₂, and hollow silica.

The first light control unit CCP1, the second light control unit CCP2, and the third light control unit CCP3 may each include base resins BR1, BR2, and BR3 for dispersing the quantum dots QD1 and QD2 and the scatterers SP. In an embodiment, the first light control unit CCP1 may include the first quantum dot QD1 and the scatterers SP dispersed in the first base resin BR1, the second light control unit CCP2 may include the second quantum dot QD2 and the scatterers SP dispersed in the second base resin BR2, and the third light control unit CCP3 may include the scatterers SP dispersed in the third base resin BR3. The base resins BR1, BR2, and BR3 may each be a medium in which the quantum dots QD1 and QD2 and the scatterers SP are dispersed, and may be formed of various resin compositions, which may be generally referred to as a binder. For example, the base resins BR1, BR2, and BR3 may be an acrylic-based resin, a urethane-based resin, a silicone-based resin, an epoxy-based resin, etc. The base resins BR1, BR2, and BR3 may be a transparent resin. In an embodiment, the first base resin BR1, the second base resin BR2, and the third base resin BR3 may each be the same as or different from each other.

The light control layer CCL may include a barrier layer BFL1. The barrier layer BFL1 may prevent moisture and/or oxygen (hereinafter referred to as “moisture/oxygen”) from being introduced. The barrier layer BFL1 may prevent the light control units CCP1, CCP2, and CCP3 from being exposed to moisture/oxygen. The barrier layer BFL1 may cover the light control units CCP1, CCP2, and CCP3. A barrier layer BFL2 may be provided between the light control units CCP1, CCP2, and CCP3 and the color filter layer CFL.

The barrier layers BFL1 and BFL2 may each independently include at least one inorganic layer. For example, the barrier layers BFL1 and BFL2 may each include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film in which light transmittance is secured, etc. The barrier layers BFL1 and BFL2 may further include an organic film. The barrier layers BFL1 and BFL2 may each be formed of a single layer or of multiple layers.

In the display device DD-a according to an embodiment, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. The filters CF1, CF2, and CF3 may each include a polymer photosensitive resin, a pigment, or a dye. The first filter CF1 may include a red pigment or a red dye, the second filter CF2 may include a green pigment or a green dye, and the third filter CF3 may include a blue pigment or a blue dye. However, embodiments are not limited thereto, and the third filter CF3 may not include a pigment or a dye. The third filter CF3 may include a polymer photosensitive resin, but may not include a pigment or a dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be separated from each other and may be provided as a single body.

The first to third filters CF1, CF2, and CF3 may be disposed corresponding to the red light emitting region PXA-R, the green light emitting region PXA-G, and the blue light emitting region PXA-B, respectively.

Although not shown, the color filter layer CFL may further include a light blocking unit. The light blocking unit may include an organic light blocking material or an inorganic light blocking material, each including a black pigment or a black dye. The light blocking unit may prevent light leakage, and may separate boundaries between the adjacent filters CF1, CF2, and CF3.

A base substrate BL may be disposed on the color filter layer CFL. The base substrate BL may provide a base surface on which the color filter layer CFL and the light control layer CCL are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

FIG. 8 is a schematic cross-sectional view showing a portion of a display device according to an embodiment. FIG. 8 shows a schematic cross-sectional view of a portion corresponding to the display panel DP of FIG. 7.

In a display device DD-TD according to an embodiment, a light emitting element ED-BT may include light emitting structures OL-B1, OL-B2, and OL-B3. The light emitting element ED-BT may include a first electrode EL1 and a second electrode EL2 facing each other, and the light emitting structures OL-B1, OL-B2, and OL-B3 stacked in a thickness direction between the first electrode EL1 and the second electrode EL2. The light emitting structures OL-B1, OL-B2, and OL-B3 may each include an emission layer EML (FIG. 7), and a hole transport region HTR and an electron transport region ETR disposed with the emission layer EML (FIG. 7) therebetween.

For example, the light emitting element ED-BT included in the display device DD-TD of an embodiment may be a light emitting element having a tandem structure and including multiple emission layers.

In an embodiment illustrated in FIG. 8, light emitted from each of the light emitting structures OL-B1, OL-B2, and OL-B3 may all be blue light. However, embodiments are not limited thereto, and the wavelength ranges of light emitted from each of the light emitting structures OL-B1, OL-B2, and OL-B3 may be different from each other. For example, the light emitting element ED-BT including the light emitting structures OL-B1, OL-B2, and OL-B3 emitting light in different wavelength ranges may emit white light.

Charge generation layers CGL1 and CGL2 may be disposed between neighboring light emitting structures OL-B1, OL-B2, and OL-B3. The charge generation layers CGL1 and CGL2 may each independently include a p-type charge generation layer and/or an n-type charge generation layer.

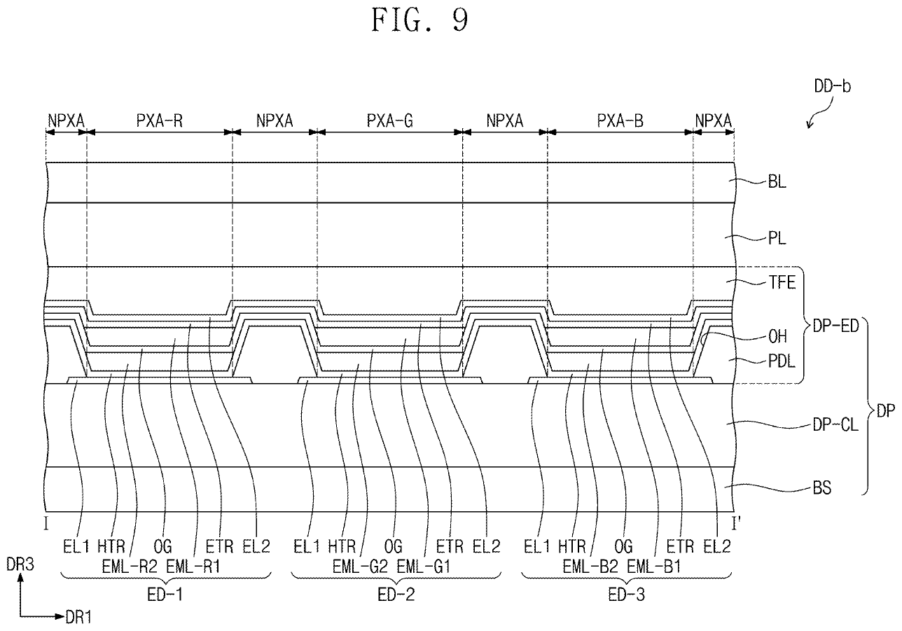

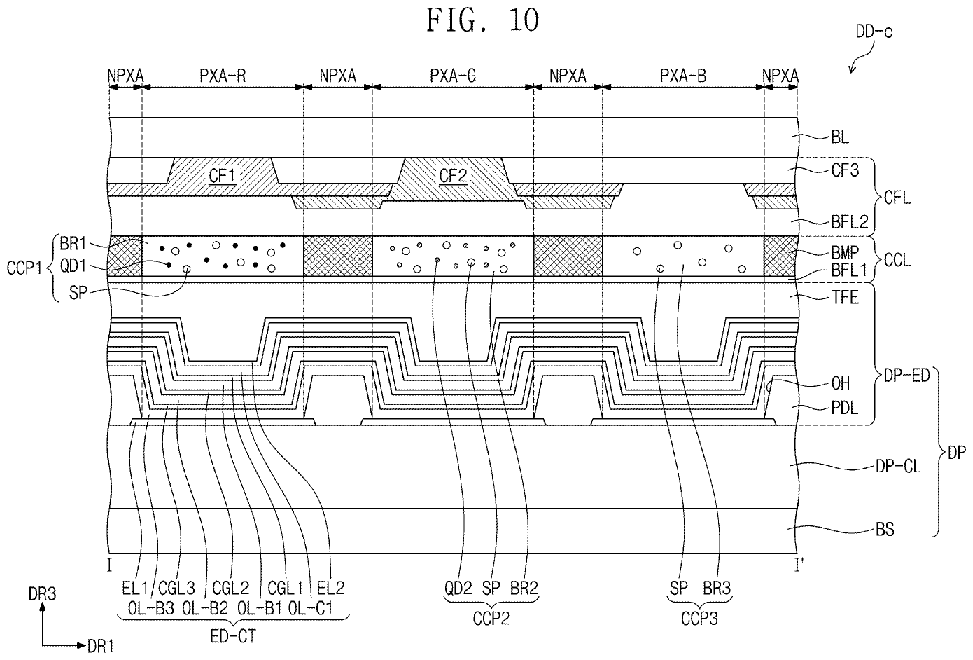

Referring to FIG. 9, a display device DD-b may include light emitting elements ED-1, ED-2, and ED-3 which may each include two emission layers that are stacked. In contrast to the display device DD shown in FIG. 2, FIG. 9 illustrates that two emission layers are provided in each of the first to third light emitting elements ED-1, ED-2, and ED-3. In each of the first to third light emitting elements ED-1, ED-2, and ED-3, the two emission layers may emit light in a same wavelength range.

The first light emitting element ED-1 may include a first red emission layer EMIL-R1 and a second red emission layer EMIL-R2. The second light emitting element ED-2 may include a first green emission layer EMIL-G1 and a second green emission layer EMIL-G2. The third light emitting element ED-3 may include a first blue emission layer EMIL-B1 and a second blue emission layer EML-B2. A light emitting auxiliary portion OG may be disposed between the first red emission layer EMIL-R1 and the second red emission layer EMIL-R2, between the first green emission layer EMIL-G1 and the second green emission layer EMIL-G2, and between the first blue emission layer EMIL-B1 and the second blue emission layer EML-B2.

The light emitting auxiliary portion OG may be a single layer or may be multiple layers. The light emitting auxiliary portion OG may include a charge generation layer. For example, the light emitting auxiliary portion OG may include an electron transport region, a charge generation layer, and a hole transport region that are stacked in that order. The light emitting auxiliary portion OG may be provided as a common layer for all of the first to third light emitting elements ED-1, ED-2, and ED-3. However, embodiments are not limited thereto, and the light emitting auxiliary portion OG may be provided by being patterned inside the openings OH defined in the pixel defining films PDL.

The first red emission layer EML-R1, the first green emission layer EML-G1, and the first blue emission layer EML-B1 may each be disposed between the electron transport region ETR and the emission auxiliary portion OG. The second red emission layer EML-R2, the second green emission layer EML-G2, and the second blue emission layer EML-B2 may each be disposed between the emission auxiliary portion OG and the hole transport region HTR.

For example, the light emitting element ED-1 may include the first electrode EL1, the hole transport region HTR, the second red emission layer EML-R2, the emission auxiliary portion OG, the first red emission layer EML-R1, the electron transport region ETR, and the second electrode EL2, stacked in that order. The second light emitting element ED-2 may include the first electrode EL1, the hole transport region HTR, the second green emission layer EML-G2, the emission auxiliary portion OG, the first green emission layer EML-G1, the electron transport region ETR, and the second electrode EL2, stacked in that order. The third light emitting element ED-3 may include the first electrode EL1, the hole transport region HTR, the second blue emission layer EML-B2, the emission auxiliary portion OG, the first blue emission layer EML-B1, the electron transport region ETR, and the second electrode EL2, stacked in that order.

An optical auxiliary layer PL may be disposed on the display element layer DP-ED. The optical auxiliary layer PL may include a polarizing layer. The optical auxiliary layer PL may be disposed on the display panel DP and may control light reflected at the display panel DP from an external light. Although not shown in the drawings, in an embodiment, the optical auxiliary layer PL may be omitted from the display device DD-b.

In contrast to FIGS. 7 and 8, FIG. 10 illustrates a display device DD-c that is different at least in that it includes four light emitting structures OL-B1, OL-B2, OL-B3, and OL-C1. A light emitting element ED-CT may include a first electrode EL1 and a second electrode EL2 facing each other, and the first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. The charge generation layers CGL1, CGL2 and CGL3 may each independently include a p-type charge generation layer and/or an n-type charge generation layer.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having different wavelength ranges from one another.

Hereinafter, a polycyclic compound according to an embodiment and a light emitting element according to an embodiment will be described in detail with reference to the Examples and the Comparative Examples. The Examples shown below are only provided as illustrations to assist in understanding the disclosure, and the scope thereof is not limited thereto.

### Examples

### 1. Synthesis of Polycyclic Compounds of Examples

A process of synthesizing polycyclic compounds according to an embodiment will be described in detail by presenting a process of synthesizing Compounds 1, 9, 11, and 18 as examples. A process of synthesizing polycyclic compounds, which will be described hereinafter, is provided only as an example, and thus the process of synthesizing compounds according to an embodiment is not limited to the Examples below.

### (1) Synthesis of Compound 1

Polycyclic Compound 1 according to an embodiment may be synthesized by, for example, processes of Reaction Formulas 1 to 3.

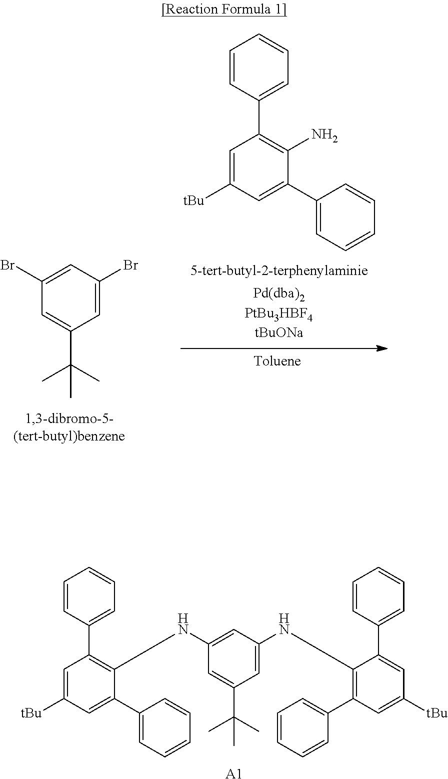

1,3-dibromo-5-(tert-butyl)benzene (20 g, 68.5 mmol), 5-tert-butyl-2-terphenylamine (41.3 g, 137 mmol), Pd(dba)₂ (1.58 g, 2.74 mmol), PtBu₃HBF₄ (1.59 g, 5.48 mmol), and tBuONa (19.7 g, 205 mmol) were added to 500 ml of toluene, and the mixture was heated and stirred at 80° C. for 6 hours. After adding water, the resultant mixture was subjected to celite filtering and liquid separation to concentrate an organic layer. The concentrated organic layer was purified using silica gel column chromatography to obtain Compound A1.

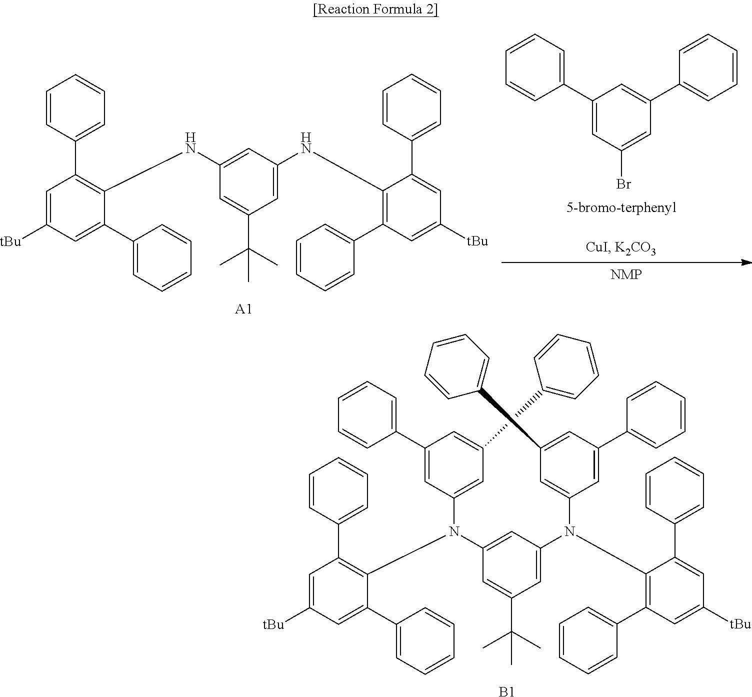

Compound A1 (30 g, 40.9 mmol), 5-bromo-terphenyl (25.3 g, 81.8 mmol), CuI (15.6 g, 81.8 mmol), and K₂CO₃ (113 g, 818 mmol) were added to 100 ml of NMP, and the mixture was reflux-stirred for 24 hours. After adding water, the resultant mixture was subjected to celite filtering and liquid separation to concentrate an organic layer. The concentrated organic layer was purified using silica gel column chromatography to obtain Compound B1.

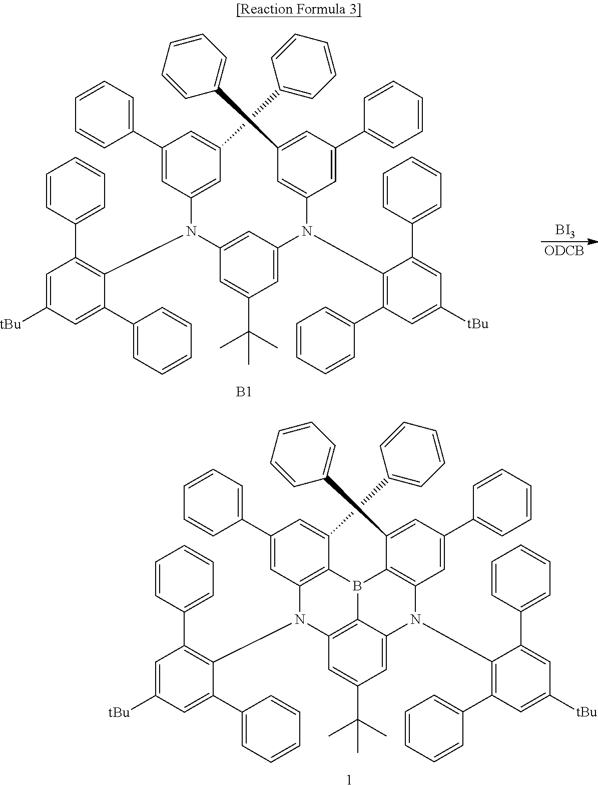

Compound B1 (20 g, 40.9 mmol) and BI₃ (17 g, 40.9 mmol) were added to 70 ml of ODCB, and the mixture was heated and stirred for 24 hours. After adding toluene, the resultant mixture was subjected to celite filtering and liquid separation to concentrate an organic layer. The concentrated organic layer was purified using silica gel column chromatography to obtain Compound 1.

### (2) Synthesis of Compound 9

Polycyclic Compound 9 according to an embodiment may be synthesized by, for example, processes of Reaction Formulas 4 and 5.

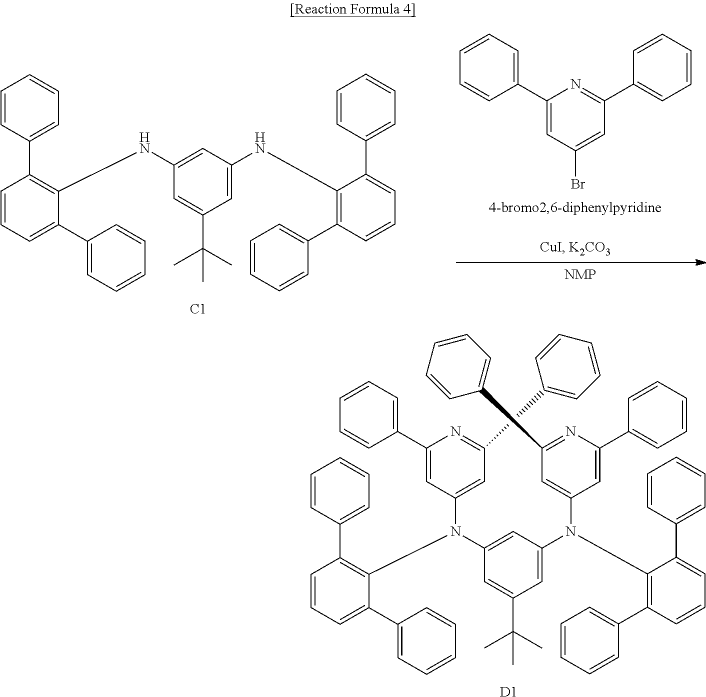

Under the same conditions as in Reaction Formula 1, Compound C1 was synthesized. Compound D1 was obtained under the same conditions as in Reaction Formula 2, except that Compound C1 instead of Compound A1 and 4-bromo-2,6-diphenylpyridine instead of compound 5-bromo-terphenyl were used.

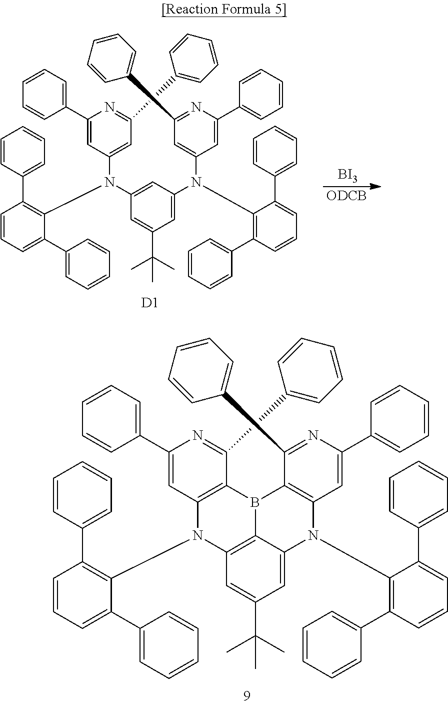

Compound 9 was obtained under the same conditions as in Reaction Formula 3, except that Compound D1 was used instead of Compound B1.

### (3) Synthesis of Compound 11

Polycyclic Compound 11 according to an embodiment may be synthesized by, for example, processes of Reaction Formulas 6 to 8.

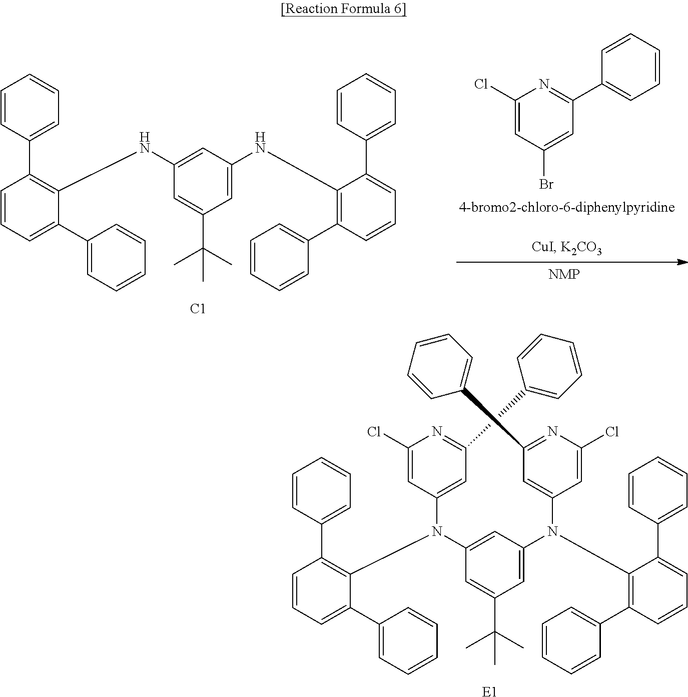

Compound E1 was obtained under the same conditions as in Reaction Formula 2, except that Compound C1 instead of Compound A1, and 4-bromo-2-chloro-6-phenylpyridine instead of 5-bromo-terphenyl were used.

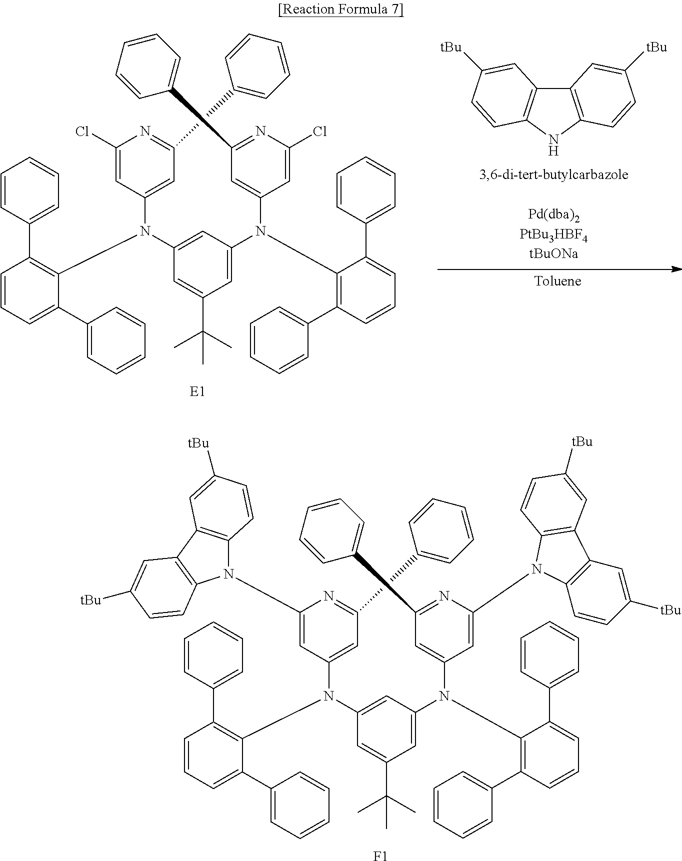

Compound F1 was obtained under the same conditions as in Reaction Formula 1, except that Compound E1 instead of 1,3-dibromo-5-(tert-butyl)benzene, and 3,6-di-tert-butylcarbazole instead of 5-tert-butyl-2-terphenylamine were used.

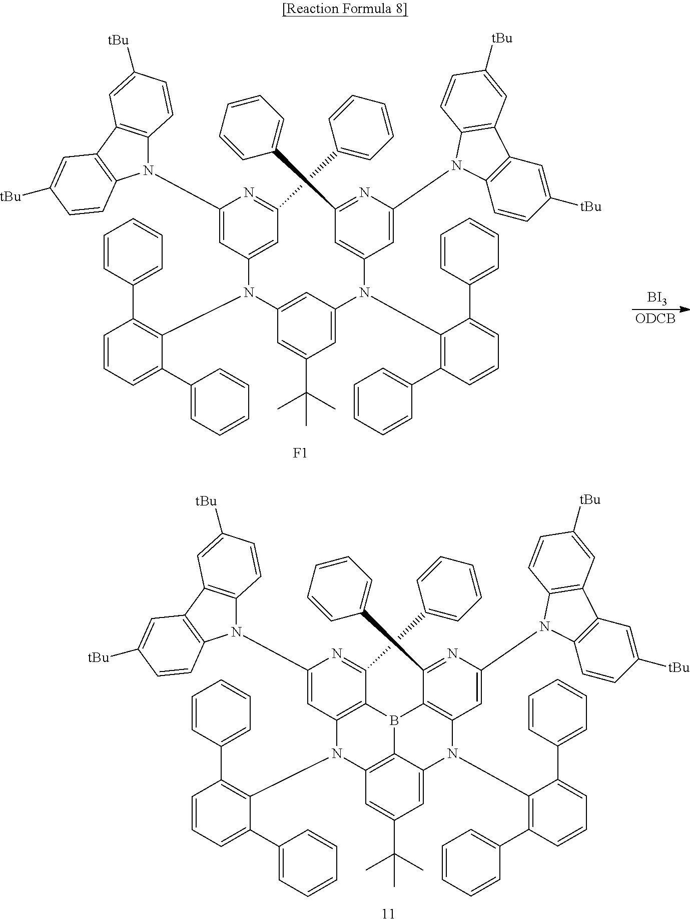

Compound 11 was obtained under the same conditions as in Reaction Formula 3, except that Compound F1 was used instead of Compound B1.

### (4) Synthesis of Compound 18

Polycyclic Compound 18 according to an embodiment may be synthesized by, for example, processes of Reaction Formulas 9 to 12.

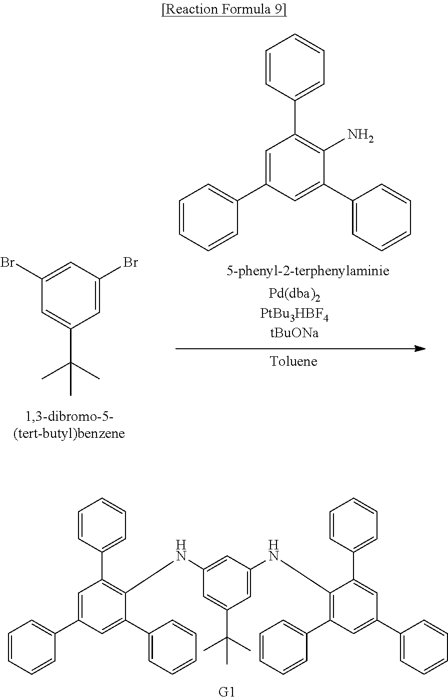

Compound G1 was obtained under the same conditions as in Reaction Formula 1, except that 5-phenyl-2-terphenylamine was used instead of 5-tert-butyl-2-terphenylamine.

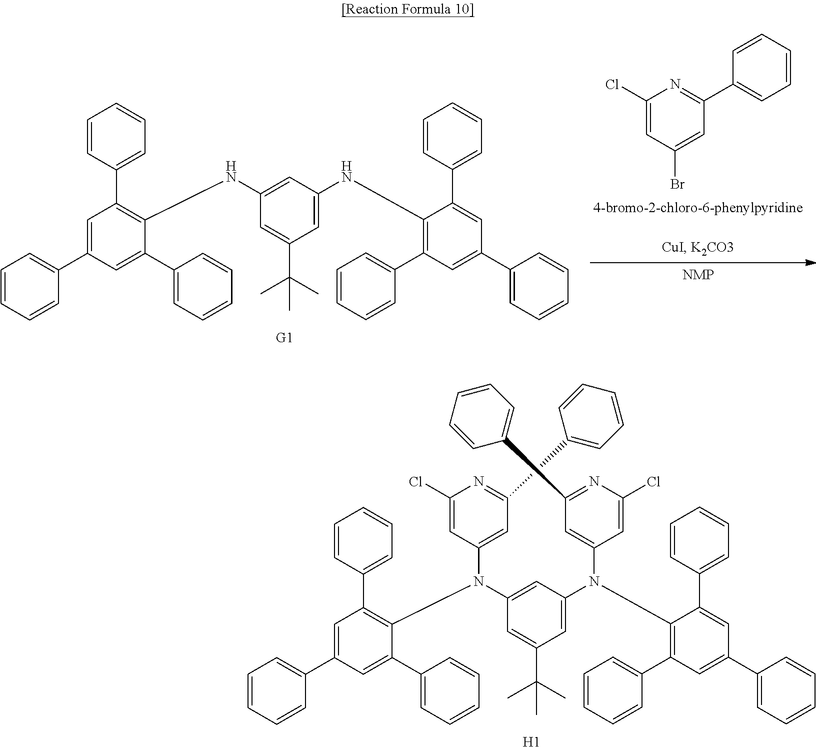

Compound H1 was obtained under the same conditions as in Reaction Formula 2, except that Compound G1 instead of Compound A1, and 4-bromo-2-chloro-6-phenylpyridine instead of 5-bromo-terphenyl were used.

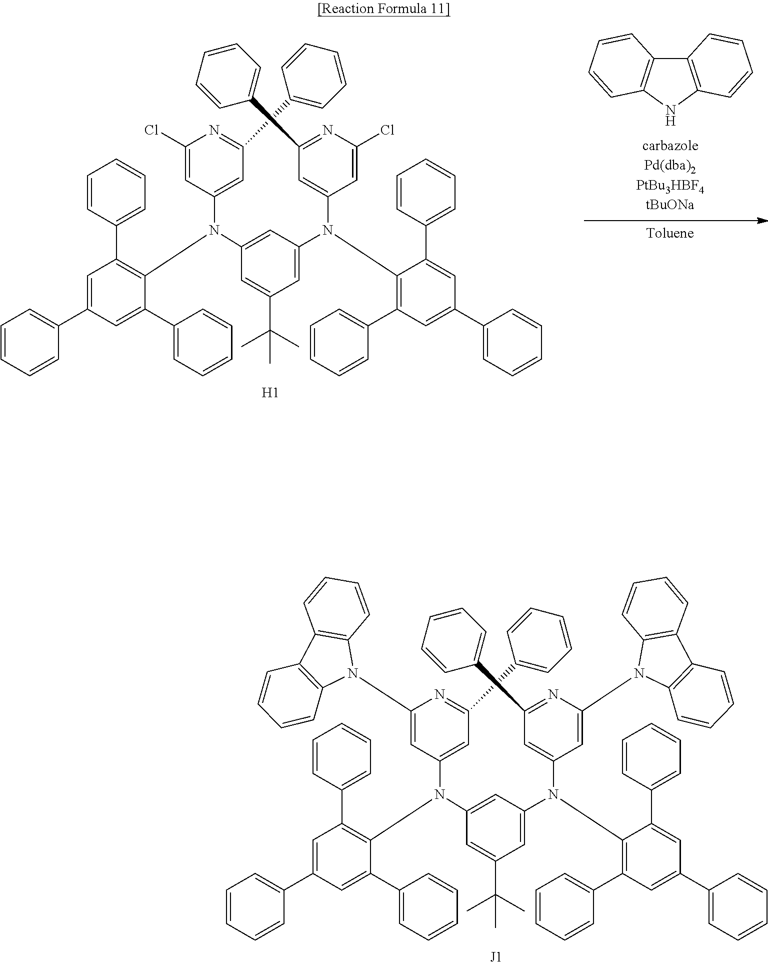

Compound J1 was obtained under the same conditions as in Reaction Formula 1, except that Compound H1 instead of 1,3-dibromo-5-(tert-butyl)benzene, and carbazole instead of 5-tert-butyl-2-terphenylamine were used.

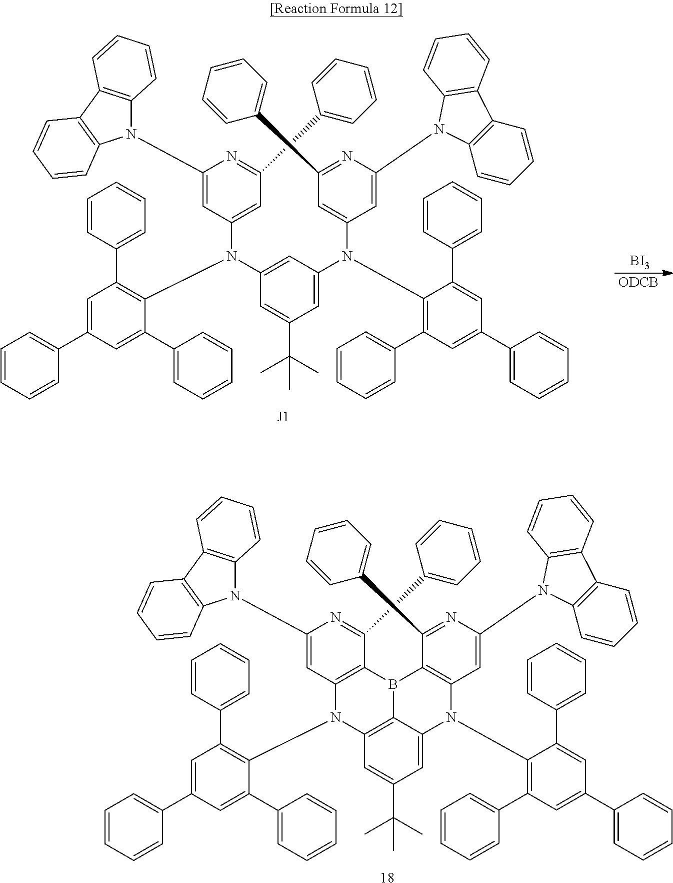

Compound 18 was obtained under the same conditions as in Reaction Formula 3, except that Compound J1 was used instead of Compound B1.

### 2. Preparation and Evaluation of Light Emitting Elements

### (1) Preparation of Light Emitting Elements

Light emitting elements including polycyclic compounds according to an embodiment or including Comparative Example compounds were prepared through a process described below. Light emitting elements of Examples 1 to 4 were prepared respectively using polycyclic compounds according to an embodiment, wherein Compounds 1, 9, 11, and 18 were included as a dopant material of an emission layer. Light emitting elements of Comparative Examples 1 to 4 were prepared respectively using Comparative Example compounds C1 to C4 as a dopant material of an emission layer.

An ITO having a thickness of 1,500 Å was patterned on a glass substrate, washed with ultrapure water, subjected to ultrasonic cleaning, irradiated with UV for 30 minutes, and treated with ozone. HAT-CN was deposited to a thickness of 100 Å, α-NPD was deposited to a thickness of 800 Å, and mCP was deposited to a thickness of 50 Å to form a hole transport region.

When an emission layer is formed, an Example polycyclic compound or a Comparative Example compound, and mCBP were co-deposited at a weight ratio of 1:99 to form a layer having a thickness of 200 Å. In Examples 1 to 4, Compounds 1, 9, 11, and 18 were respectively co-deposited with mCBP, and in Comparative Examples 1 to 4, Comparative Example compounds C1, C2, C3, and C4 were respectively co-deposited with mCBP.

TPBi was used to form a 300 Å-thick layer and LiF was used to form a 5 Å-thick layer on the emission layer to form an electron transport region. Aluminum (Al) was used to form a second electrode having a thickness of 1,000 Å. The hole transport region, the emission layer, the electron transport region, and the second electrode were formed using a vacuum deposition apparatus.

The compounds used in Examples 1 to 4 and Comparative Example compounds used in Comparative Examples 1 to 4 are shown in Table 1.

TABLE 1

| | |
|---|---|
| Compound 1 | 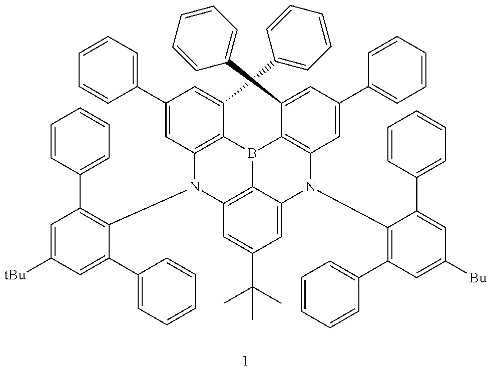 |
| Compound 9 | 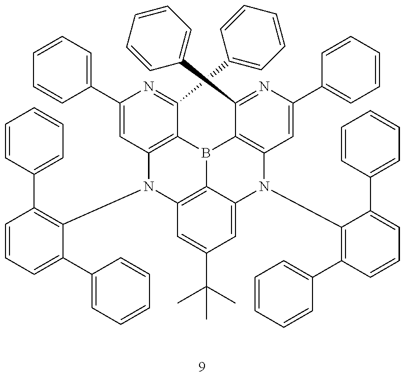 |
| Compound 11 | 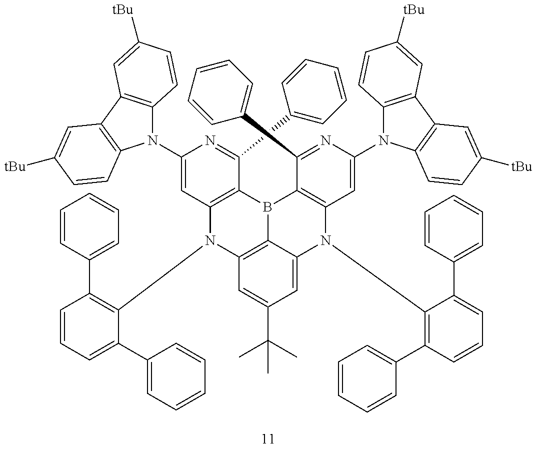 |
| Compound 18 | 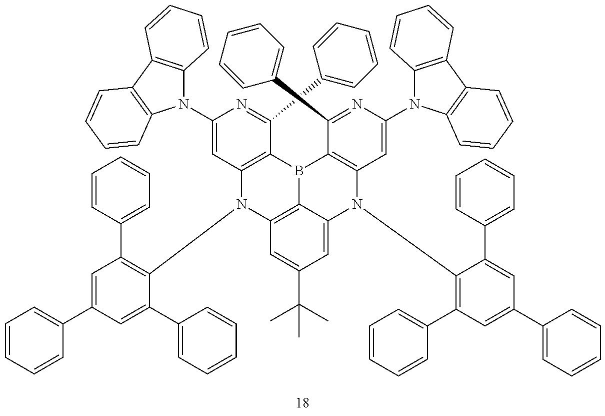 |
| Comparative Example Compound C1 | 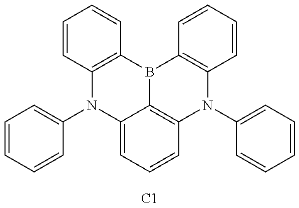 |
| Comparative Example Compound C2 | 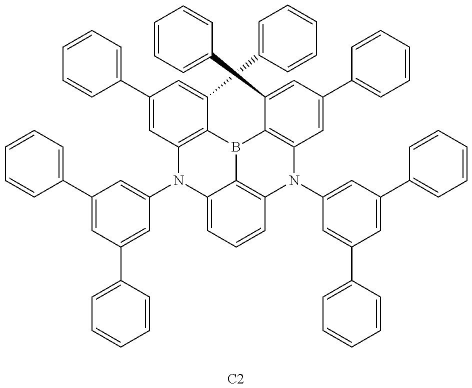 |
| Comparative Example Compound C3 | 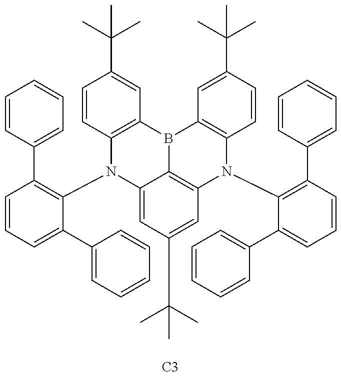 |
| Comparative Example Compound C4 | 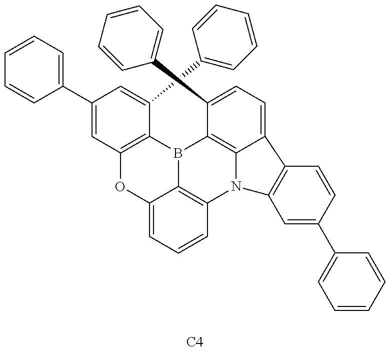 |

### (2) Characteristics Evaluation of Light Emitting Elements

Table 2 shows evaluation results of the light emitting elements of the Examples and the Comparative Examples. In the light emitting elements of the Examples and the Comparative Examples, full width at half maximum, maximum emission wavelength (λₘₐₓ), roll-off, external quantum efficiency (EQE_{max, 1000nit}), and lifetime (LT₅₀) were evaluated. Full width at half maximum, maximum emission wavelength (λₘₐₓ), roll-off, external quantum efficiency (EQE_{max, 1000nit}), and lifetime (LT₅₀) were evaluated using a spectroradiometer (SR-3AR from TOPCON). The maximum emission wavelength (λₘₐₓ) represents wavelength showing the maximum value in the emission spectrum, and the external quantum efficiency (EQE_{max, 1000nit}) is indicated with respect to a luminance of 1,000 cd/m². The lifetime (LT₅₀) is a measure of the half-life, which is the time taken to decrease to half of the initial luminance, and indicates a relative value with the half-life of the light emitting element of Comparative Example 1 being 1. The roll-off indicates the percentage of reduction in efficiency at high luminance, and is evaluated with respect to a luminance of 1 cd/m² and a luminance of 1,000 cd/m². The roll-off was calculated using Equation 1.

R₀=[(E₁−E₂)/E₁]×100% [Equation 1]

In Equation 1, E₁ indicates external quantum efficiency at a luminance of 1 cd/m², E₂ indicates external quantum efficiency at a luminance of 1,000 cd/m², and R₀ indicates a roll-off value.

TABLE 2

| | | Full | | | | |
|---|---|---|---|---|---|---|
| | | width | | | | |
| | | at half | | | | |
| Example of | | max- | | Roll- | | |
| element | | imum | λₘₐₓ | off | EQE_{max, 1000nit} | Lifespan |
| preparation | Dopant | (nm) | (nm) | (%) | (%) | (LT₅₀) |
| Example 1 | Compound 1 | 20 | 465 | 9.9 | 17.6 | 1.7 |
| Example 2 | Compound 9 | 20 | 458 | 11.5 | 17.8 | 1.6 |
| Example 3 | Compound 11 | 21 | 460 | 9.7 | 18.8 | 1.8 |
| Example 4 | Compound 18 | 22 | 460 | 9.8 | 18.7 | 1.8 |
| Comparative | Comparative | 32 | 462 | 32.0 | 11.2 | 1.0 |
| Example 1 | Example | | | | | |
| | Compound C1 | | | | | |
| Comparative | Comparative | 28 | 465 | 55.0 | 5.8 | 1.3 |
| Example 2 | Example | | | | | |
| | Compound C2 | | | | | |
| Comparative | Comparative | 23 | 458 | 25.0 | 15.6 | 1.2 |
| Example 3 | Example | | | | | |
| | Compound C3 | | | | | |
| Comparative | Comparative | 38 | 457 | 58.0 | 5.2 | 0.5 |
| Example 4 | Example | | | | | |
| | Compound C4 | | | | | |

Referring to Table 2, it can be seen that the light emitting elements of Examples 1 to 4 had a full width at half maximum of about 22 nm or less, and a maximum emission wavelength of about 458 to about 465 nm. As the light emitting elements of Examples 1 to 4 have a narrow full width at half maximum, color purity may be enhanced. The light emitting elements of Examples 1 to 4 include Compounds 1, 9, 11, and 18, and Compounds 1, 9, 11, and 18 are polycyclic compounds according to an embodiment. Accordingly, the light emitting elements including the polycyclic compounds according to an embodiment may have a narrow full width at half maximum and enhanced color purity.

Referring to Table 2, it can be seen that, compared to the light emitting elements of Comparative Examples 1 to 4, the light emitting elements of Examples 1 to 4 have a very low efficiency reduction percentage at high luminance and a long half-life. It can be seen that the light emitting elements of Examples 1 to 4 have an external quantum efficiency of 17% or greater. The light emitting elements of Examples 1 to 4 include Compounds 1, 9, 11 and 18, which are polycyclic compounds according to an embodiment. In Compounds 1, 9, 11, and 18, a fused ring of five rings including B as a ring-forming atom is protected through phenyl groups adjacent to each other, and accordingly, the fused ring of five rings may be protected and intermolecular interaction may be prevented. The phenyl groups correspond to P1 and P2 of Formula Z1 described above. In Compounds 1, 9, 11, and 18, as intermolecular interaction is prevented, Dexter energy transfer may be minimized. Accordingly, a light emitting element including the polycyclic compound according to an embodiment may exhibit high efficiency and long lifespan.

The light emitting element of Comparative Example 1 includes Comparative Example compound C1, and Comparative Example compound C1 includes a fused ring of five rings. In Comparative Example compound C1 is believed to have a wide full width at half maximum and a high efficiency reduction percentage at high luminance due to the unprotected fused ring of five rings.

The light emitting element of Comparative Example 2 includes Comparative Example compound C2, and Comparative Example compound C2 is a compound in which a fused ring of five rings is bonded to phenyl groups adjacent to each other. However, Comparative Example compound C2 includes a substituent at the meta positions with respect to N. Unlike the polycyclic compound according to an embodiment including a substituent (e.g., a phenyl group) other than a hydrogen atom at ortho positions with respect to N, Comparative Example compound C2 has a hydrogen atom in the ortho positions with respect to N. Accordingly, in Comparative Example compound C2, the fused ring of five rings is not protected and intermolecular interaction is not prevented, and thus it is believed that exciton decay is not prevented. Accordingly, it can be seen that the light emitting element of Comparative Example 2 including Comparative Example compound C2 has low external quantum efficiency and a short lifespan. It can be seen that the light emitting element of Comparative Example 2 has a very high efficiency reduction percentage at high luminance.

The light emitting element of Comparative Example 3 includes Comparative Example compound C3. Unlike the polycyclic compound according to an embodiment, in Comparative Example compound C3, a t-butyl group is bonded to a fused ring of five rings, and the bonding position of the t-butyl group is different from the bonding position of the phenyl group in the polycyclic compound according to an embodiment. Accordingly, it can be seen that the light emitting element of Comparative Example 3 including Comparative Example compound C3 has low external quantum efficiency and a short lifespan. It can be seen that the light emitting element of Comparative Example 3 has a high efficiency reduction percentage at high luminance.

The light emitting element of Comparative Example 4 includes Comparative Example compound C4. Unlike the polycyclic compound according to an embodiment, Comparative Example compound C4 includes a fused ring of seven rings in which a substituent at the ortho positions with respect to N is bonded to an adjacent benzene ring to form a ring. Accordingly, in Comparative Example compound C4, intermolecular interaction is not prevented, and it is believed that the light emitting element of Comparative Example 4 including Comparative Example compound C4 has a very short lifespan. Accordingly, it is seen that the light emitting element of Comparative Example 4 including Comparative Example compound C4 has a wide full width at half maximum and a very high efficiency reduction percentage at high luminance.

The light emitting element according to an embodiment may include a polycyclic compound according to an embodiment in at least one functional layer disposed between a first electrode and a second electrode. For example, the light emitting element may include the polycyclic compound according to an embodiment in an emission layer. The polycyclic compound according to an embodiment may include a fused ring of five rings containing B as a ring-forming atom and the fused ring of five rings may be bonded to a phenyl group. Accordingly, in the polycyclic compound according to an embodiment, the fused ring of five rings may be protected and intermolecular interaction may be prevented, and accordingly, Dexter energy transfer may be minimized. The light emitting element including the polycyclic compound according to an embodiment may exhibit high efficiency and long lifespan.

A light emitting element according to an embodiment includes a polycyclic compound according to an embodiment, and may thus exhibit high efficiency and long life characteristics.

A light emitting element according to an embodiment includes a polycyclic compound according to an embodiment and may thus exhibit a narrow full width at half maximum and emit light having enhanced color purity.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
an emission layer disposed between the first electrode and the second electrode, wherein
the emission layer includes:
a first compound represented by Formula 1; and
at least one of a second compound represented by Formula HT-1, a third compound represented by Formula ET-1, or a fourth compound represented by Formula M-b: 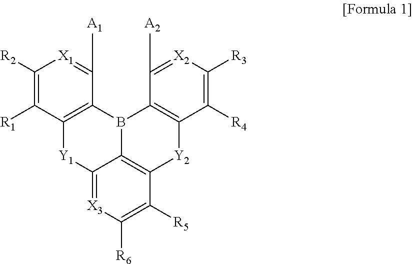
wherein in Formula 1,
X₁ to X₃ are each independently C(R₇) or N,
Y₁ and Y₂ are each independently O, S, or N(Rₐ),
Rₐ is a substituted phenyl group including a substituent at an ortho position with respect to N,
A₁ and A₂ are each independently a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
R₁ to R₇ are each independently a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; 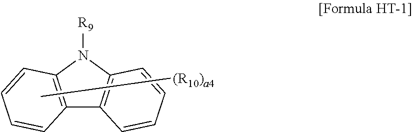
wherein in Formula HT-1,
a4 is an integer from 0 to 8, and
R₉ and R₁₀ are each independently a hydrogen atom, a deuterium atom, a substituted or unsubstituted aryl group having 6 to 60 ring-forming carbon atoms, or a substituted or unsubstituted heteroaryl group having 2 to 60 ring-forming carbon atoms; 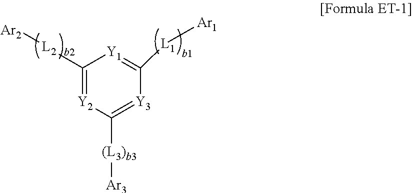
wherein in Formula ET-1,
at least one of Y₁ to Y₃ is N,
the remainder of Y₁ to Y₃ is each independently C(R_{b}),
R_{b} is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer from 0 to 10,
L₁ to L₃ are each independently a direct linkage, a substituted or unsubstituted arylene group having 6 to 30 ring-forming carbon atoms, or a substituted or unsubstituted heteroarylene group having 2 to 30 ring-forming carbon atoms, and
Ar₁ to Ar₃ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and 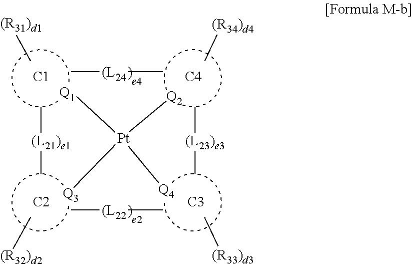
wherein in Formula M-b,
Q₁ to Q₄ are each independently C or N,
C1 to C4 are each independently a substituted or unsubstituted hydrocarbon ring group having 5 to 30 ring-forming carbon atoms, or a substituted or unsubstituted heterocyclic group having 2 to 30 ring-forming carbon atoms,
e1 to e4 are each independently 0 or 1,
L₂₁ to L₂₄ are each independently a direct linkage, 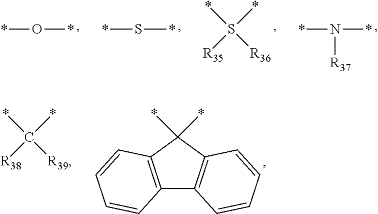
a substituted or unsubstituted divalent alkyl group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
d1 to d4 are each independently an integer from 0 to 4, and
R₃₁ to R₃₉ are each independently a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or are bonded to an adjacent group to form a ring.

2. The light emitting element of claim 1, wherein in Formula 1,
Rₐ is a group represented by Formula 2: 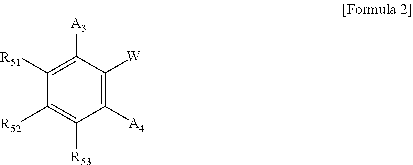
wherein in Formula 2,
at least one of A₃ or A₄ is each independently a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
the remainder of A₃ and A₄ is a hydrogen atom, and
R₅₁ to R₅₃ are each independently a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

3. The light emitting element of claim 2, wherein the group represented by Formula 2 is a group represented by Formula 2-1: 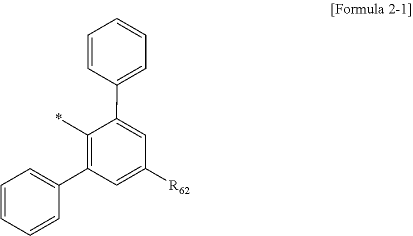
wherein in Formula 2-1,
R₆₂ is a hydrogen atom, a deuterium atom, a substituted or unsubstituted alkyl group having 1 to 10 carbon atoms or a substituted or unsubstituted aryl group having 6 to 20 ring-forming carbon atoms.

4. The light emitting element of claim 3, wherein in Formula 2-1,
R₆₂ is an unsubstituted t-butyl group or an unsubstituted phenyl group.

5. The light emitting element of claim 1, wherein the first compound represented by Formula 1 is a compound represented by Formula 1-1: 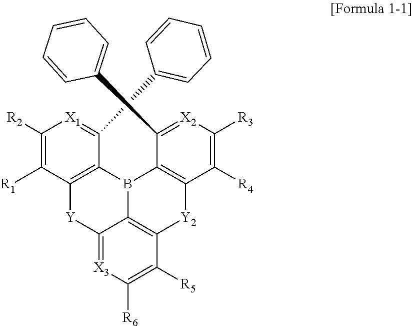
wherein in Formula 1-1,
X₁ to X₃, Y₁, Y₂, and R₁ to R₆ are each the same as defined in Formula 1.

6. The light emitting element of claim 5, wherein the compound represented by Formula 1-1 is a compound represented by Formula 1-A: 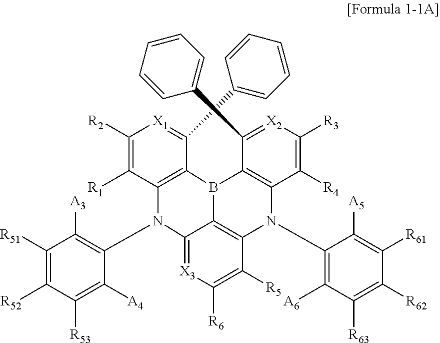
wherein in Formula 1-1A,
at least one of A₃ to A₆ is each independently a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
the remainder of A₃ to A₆ is each independently a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms,
R₅₁ to R₅₃ and R₆₁ to R₆₃ are each independently a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
X₁ to X₃ and R₁ to R₆ are each the same as defined in Formula 1.

7. The light emitting element of claim 1, wherein in Formula 1,
R₂ and R₃ are each independently a group represented by one of R-1 to R-6: 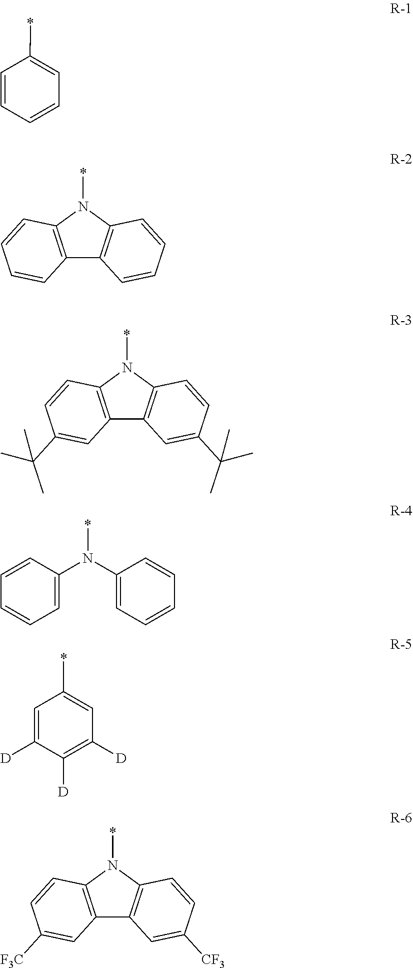
wherein in R-5,
D is a deuterium atom.

8. The light emitting element of claim 1, wherein in Formula 1,
R₆ is a t-butyl group.

9. The light emitting element of claim 1, wherein in Formula 1,
at least one of X₁ to X₃ is N.

10. The light emitting element of claim 1, wherein the first compound represented by Formula 1 is a compound represented by one of Formulas 1-1X to 1-3X: 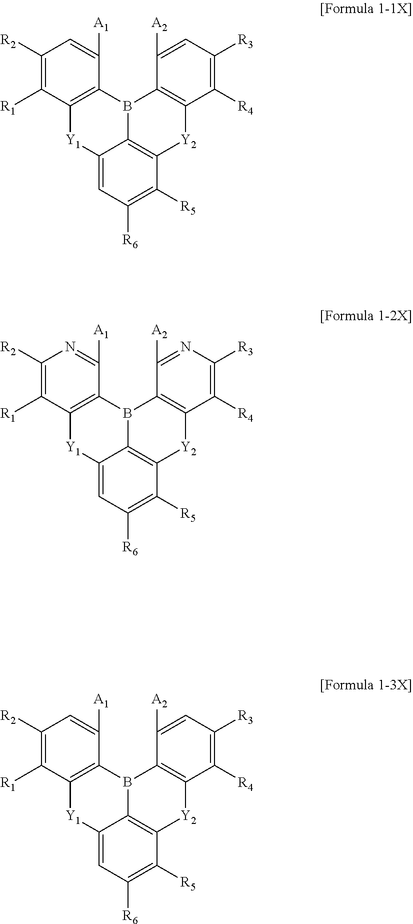
wherein in Formulas 1-1X to 1-3X,
A₁, A₂, Y₁, Y₂, and R₁ to R₆ are each the same as defined in Formula 1.

11. The light emitting element of claim 1, wherein in Formula 1,
at least one of Y₁, Y₂, and R₁ to R₆ each independently includes a deuterium atom or a substituent including a deuterium atom.

12. The light emitting element of claim 1, wherein the emission layer comprises the first compound, the second compound, and the third compound.

13. The light emitting element of claim 1, wherein the emission layer comprises the first compound, the second compound, the third compound, and the fourth compound.

14. The light emitting element of claim 1, wherein the first compound represented by Formula 1 is selected from Compound Group 1: 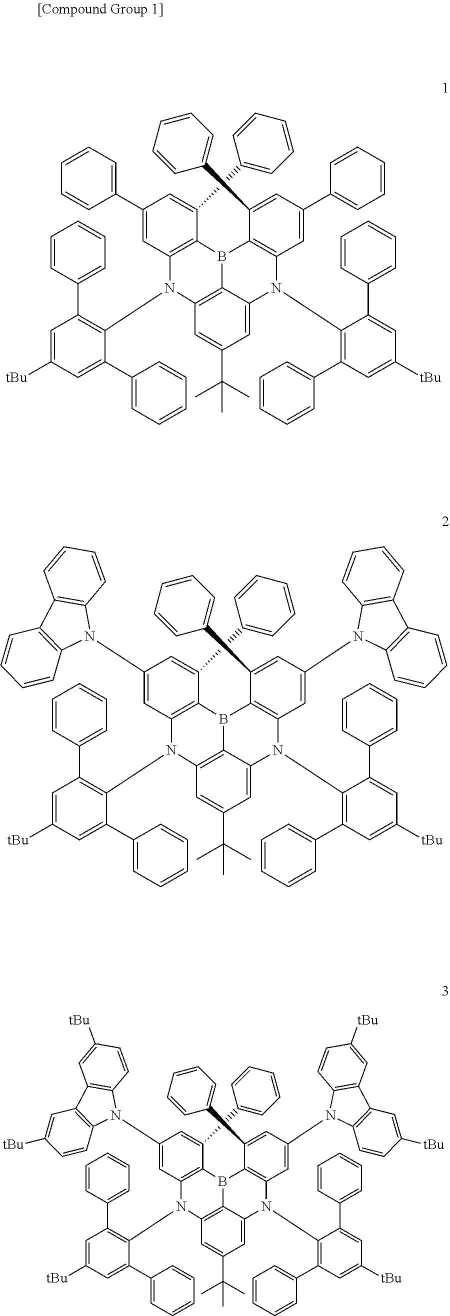 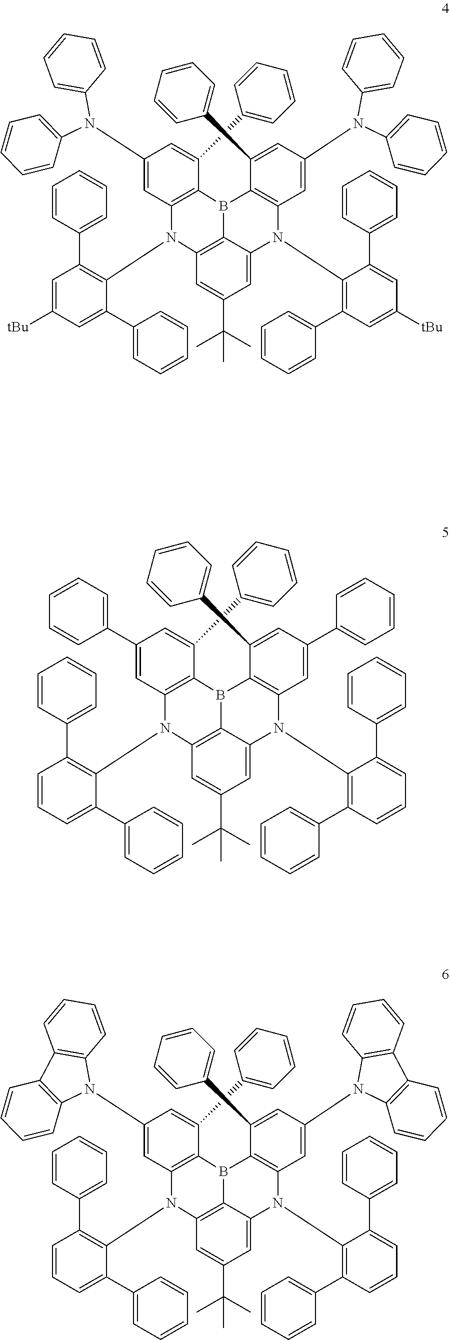 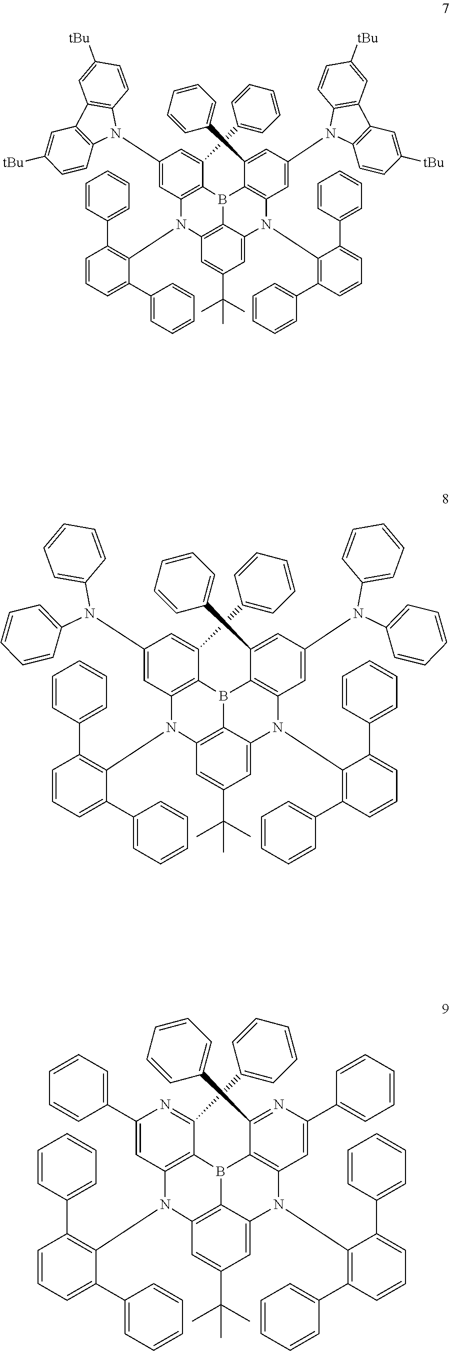 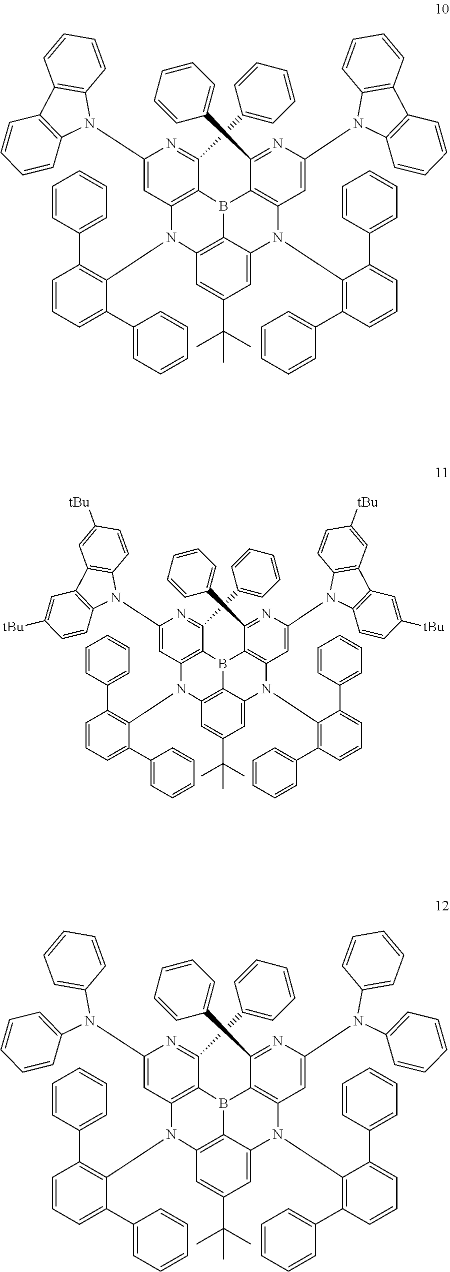 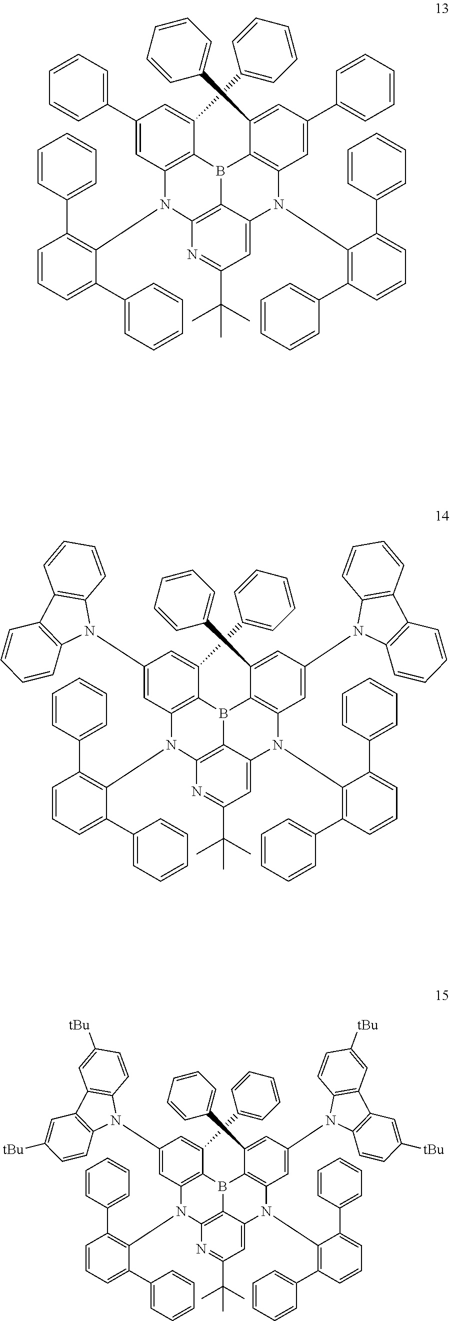 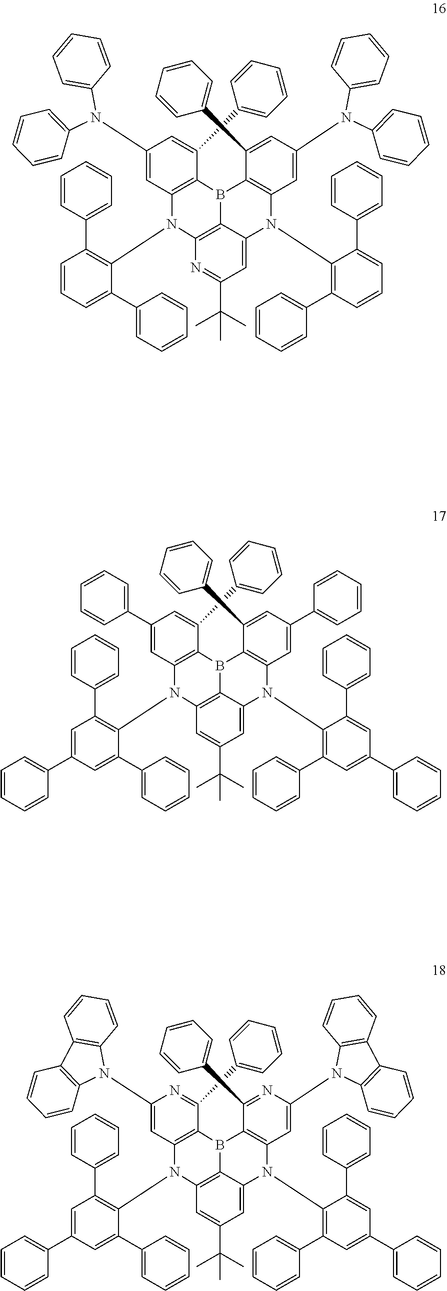 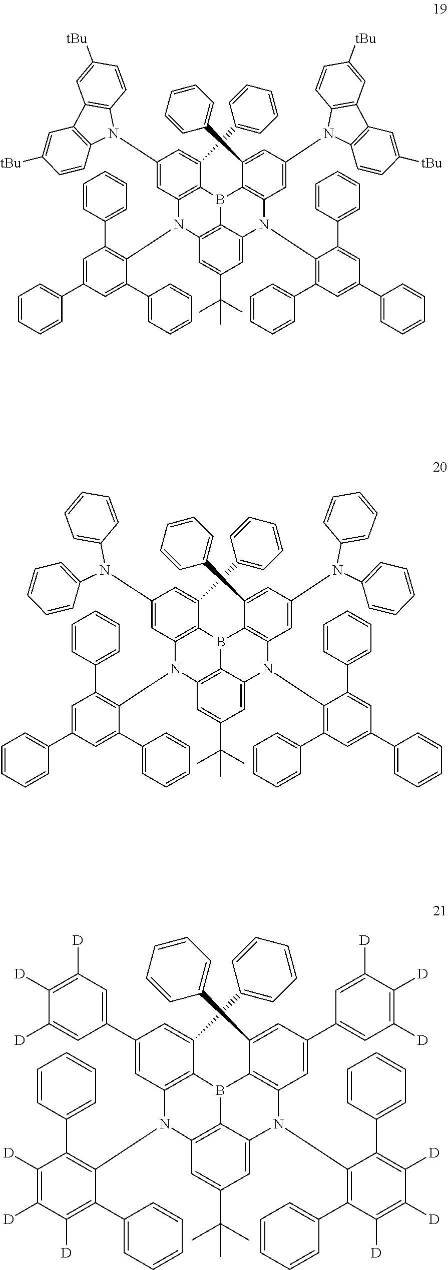 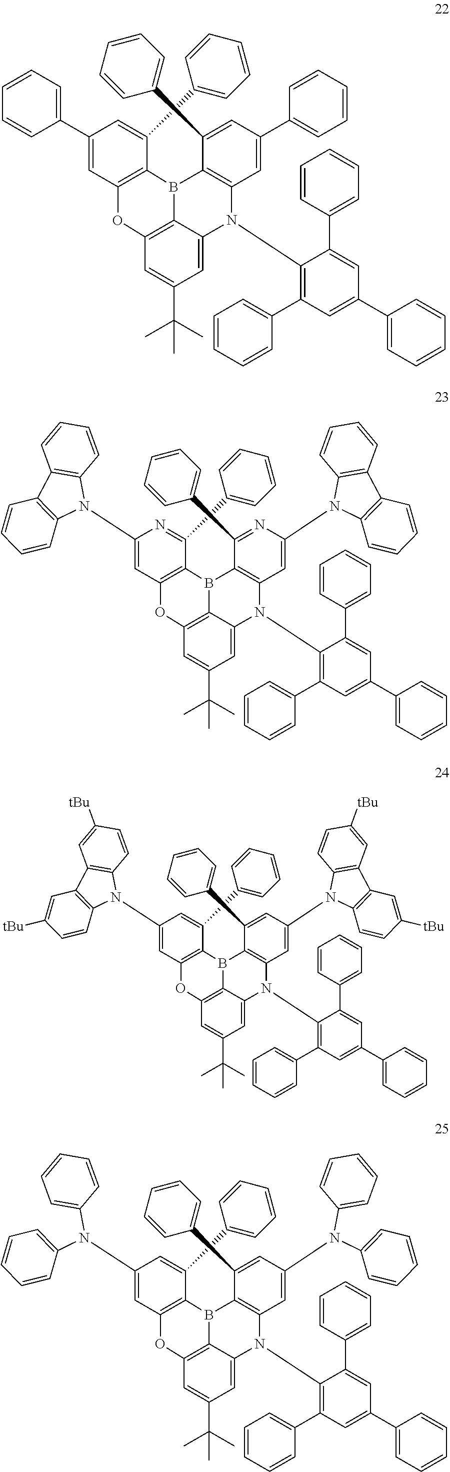 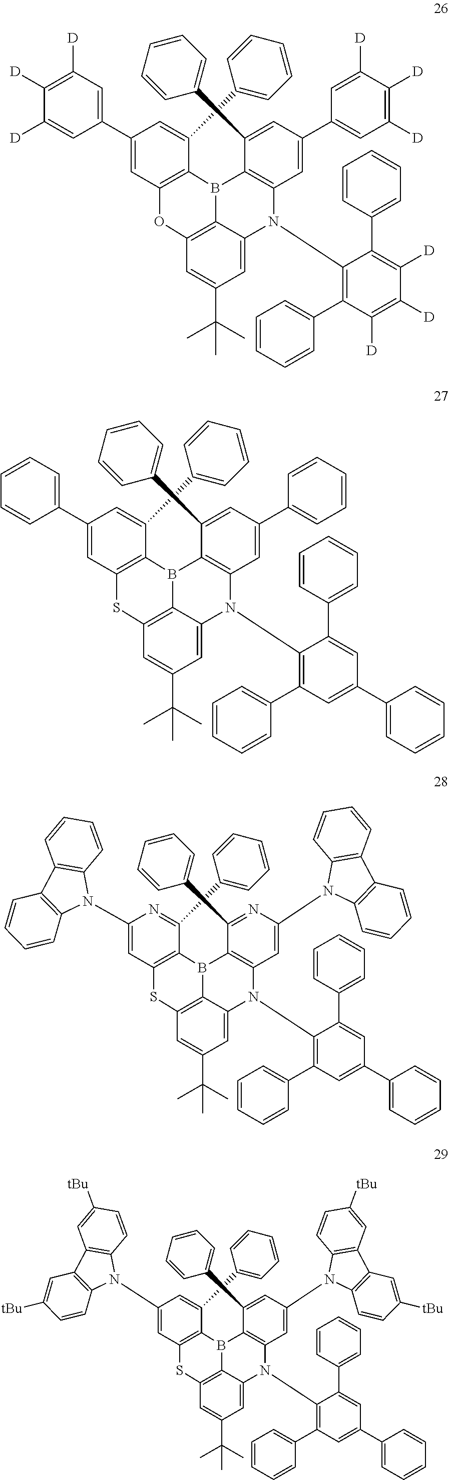 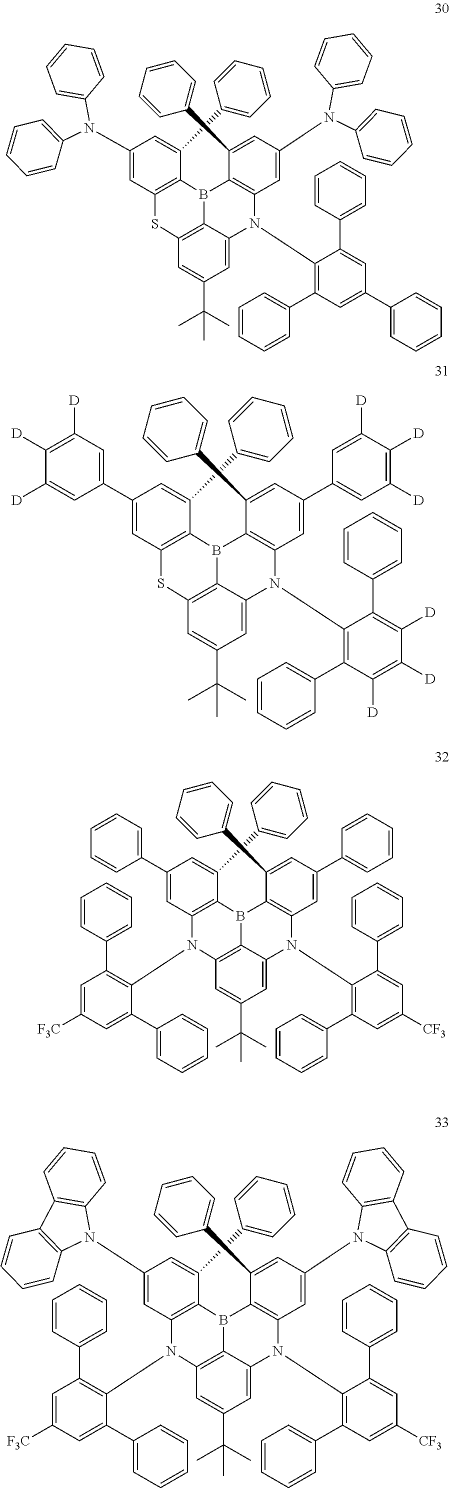 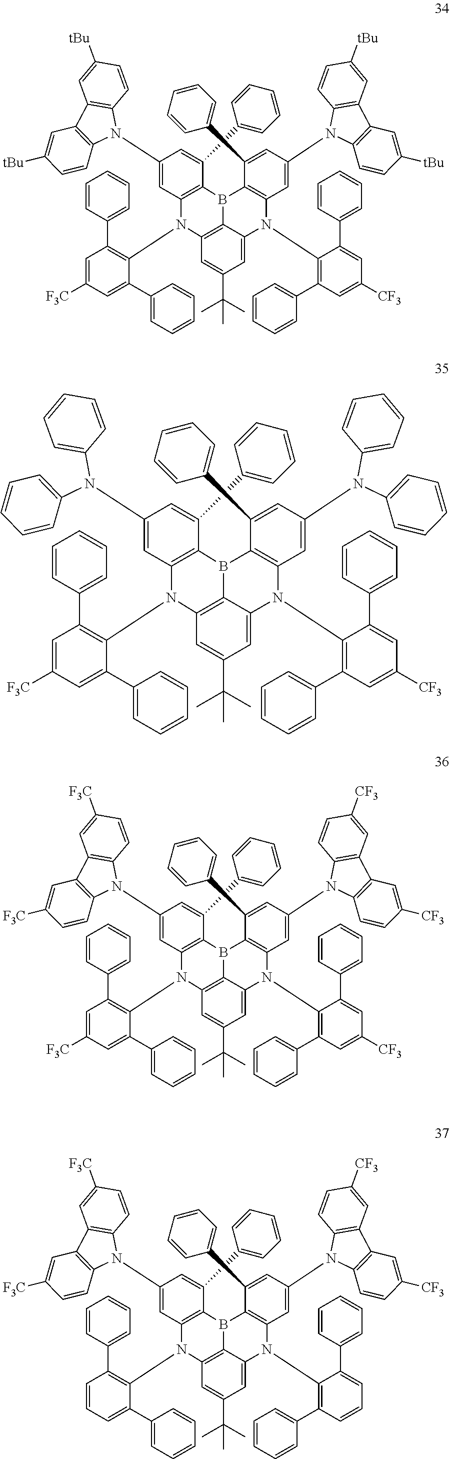
wherein in Compound Group 1,
tBu is a t-butyl group, and
D is a deuterium atom.

15. A light emitting element comprising:
a first electrode;
a second electrode disposed on the first electrode; and
at least one functional layer disposed between the first electrode and the second electrode, wherein
the at least one functional layer includes a polycyclic compound represented by Formula 1: 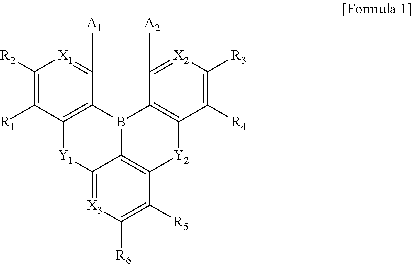
wherein in Formula 1,
X₁ to X₃ are each independently C(R₇) or N,
Y₁ and Y₂ are each independently O, S, or N(Rₐ),
Rₐ is a substituted phenyl group including a substituent at an ortho position with respect to N,
A₁ and A₂ are each independently a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
R₁ to R₇ are each independently a hydrogen atom, a deuterium atom, a halogen atom, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

16. The light emitting element of claim 15, wherein
the at least one functional layer comprises:
an emission layer,
a hole transport region disposed between the first electrode and the emission layer, and
an electron transport region disposed between the emission layer and the second electrode, and
the emission layer includes the polycyclic compound.

17. The light emitting element of claim 16, wherein
the emission layer is a delayed fluorescence emission layer including a host and a dopant,
the dopant includes the polycyclic compound.

18. The light emitting element of claim 15, wherein in Formula 1,
A₁ and A₂ are each independently a substituted or unsubstituted phenyl group.

19. The light emitting element of claim 15, wherein the polycyclic compound is symmetrical with respect to a boron atom.

20. The light emitting element of claim 15, wherein the polycyclic compound is selected from Compound Group 1: 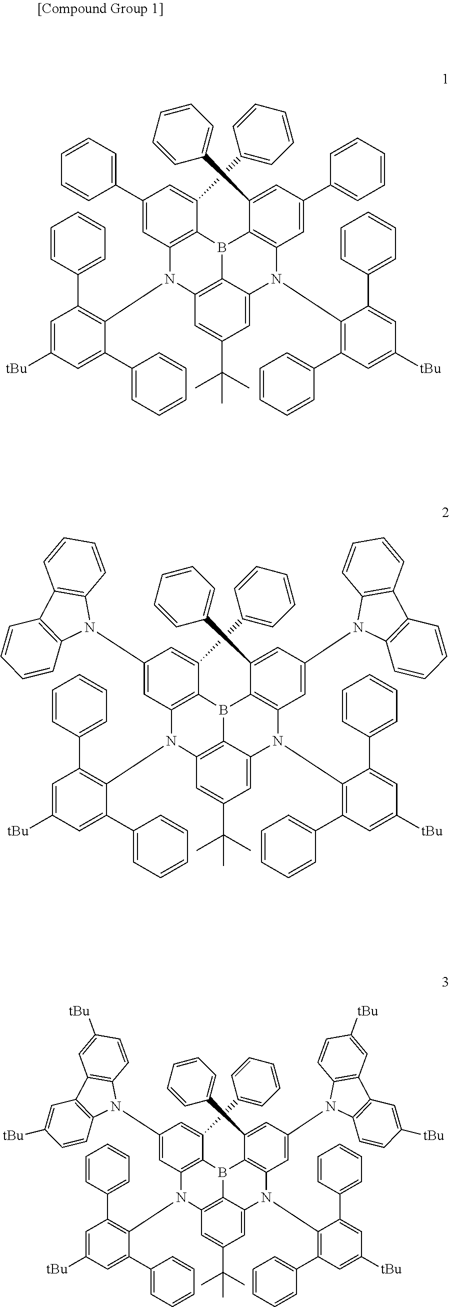 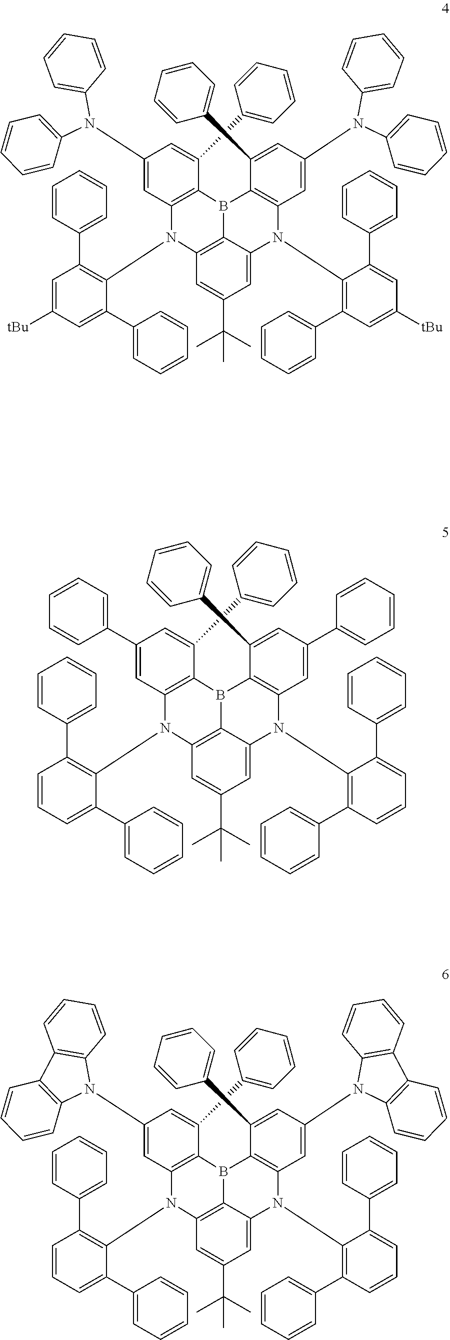 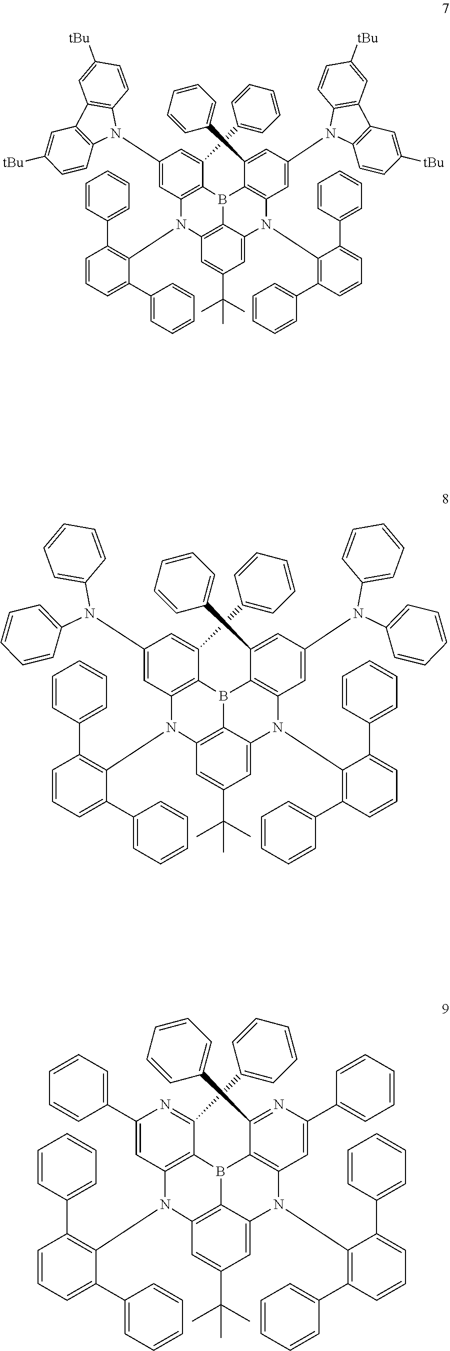 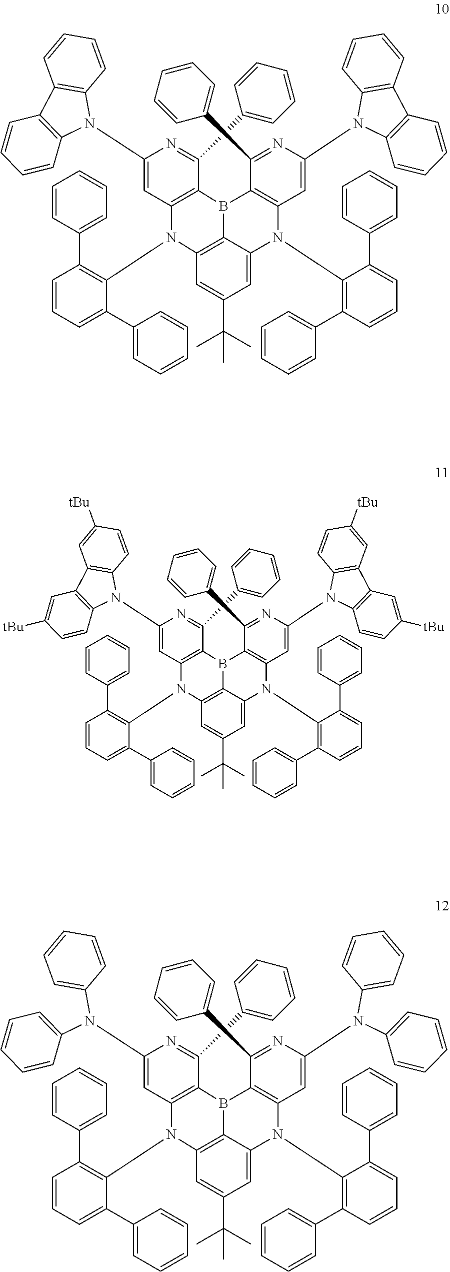 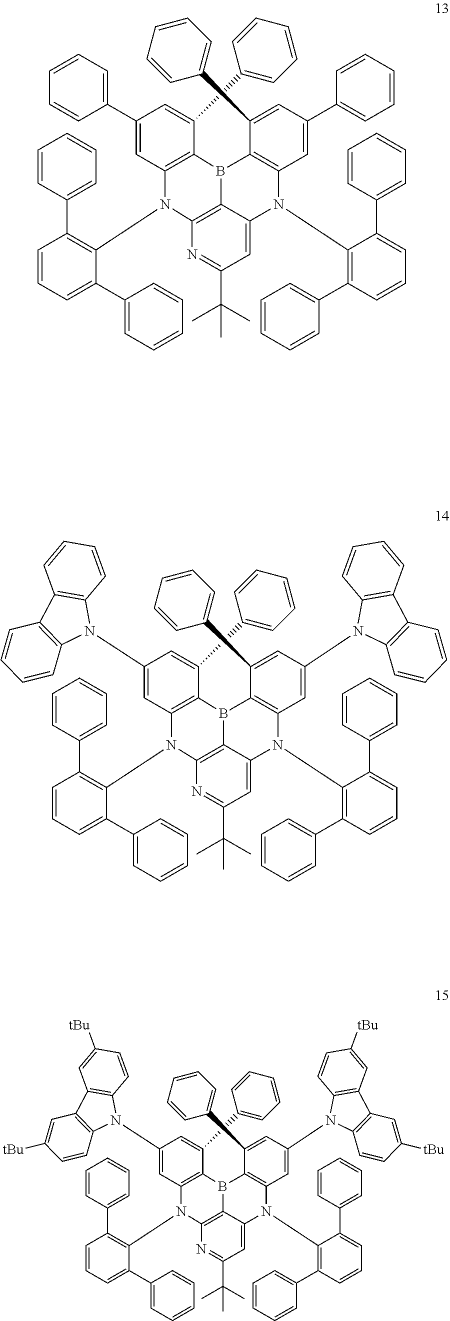 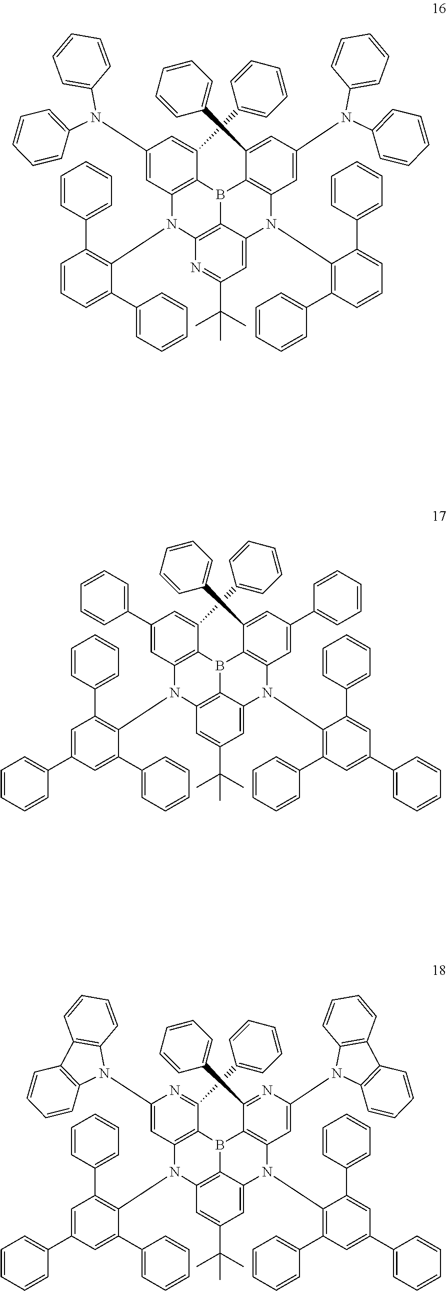 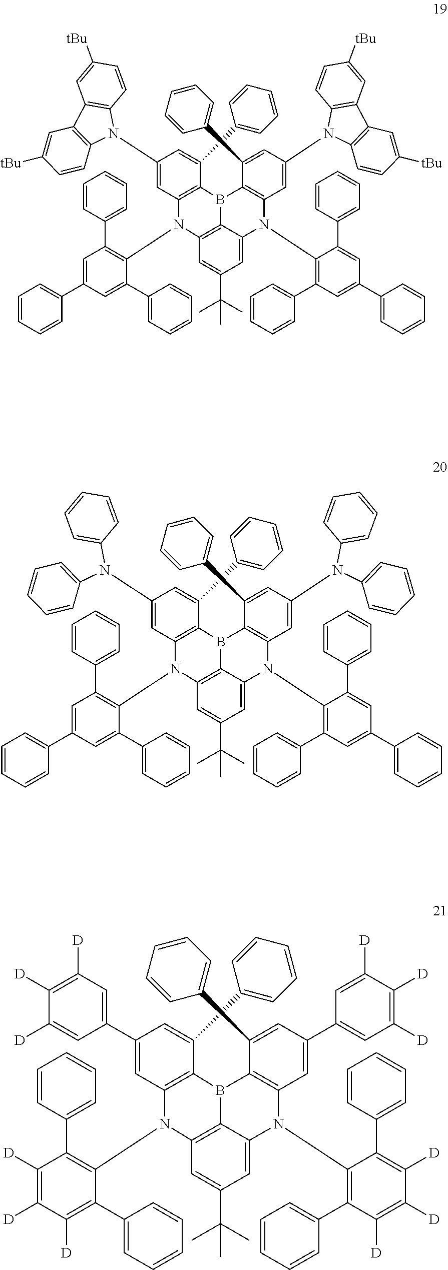 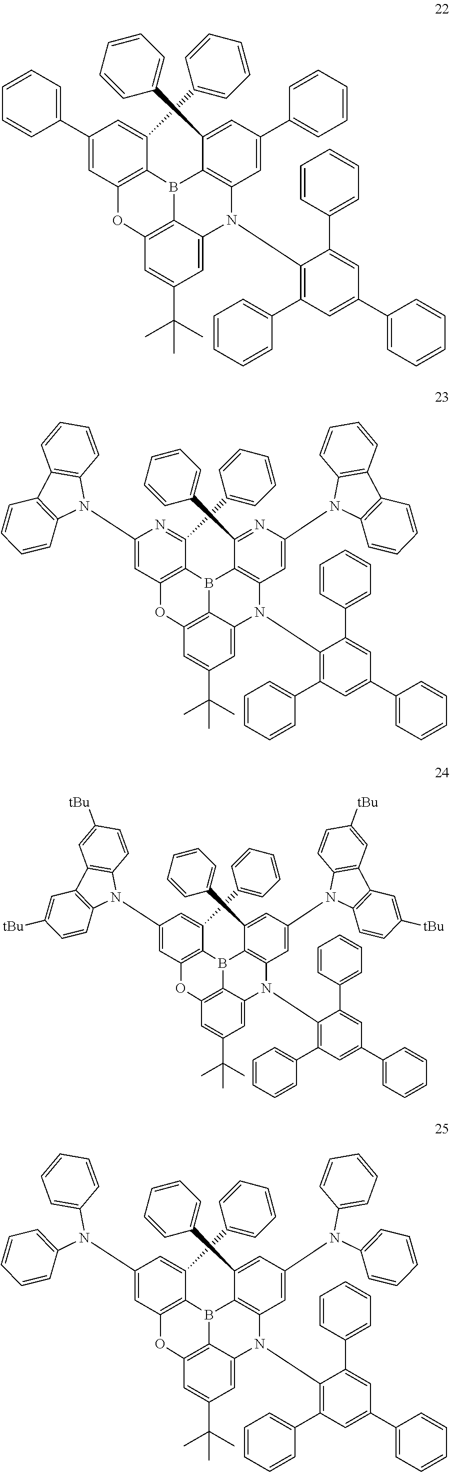 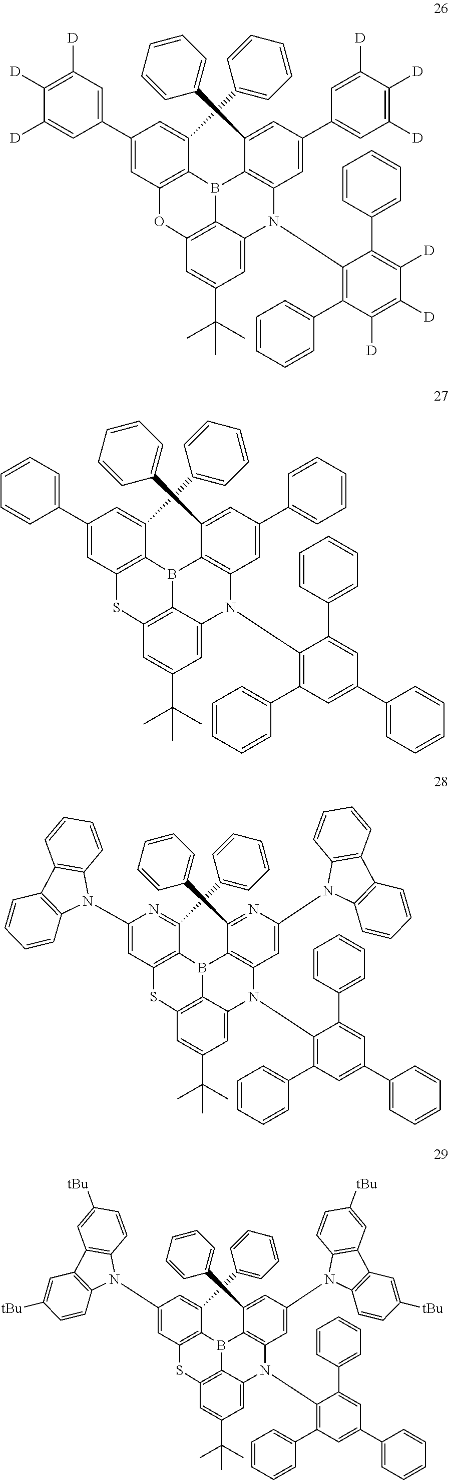 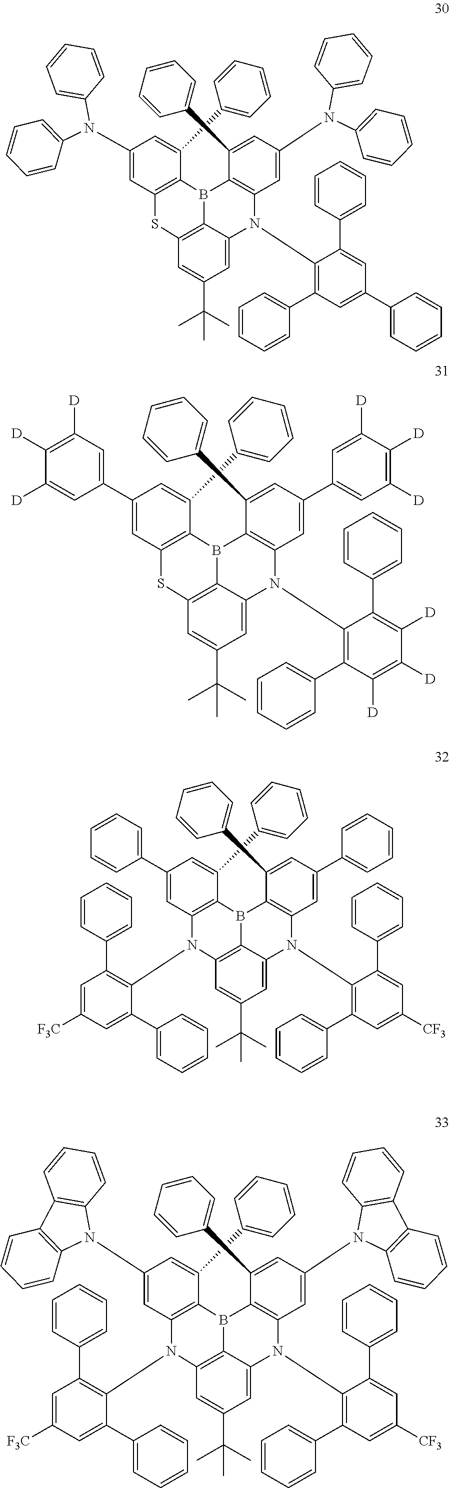 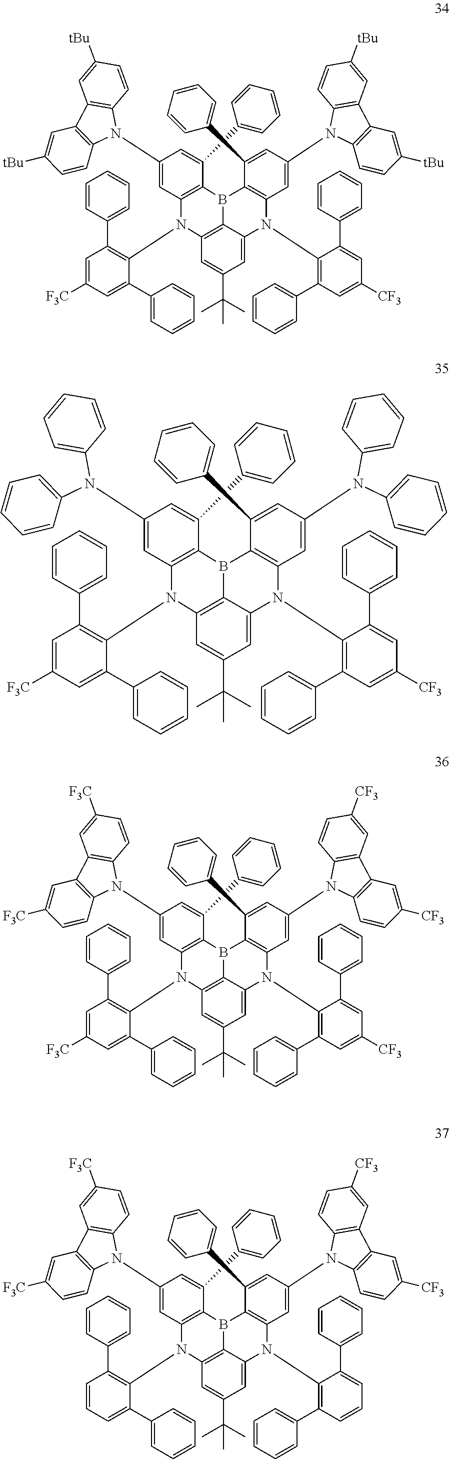
wherein in Compound Group 1,
tBu is a t-butyl group, and
D is a deuterium atom.
